(19) United States
(12) Patent Application Publication
(10) Pub. No.: US 2026/0270591 A1
(43) Pub. Date: Sep. 10, 2026

(54) IMAGE SENSOR DEVICE

(71) Applicant: SAMSUNG ELECTRONICS CO., LTD., Suwon-si (KR)

(72) Inventors: SEONJU LEE, Suwon-si (KR); JAEHONG KIM, Suwon-si (KR); DAEHWA PAIK, Suwon-si (KR); YONGJUN CHO, Suwon-si (KR)

(73) Assignee: SAMSUNG ELECTRONICS CO., LTD., Suwon-si (KR)

(21) Appl. No.: 19/462,546

(22) Filed: Jan. 28, 2026

(30) Foreign Application Priority Data
Mar. 5, 2025 (KR) 10-2025-0028197
Mar. 5, 2025 (KR) 10-2025-0028226

(51) Int. Cl. H04N 25/78; H04N 25/709; H04N 25/79; H10F 39/00

(52) U.S. Cl. CPC H04N 25/78; H04N 25/709; H04N 25/79; H10F 39/809

(57) ABSTRACT

An image sensor device includes: a ramp generator circuit configured to generate a ramp signal; a first variable ramp buffer circuit configured to output a first output voltage according to the ramp signal and a first control signal; a second variable ramp buffer circuit configured to output a second output voltage according to the ramp signal and a second control signal; a first ADC circuit configured to sample a first digital signal based on a first pixel voltage received via a first column line and the first output voltage; and a second ADC circuit configured to sample a second digital signal based on a second pixel voltage received via a second column line and the second output voltage. The variable ramp buffer circuit controls the first output voltage to a first level during an auto-zero operation, and the first output voltage to a reference level after the auto-zero operation.

### CROSS-REFERENCE TO RELATED APPLICATIONS

This application claims priority under 35 U.S.C. § 119 to Korean Patent Application No. 10-2025-0028226, filed on Mar. 5, 2025, and Korean Patent Application No. 10-2025-0028197, filed on Mar. 5, 2025, the disclosures of which are incorporated by reference herein in their entireties.

### BACKGROUND

The present disclosure relates to an image sensor, and more particularly, to an image sensor device.

An image sensor converts light reflected from, or emitted by, an external object into an electrical signal to obtain image information on the external object. An electronic device including the image sensor may display an image on a display panel by using the obtained image information.

As a performance of the image sensor improves and a size of the image sensor decreases, various noises may occur in the image data obtained by the image sensor. As an example, as the performance of the image sensor improves (e.g., resolution, frame rate, etc. increase), a sampling time for obtaining image data may be reduced. In this case, multiple samplings may be performed at the same time point (or within a specific time period), which may cause a sudden fluctuation of a power supply voltage or ground voltage used by the image sensor. The sudden fluctuation of the power supply voltage or the ground voltage may add noise to image data and thereby degrade the quality of image data.

### SUMMARY

One or more example embodiments an image sensor device having improved performance and improved reliability.

According to an aspect of an example embodiment an image sensor device includes: a ramp generator circuit configured to generate a ramp signal; a first variable ramp buffer circuit configured to output a first output voltage according to the ramp signal and a first control signal; a second variable ramp buffer circuit configured to output a second output voltage according to the ramp signal and a second control signal; a first analog to digital conversion (ADC) circuit configured to sample a first digital signal based on a first pixel voltage received via a first column line and the first output voltage; and a second ADC circuit configured to sample a second digital signal based on a second pixel voltage received via a second column line and the second output voltage. The first variable ramp buffer circuit is further configured to control the first output voltage to a first level during an auto-zero operation of the first and second ADC circuits, and control the first output voltage to a reference level after the auto-zero operation. The second variable ramp buffer circuit is further configured to control the second output voltage to a second level different from the first level during the auto-zero operation, and control the second output voltage to the reference level after the auto-zero operation.

According to another aspect of an example embodiment an image sensor device includes: a ramp generator circuit configured to generate a ramp signal; a first variable ramp buffer circuit configured to output a first output voltage according to the ramp signal and a first control signal; and a first ADC circuit configured to output a first digital signal based on a first pixel voltage received via a first column line and the first output voltage. The first variable ramp buffer circuit includes: a first driving transistor connected between a first node to which the first output voltage is output and a ground voltage, wherein the first driving transistor is configured to operate according to the ramp signal; and a first variable current bias circuit coupled between the first node and a power supply voltage, wherein the first variable current bias circuit is configured to control a first bias current provided to the first node according to the first control signal, drive the first bias current to a first magnitude during an auto-zero operation of the first ADC circuit, and drive the first bias current to a reference magnitude after the auto-zero operation.

According to another aspect of an example embodiment, an image sensor device includes: a ramp generator circuit configured to generate a ramp signal; a variable ramp buffer block circuit configured to buffer the ramp signal to output a plurality of output voltages; and an ADC block circuit configured to sample a plurality of digital signals corresponding to a plurality of pixel voltages by comparing the plurality of pixel voltages received via a plurality of column lines and the plurality of output voltages, respectively. The variable ramp buffer block circuit is further configured to control at least two output voltages of the plurality of output voltages to have different levels while the ADC block circuit performs an auto-zero operation, and control the plurality of output voltages to have a common voltage level after the auto-zero operation.

According to another aspect of an example embodiment an image sensor device includes: a first pixel configured to output a first pixel voltage via a first column line; a ramp generator circuit configured to generate a ramp signal; a first variable pixel load circuit connected to the first column line, wherein the first variable pixel load circuit is configured to generate a first pixel bias current according to a first control signal; and a first ADC circuit configured to sample a first digital signal based on the ramp signal and a first pixel output voltage. The first variable pixel load circuit is further configured to control the first pixel bias current to a first level during an auto-zero operation of the first ADC circuit, and control the first pixel bias current to a reference level after the auto-zero operation.

According to another aspect of an example embodiment an image sensor device includes: a ramp generator circuit configured to generate a ramp signal; a first variable ramp buffer circuit configured to output a first output voltage according to the ramp signal and a first control signal; a second variable ramp buffer circuit configured to output a second output voltage according to the ramp signal and a second control signal; a first control switch coupled between the first variable ramp buffer circuit and the second variable ramp buffer circuit; a first ADC circuit configured to sample a first digital signal based on a first pixel voltage received via a first column line and the first output voltage; and a second ADC circuit configured to sample a second digital signal based on a second pixel voltage received via a second column line and the second output voltage. The first control switch is turned on during an auto-zero operation of the first and second ADC circuits, and the first control switch is turned off after the auto-zero operation.

According to another aspect of an example embodiment a method of operating an image sensor device, includes: performing an auto-zero operation of first and second ADC circuits of the image sensor device; controlling, while the auto-zero operation is performed, a first output voltage of a first variable ramp buffer to a first level and a second output voltage of a second variable ramp buffer to a second level; controlling, after the auto-zero operation, the first output voltage of the first variable ramp buffer to a reference level and the second output voltage of the second variable ramp buffer to the reference level; controlling, by the first variable ramp buffer, the first output voltage based on a ramp signal; controlling, by the second variable ramp buffer, the second output voltage based on the ramp signal; sampling, by the first ADC circuit, a first digital signal based on the first output voltage and a first pixel voltage; and sampling, by the second ADC circuit, a second digital signal based on the second output voltage and a second pixel voltage.

According to another aspect of an example embodiment an image sensor device includes: a first pixel configured to output a first pixel voltage via a first column line; a ramp generator circuit configured to generate a ramp signal; a first variable pixel buffer circuit configured to receive the first pixel voltage via the first column line, and output a first pixel output voltage according to the first pixel voltage and a first control signal; and a first ADC circuit configured to sample a first digital signal based on the ramp signal and the first pixel output voltage. The first variable pixel buffer circuit is further configured to control the first pixel output voltage to a first level during an auto-zero operation of the first ADC circuit, and control the first pixel output voltage to a reference level corresponding to the first pixel voltage after the auto-zero operation.

### BRIEF DESCRIPTION OF DRAWINGS

The forgoing and other aspects will be more apparent from the following description of example embodiments, taken in conjunction with the accompanying drawings, in which:

FIG. 1 is a diagram illustrating an image system according to an example embodiment;

FIG. 2 is a block diagram illustrating an image sensor device according to an example embodiment;

FIG. 3A is a circuit diagram illustrating some examples of pixels included in a pixel array according to an example embodiment;

FIG. 3B is a timing diagram for explaining operation of a first analog-to-digital converter (ADC) circuit according to an example embodiment;

FIGS. 4A, 4B, 4C, and 4D are diagrams for describing a ramp buffer and an ADC circuit according to example embodiments;

FIG. 5 is a block diagram showing a variable ramp buffer and an ADC circuit of an image sensor device according to an example embodiment;

FIG. 6 is a circuit diagram showing variable ramp buffers according to an example embodiment;

FIGS. 7A and 7B are diagrams for describing an operation of applying an offset to an inverting input end of a first amplifier by operation of an A-th variable ramp buffer according to an example embodiment;

FIG. 8 is a timing diagram showing operation of variable ramp buffers and ADC circuits according to an example embodiment;

FIGS. 9A and 9B are diagrams for describing operation of variable ramp buffers according to an example embodiment;

FIG. 10 is a circuit diagram showing a variable ramp buffer according to an example embodiment;

FIG. 11 is a circuit diagram showing a variable ramp buffer according to an example embodiment;

FIGS. 12A and 12B are diagrams for describing operation of a variable ramp buffer according to an example embodiment;

FIG. 13 is a circuit diagram showing a variable ramp buffer according to an example embodiment;

FIGS. 14A and 14B are diagrams for describing operation of a variable ramp buffer according to an example embodiment;

FIG. 15 is a circuit diagram showing a variable ramp buffer according to an example embodiment;

FIG. 16 is a circuit diagram showing a variable ramp buffer according to an example embodiment;

FIG. 17 is a timing diagram for explaining operation of a variable ramp buffer according to an example embodiment;

FIGS. 18-20 are circuit diagrams illustrating a variable ramp buffer according to an example embodiment;

FIG. 21 is a flowchart illustrating operation of an image sensor device according to an example embodiment;

FIGS. 22-26 are circuit diagrams illustrating a variable ramp buffer according to an example embodiment;

FIG. 27 is a block diagram showing some configurations of an image sensor device according to an example embodiment;

FIG. 28 is a block diagram showing an image sensor device according to an example embodiment;

FIG. 29 is a block diagram showing an image sensor device according to an example embodiment;

FIG. 30 is a block diagram illustrating a variable pixel load circuit and an ADC circuit according to an example embodiment;

FIG. 31 is a timing diagram for describing an operation of a variable pixel load circuit according to an example embodiment;

FIG. 32 is a block diagram illustrating an image sensor device according to an example embodiment;

FIG. 33 is a block diagram illustrating a variable ramp buffer, variable pixel load circuit, and ADC circuit according to an example embodiment;

FIG. 34 is a block diagram illustrating an image sensor device according to an example embodiment;

FIG. 35 is a block diagram illustrating a ramp buffer, variable pixel buffer, and ADC circuitry according to an example embodiment;

FIG. 36 is a block diagram showing an image sensor device according to an example embodiment;

FIG. 37 is a block diagram illustrating a variable ramp buffer, variable pixel buffer, and ADC circuitry according to an example embodiment; and

FIGS. 38 and 39 are diagrams showing a stacked structure of an image sensor device according to an example embodiment.

### DETAILED DESCRIPTION

Hereinafter, example embodiments will be described with reference to the accompanying drawings. Embodiments described herein are provided as examples, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

Terms such as “block,” “unit,” “module,” or the like, or configurations corresponding thereto, or functional blocks or circuits in the drawings, as used below, may be implemented in hardware, which may operate according to computer instructions.

Hereinafter, where various components are listed via the conjunction of “or,” this may refer to each of the listed components, or to a combination of at least some. For example, “A, B, or C” can mean each of A, B, and C, or can mean only A, only B, only C, both A and B, both A and C, both B and C, or all of A, B, and C.

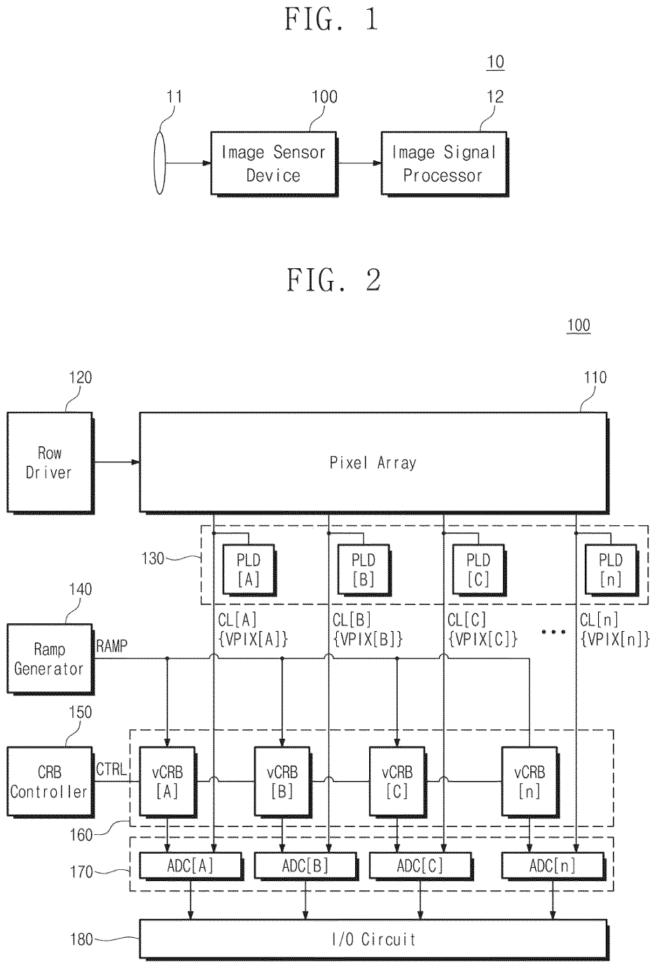

FIG. 1 is a diagram illustrating an image system according to an example embodiment. Referring to FIG. 1, an image system 10 may include a lens 11, an image sensor device 100, and an image signal processor 12. In an example embodiment, the image system 10 may be implemented as part of various electronic devices such as a camera, a smartphone, a wearable device, an Internet of Things (IoT) device, a home appliance, a tablet Personal Computer (PC), a Personal Digital Assistant (PDA), a Portable Multimedia Player (PMP), a navigation device, a drone, an Advanced Drivers Assistance System (ADAS), a traffic surveillance camera, a closed-circuit television (CCTV), and the like. In addition, the image system 10 may be mounted on an electronic device provided as a component in a vehicle, furniture, a manufacturing facility, a door, various measurement devices, or the like.

The lens 11 may receive light reflected from, or emitted by, an external object. The image sensor device 100 may generate an electrical signal based on light received through the lens 11. For example, the image sensor device 100 may be implemented as a Complementary Metal Oxide Semiconductor (CMOS) image sensor or the like. However, example embodiments are not limited thereto, and the image sensor device 100 may be implemented based on various image sensors such as a dynamic vision sensor (DVS), a digital pixel sensor (DPS), and the like.

The image signal processor 12 may receive the electrical signal (e.g., image data or output data including information about an external object or field of view) from the image sensor device 100, and perform various image signal processing operations on the received signals. In an example embodiment, the image signal processing operation may include various signal processing operations to improve image quality, such as a de-noising operation, a tone-mapping operation, a detail enhancing operation, a white balancing operation, a gamma correction operation, a de-mosaic operation, a sharpening operation, a color conversion operation, and the like.

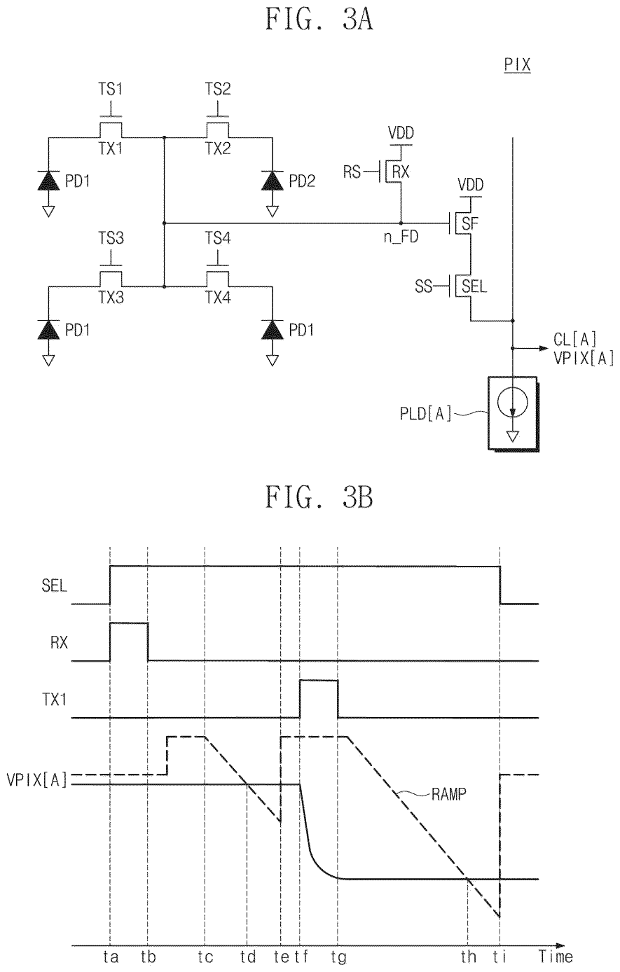

FIG. 2 is a block diagram illustrating the image sensor device of FIG. 1. Referring to FIGS. 1 and 2, the image sensor device 100 may include a pixel array 110, a row driver (e.g., row driver circuit) 120, a pixel load block (e.g., pixel load block circuit) 130, a ramp generator (e.g., ramp generator circuit) 140, a ramp buffer controller (e.g., ramp buffer control circuit) 150, a variable ramp buffer block (e.g., variable ramp buffer block circuit) 160, an analog to digital conversion (ADC) block (e.g., ADC block circuit) 170, and an input/output circuit 180.

The pixel array 110 may include a plurality of pixels. Each of the plurality of pixels may be configured to convert light incident through the lens 11 into an electrical signal. The plurality of pixels may output a plurality of pixel voltages VPIX[A] to VPIX[n] through the plurality of column lines CL[A] to CL[n], respectively. In an example embodiment, each of the plurality of pixel voltages VPIX[A] to VPIX[n] may correspond to a reset level or a signal level of a corresponding pixel.

Hereinafter, for convenience of description, a reference symbol of “[X]” is used. “[X]” may be used in combination with other reference symbols, and may indicate that a component of the combined reference symbol corresponds to the X-th column of the plurality of pixels. For example, the reference symbol of CL[A] may refer to a column line CL corresponding to the A-th column of the plurality of pixels of the pixel array. The reference symbol of VPIX[B] may refer to a pixel voltage output from pixels corresponding to the B-th column of the plurality of pixels. Further, for ease of description, reference numerals indicating column numbers are capitalized and may be used in conjunction with reference numeral to distinguish similar components, such as first, second, third, etc. In this case, the respective components may be distinguished using expressions such as 1X-th, 2X-th, 1Y-th, 2Y-th, and the like. For example, “OTA1[A]” may be referred to as a 1A-th amplifier, which may refer to a first amplifier of the amplifiers corresponding to the A-th column. As another example, “AZS2[B]” may be referred to as a 2B-th auto-zero switch, which may refer to a second one of auto-zero switches corresponding to a B-th column. As another example, “vCRB[A]” may be referred to as the A-th variable ramp buffer, which may refer to a variable ramp buffer corresponding to the A-th column. The reference symbols and terms described above will be understood in accordance with the context of the detailed description, unless defined otherwise.

The row driver 120 may provide various control signals to the plurality of pixels included in the pixel array 110. The plurality of pixels may operate under the control of the row driver 120.

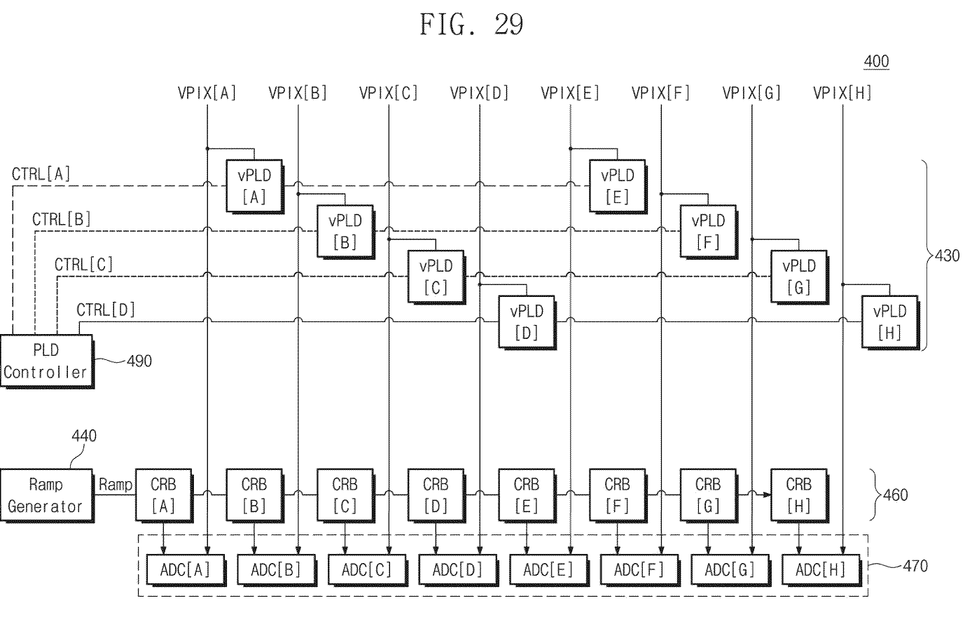

The pixel load block 130 may include a plurality of pixel load circuits PLD[A] to PLD[n]. The plurality of pixel load circuits PLD[A] to PLD[n] may be connected to the plurality of column lines CL[A] to CL[n], respectively. The plurality of pixel load circuits PLD[A] to PLD[n] may provide pixel bias currents for the plurality of pixel voltages VPIX[A] to VPIX[n] provided through the plurality of column lines CL[A] to CL[n], respectively. For example, the A-th pixel load circuit PLD[A] may be connected to the A-th column line CL[A] and may provide a first pixel bias current for the A-th Column line CL[A]. The A-th column line CL[A] may be quickly initialized by the first pixel bias current. In an example embodiment, the A-th pixel voltage VPIX[A] of the A-th column line CL[A] may be partially controlled by the first pixel bias current. Each of the plurality of pixel load circuits PLD[A] to PLD[n] may operate in response to the same bias signal. That is, each of the plurality of pixel load circuits PLD[A] to PLD[n] may generate a pixel bias current of the same magnitude. However, example embodiments are not limited thereto, and the plurality of pixel load circuits PLD[A] to PLD[n] may operate in response to different control signals, and each of the plurality of pixel load circuits PLD[A] to PLD[n] may individually control a pixel bias current. Configurations related thereto are described with reference to FIGS. 29-37 below.

The image sensor device 100 may be configured to convert a plurality of pixel voltages VPIX[A] to VPIX[n], which output through the plurality of column lines CL[A] to CL[n], into digital signals, respectively. For example, the ADC block 170 may be configured to convert the plurality of pixel voltages VPIX[A] to VPIX[n] into digital signals, respectively. As a more detailed example, the ADC block 170 may include a plurality of ADC circuits ADC[A] to ADC[n].

The plurality of ADC circuits ADC[A] to ADC[n] may receive the plurality of pixel voltages VPIX[A] to VPIX[n] through the plurality of column lines CL[A] to CL[n], respectively. The plurality of ADC circuits ADC[A] to ADC[n] may compare the plurality of pixel voltages VPIX[A] to VPIX[n] with a ramp signal RAMP, respectively, and output digital signals corresponding to the plurality of pixel voltages VPIX[A] to VPIX[n], respectively, based on the comparison result. As an example, the ramp signal RAMP may be generated by the ramp generator 140. The ramp signal RAMP may be a signal that changes at a constant rate over time. For example, the ramp signal RAMP may be a signal that decreases at a constant rate over time.

In an example embodiment, the A-th ADC circuit ADC[A] may receive the A-th pixel voltage VPIX[A] through the A-th column line CL[A]. The A-th ADC circuit ADC[A] may compare the A-th pixel voltage VPIX[A] with the ramp signal RAMP, and output the A-th digital signal based on the comparison result. The B-th ADC circuit ADC[B] may receive the B-th pixel voltage VPIX[B] through the B-th column line CL[B]. The B-th ADC circuit ADC[B] may compare the B-th pixel voltage VPIX[B] with the ramp signal RAMP, and output the B-th digital signal based on the comparison result.

According to an example embodiment, the image sensor device 100 may include a ramp buffer controller (e.g., ramp buffer control circuit) 150 and a variable ramp buffer block (e.g., variable ramp buffer block circuit) 160.

The ramp buffer controller 150 may generate various control signals CTRL or bias signals used in the variable ramp buffer block 160. The variable ramp buffer block 160 may receive the ramp signal RAMP from the ramp generator 140, buffer the received ramp signal RAMP, and transmit the buffered ramp signal RAMP to the ADC block 170. In this case, the reliability of the ramp signal RAMP may be improved.

For example, each of the plurality of ADC circuits ADC[A] to ADC[n] may perform a sampling operation using the ramp signal RAMP. When the ramp signal RAMP is generated from one ramp generator 140, a waveform or a delay time of the ramp signal RAMP received in each of the plurality of ADC circuits ADC[A] to ADC[n] may vary depending on a load of a path through which the ramp signal RAMP is transmitted. Accordingly, an operation reliability of the plurality of ADC circuits ADC[A] to ADC[n] may be degraded.

The variable column ramp buffer (vCRB) block 160 (hereinafter, for convenience of description, referred to as a variable ramp buffer block) may include a plurality of variable ramp buffers vCRB[A] to vCRB[n]. Each of the plurality of variable ramp buffers vCRB[A] to vCRB[n] may receive the ramp signal RAMP from the ramp generator 140, buffer the received ramp signal RAMP, and provide the ramp signal RAMP to the plurality of ADC circuits ADC[A] to ADC[n], respectively.

In an example embodiment, the plurality of variable ramp buffers vCRB[A] to vCRB[n] may perform a buffering operation on the ramp signal RAMP using bias signals generated by the ramp buffer controller 150.

In an example embodiment, the ADC block 170 may perform a correlated double sampling (CDS) operation. For example, each of the plurality of pixel voltages VPIX[A] to VPIX[n] may correspond to a reset level and a signal level for a corresponding pixel. The plurality of ADC circuits ADC[A] to ADC[n] of the ADC block 170 may perform reset sampling with respect to a reset level of the plurality of pixel voltages VPIX[A] to VPIX[n], respectively, and may perform signal sampling with respect to signal levels of the plurality of pixels voltages VPIX[A] to VPIX[n], respectively. Because the reset levels of the plurality of pixel voltages VPIX[A] to VPIX[n] may have similar levels to each other, a time point in time when the ramp signal RAMP becomes lower than the reset levels of a plurality of pixel voltages VPIX[a] to VPIX[n] in the reset sampling operation may be similar. In this case, as the plurality of ADC circuits ADC[A] to ADC[n] perform sampling at the same time within a short time, thereby generating noise in the power supply voltage or the ground voltage connected to the plurality of ADC circuits ADC [A] to ADC[n], or the level of the power supply voltage may be fluctuated. This may reduce operational reliability of the image sensor device 100.

In an example embodiment, each of the plurality of variable ramp buffers vCRB[A] to vCRB[n] of the variable ramp buffer block 160 may apply different offsets to the ramp signal RAMP by using the control signal CTRL. In this case, signals output from the plurality of variable CRB circuits vCRB[A] to vCRB[n] may be varied. Accordingly, different offsets may be applied to inputs of each of the plurality of ADC circuits ADC[A] to ADC[n]. In this case, when the plurality of ADC circuits ADC[A] to ADC[n] perform a conversion operation (e.g., reset sampling) on pixel voltages of the same or similar level, a sampling time point may be distributed. In this case, a sudden fluctuation of levels or voltages in the power supply voltage or the ground voltage connected to the plurality of ADC circuits ADC[A] to ADC[n] may be reduced. The configuration and operation of the variable ramp buffers vCRB[A] to vCRB[n] according to example embodiments are described in more detail with reference to the following drawings.

FIG. 3A is a circuit diagram illustrating some examples of pixels included in the pixel array of FIG. 2. FIG. 3B is a timing diagram for explaining the operation of the first ADC circuit of FIG. 2. In FIG. 3B, a horizontal axis indicates time, and a vertical axis indicates the level of each signal.

Referring to FIGS. 2, 3A, and 3B, a pixel PIX may include first to fourth photodiodes PD1 to PD4, first to fourth transfer transistors TX1 to TX4, a reset transistor TX, a source follower SF, and a selection transistor SEL. In an example embodiment, each of the first to fourth transfer transistors TX1 to TX4, the reset transistor RX, and the selection transistor SEL may refer to a transistor (e.g., an NMOS transistor) configured to operate in response to a corresponding signal.

The first to fourth photodiodes PD1 to PD4 may generate a photo-charge in response to light incident from the outside. The first to fourth transfer transistors TX1 to TX4 may be connected between the first to fourth photodiodes PD1 to PD4 and the floating diffusion (FD) node n_FD, respectively, and may operate in response to first to fourth transfer signals TS1 to TS4. The reset transistor RX may be connected between the power supply voltage Vpix and the FD node n_FD, and may operate in response to a reset signal RS. The source follower SF and the selection transistor SEL may be connected in series between the power supply voltage Vpix and the A-th column line CL[A]. The source follower SF may operate in response to a level of the FD node n_FD, and the selection transistor SEL may operate in response a selection signal SS. In an example embodiment, the level of the A-th pixel voltage VPIX[A] output through the A-th column line CL[A] may vary depending on the level of the FD node n_FD.

In an example embodiment, the A-th pixel load circuit PLD[A] may be connected to the A-th column line CL[A] and may provide a first pixel bias current.

The pixel structure of FIG. 3A, for example, a structure in which four photodiodes share one FD node n_FD is some examples, and example embodiments are not limited thereto. The plurality of pixels included in the image sensor device 100 may be implemented in various structures, for example, a single photodiode structure, a split diode structure, or the like, or may further include additional circuits for a structure for a dual conversion gain (DCG), a structure for a global shutter, or the like.

Hereinafter, in order to concisely describe operations of the pixel PIX and the ADC circuit ADC, each operation is described with reference to one photodiode (e.g., PD1). As shown in FIG. 3B, during a period between a-th to i-th time points (ta-ti), the selection signal SEL may maintain a high level. During a period between the a-th to b-th time points (ta-tb), the reset signal RS may be at a high level. In this case, in response to the reset signal RS of the high-level, the reset transistor RX may be turned on. Accordingly, the FD node n_FD may be reset to a level corresponding to the power supply voltage Vpix, and the first pixel voltage VPIX[A] may have a reset level corresponding to the FD node n_FD.

Thereafter, the A-th ADC circuit ADC[A] may perform a reset sampling operation. For example, the A-th ADC circuit ADC[A] may compare the reset level of the A-th pixel voltage VPIX[A] with the ramp signal RAMP, during a period between c-th to e-th time points (tc-te). At a td time point at which the ramp signal RAMP becomes lower than the reset level of the A-th pixel voltage VPIX[A], the A-th ADC circuit ADC[A] may output or store a digital signal corresponding to the reset level of A-th pixel voltage VPIX[A].

Thereafter, during a period between the f-th to g-th time points (tf-tg), the first transfer signal TS1 may maintain a high level. In response to the first transfer signal TS1 of the high level, the first transfer transistor TX1 may be turned on. Accordingly, the photo-charge generated by the first photodiode PD1 may be transferred to the FD node n_FD, and the level of the FD node n_FD may be lowered. At this time, as the level of the FD node n_FD is lowered, the A-th pixel voltage VPIX[A] may be lowered. In an example embodiment, the A-th pixel voltage VPIX[A] may be lowered to a signal level corresponding to the level of the FD node n_FD.

Thereafter, the A-th ADC circuit ADC[A] may perform a signal sampling operation. For example, the A-th ADC circuit ADC[A] may compare the signal level of the A-th pixel voltage VPIX[A] with the ramp signal RAMP, during a period between g-th to i-th time points (tg-ti). At an h-th time point at which the ramp signal RAMP becomes lower than the signal level of the A-th pixel voltage VPIX[A], the A-th ADC circuit ADC[A] may output or store a digital signal corresponding to the signal level of A-th pixel voltage VPIX[A].

The operation of the pixel PIX and the ADC circuit for the pixel PIX described with reference to FIGS. 3A and 3B are provided as examples, and example embodiments are not limited thereto. For example, it will be understood that the above-described operation scheme may be variously modified according to a structure and an operation manner of the pixel PIX.

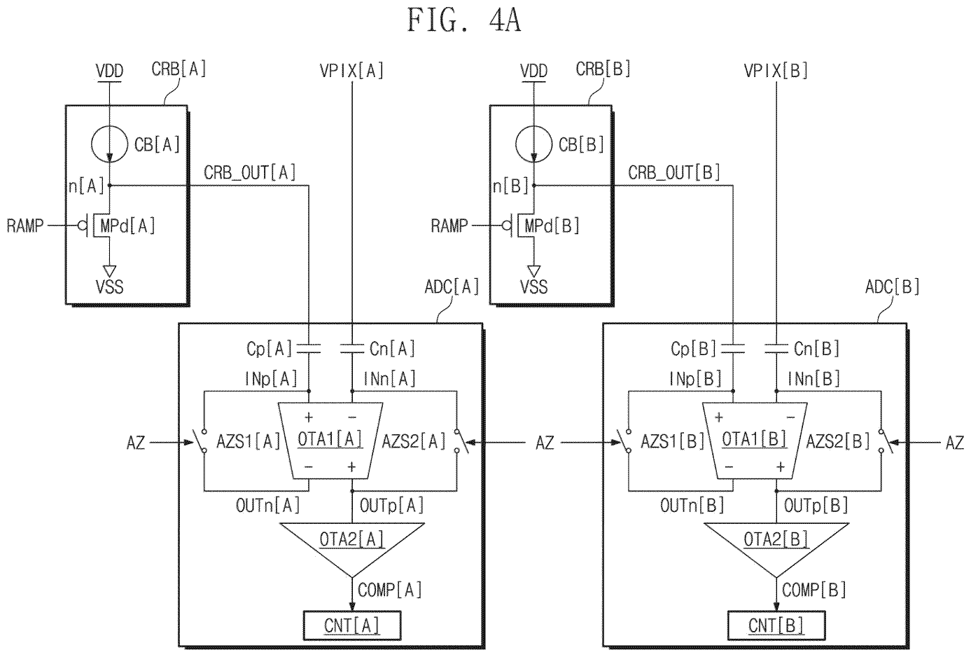

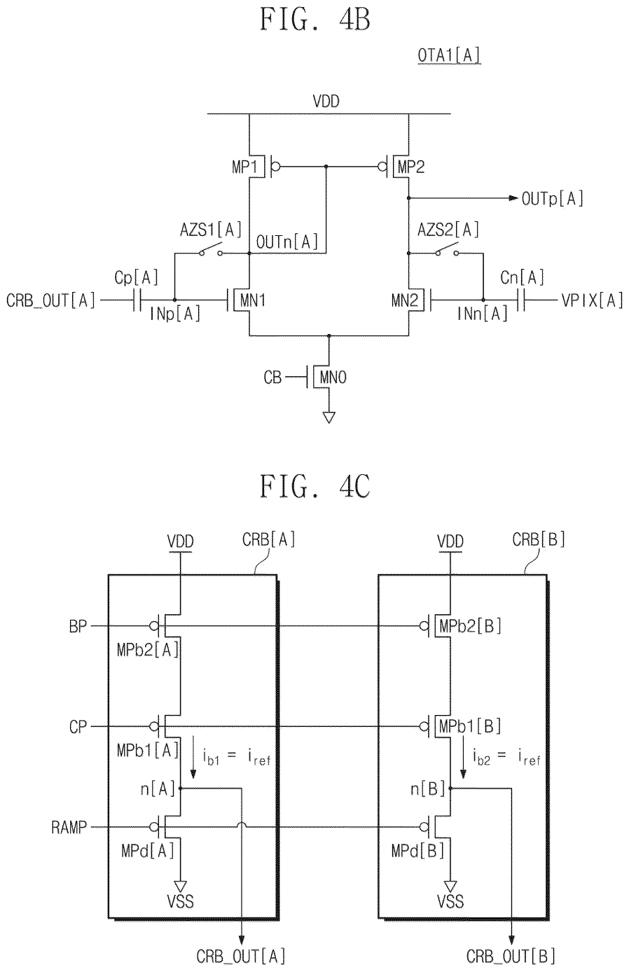

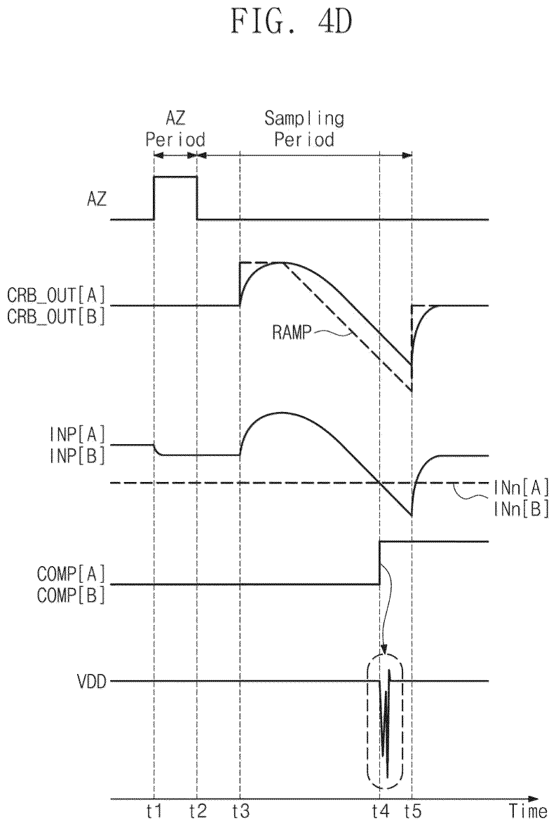

FIGS. 4A, 4B, 4C, and 4D are diagrams for describing a ramp buffer and an ADC circuit. For ease of description, some components are omitted. For example, for the sake of brevity the figures and ease of description, the A-th and B-th ADC circuits ADC[A] and ADC[B] coupled with the A-th and the B-th column lines CL[A] and CL[B] and the A-th and a B-th ramp buffers CRB[A] and CRB[B] configured to provide a buffered ramp signal to the A-th and B-th ADC circuits ADC[A] and ADC[B]. However, example embodiments are not limited thereto, and other ADC circuits or column ramp buffers may have a similar structure as described with reference to FIGS. 4A, 4B, 4C, and 4D.

Referring to FIG. 4A, the A-th ramp buffer CRB[A] may be configured to buffer the ramp signal RAMP to output the A-th ramp buffer output CRB_OUT[A]. For example, the A-th ramp buffer CRB[A] may include an A-th current bias circuit CB[A] and an A-th driving transistor MPd[A]. In an example embodiment, the A-th driving transistor MPd[A] may be a P-channel Metal-Oxide-Semiconductor (PMOS) transistor.

The A-th current bias circuit CB[A] may be connected between the power supply voltage Vpix and the A-th node n[A], and may be configured to generate or flow a predetermined bias current. The A-th driving transistor MPd[A] may be connected between the A-th node n[A] and the ground voltage VSS, and may operate in response to the ramp signal RAMP. The A-th ramp buffer output CRB_OUT[A] may be output through the A-th node n[A]. For example, the current flowing through the A-th driving transistor MPd[A] may vary in response to the level of the ramp signal RAMP. That is, as the level of the ramp signal RAMP decreases, the current flowing through the A-th driving transistor MPd[A] may increase, and accordingly, the A-th ramp buffer output CRB_OUT[A] may decrease. Therefore, the A-th ramp buffer output CRB_OUT[A] may be a signal in which the ramp signal RAMP is buffered.

The A-th ADC circuit ADC[A] may include an A-th non-inverting input capacitor Cp[A], an A-th inverting input capacitor Mn[A], a 1A-th amplifier OTA1[A], a 2A-th amplifier OTA2[A], and an A-th counter CNT[A], and 1A and 2A auto-zero switches AZS1[A] and AZS2[A].

The A-th non-inverting input capacitor Cp[A] may be connected between the A-th ramp buffer output CRB_OUT[A] of the A-th ramp buffer CRB[A] and the non-inverted input terminal (+) of the 1A-th amplifier OTA1[A]. The A-th inverting input capacitor Cn[A] may be connected between the A-th pixel voltage VPIX[A] and the inverting input terminal (−) of the 1A-th amplifier OTA1[A].

The 1A-th amplifier OTA1[A] may compare the A-th non-inverting input INp[A] and the A-th inverting input INn[A], and output a comparison result. In an example embodiment, the 1A-th amplifier OTA1[A] may be an operational transconductance amplifier (OTA). For example, when the A-th non-inverting input INp[A] is higher than the A-th inverting input INn[A], the A-th amplifier OTA1[A] may output a high level to a A-th not-inverting output OUTp[A] and output a low level to a A-th inverting output OUTn[A]. Conversely, when the A-th non-inverting input INp[A] is lower than the A-th inverting input INn[A], the 1A-th amplifier OTA1[A] may output a low level to the A-th non-inverting output OUTp[A] and output a high level to the A-th inverting output OUTn[A].

For example, as shown in FIG. 4B, the 1A-th amplifier OTA1[A] may include a first PMOS transistor MP1, a second PMOS transistor MP2, a first NMOS transistor MN1, a second NMOS transistor MN2, and a 0-th NMOS transistor MN0.

The first PMOS transistor MP1 may be connected between the power supply voltage Vpix and the A-th inverting output OUTn[A]. The second PMOS transistor MP2 may be connected between the power supply voltage Vpix and the A-th non-inverting output OUTp[A]. A gate electrode of the first PMOS transistor MP1 and a gate electrode of the second PMOS transistor MP2 may be connected to the A-th inverting output OUTn[A]. The first NMOS transistor MN1 may be connected between the A-th inverted output OUTn[A] and one end of the 0-th NMOS transistors MN0. A gate electrode of the first NMOS transistor MN1 may be connected to the A-th non-inverting input INp[A]. The second NMOS transistor MN2 may be connected between the non-inverting output OUTp[A] and one end of the zeroth NMOS transistors MN0. A gate electrode of the second NMOS transistor MN2 may be connected to the A-th inverting input INn[A]. The other end of the 0-th NMOS transistor MN0 may be connected to the ground voltage VSS, and the gate electrode of the 0-th NMOS transistor MN0 may operate in response to the current bias circuit signal CB.

As shown in FIG. 4B, the 1A-th amplifier OTA1[A] may have a structure of an operational transconductance amplifier (OTA) configured to compare the A-th non-inverting input INp[A] and the A-th inverting input INn[A], and output a comparison result.

In an example embodiment, the 1A-th amplifier OTA1[A] may perform an auto-zeroing operation before performing a sampling operation. For example, the 1A-th auto-zero switch AZS1[A] may be connected between the A-th inverting output OUTn[A] and the A-th non-inverting input INp[A], and the 2A-th auto-zero switch AZS2[A] may also be connected between the a-th non-inverting output OUTp[A] and an A-th inverting input INn[A].

The auto-zero switches AZS1[A] and AZS2[B] may operate in response to the auto-zero signal AZ. As an example, as the 1A-th auto-zero switch AZS1[A] is turned on in response to the auto-zero signal AZ, the levels of the A-th inverted output OUTn[A] and the A-th non-inverted input INp[A] may be equalized, and as the 2A-th auto-zero switch AZS2[A] is turned on in response to the auto-zero signals AZ, the level of the A-th non-inverting output OUTp[A] and the A-th inverted input INn[A] may also be equalized.

The 2A-th amplifier OTA2[A] may invert and output the A-th non-inverting output OUTp[A] of the 1A-th amplifier OTA1[A]. In an example embodiment, the output of the 2A-th amplifier OTA2[A] may be the A-th comparison signal COMP[A]. In an example embodiment, the 2A-th amplifier OTA2[A] may be an operational transconductance amplifier (OTA).

Therefore, when the A-th ramp buffer output CRB_OUT[A] corresponding to the ramp signal RAMP is higher than the A-th pixel signal VPIX[A], the A-th comparison signal COMP[A] may be at a logic low level, and when the first ramp buffer output CRB_OUT[A] corresponding to the A-th ramp signal RAMP is lower than the A-th pixel signal VPIX[A], the A-th comparative signal COMP[A] may be at the logic high level. The A-th counter CNT[A] may store or output a corresponding digital value in response to the A-th comparison signal COMP[A] or the A-th comparison signal COMP[A] of the logic high level.

The B-th ramp buffer CRB[B] may include a B-th current bias circuit CB[B] and a B-th driving PMOS transistor MPd[B], and may output the B-th ramp buffer output CRB_OUT[B] in response to the ramp signal RAMP. The B-th ADC circuit ADC[B] may include a B-th non-inverting input capacitor Cp[B], a B-th inverting input capacitor Cn[B], a 1B-th amplifier OTA1[B], a 2B-th amplifier OTA2[B], a B-th counter CNT[B], and auto-zero switches AZS1[B] and AZS2[B]. In an example embodiment, the structure and operation of the B-th ramp buffer CRB[B] and the B-th ADC circuit ADC[B] are similar to those of the A-th ramp buffer CRB[A] and the A-th ADC circuit ADC[A], and thus a detailed description thereof is omitted.

In one example embodiment, the A-th and B-th ramp buffers CRB[A], CRB[B] may operate in response to the same bias signal. That is, the outputs CRB_OUT[A] and CRB_OUT[B] of the A-th and B-th ramp buffers CRB[A] and CRB[B] may be substantially the same or similar.

For example, as shown in FIG. 4C, the first ramp buffer CRB[A] e an A-th driving transistor MPd[A], a 1A-th bias transistor MPb1[A], and a 2A-th bias transistor MPb2[A]. In an example embodiment, each of the A-th driving transistor MPd[A], the 1A-th bias transistor MPb1[A], and the 2A-th bias transistor MPb2[A] may be a PMOS transistor.

The A-th driving transistor MPd[A], the 1A-th bias transistor MPb1[A], and the 2A-th biased transistor MPb2[A] may be connected in series between the ground voltage VSS and the power supply voltage Vpix. The A-th driving transistor MPd[A] may operate in response to the ramp signal RAMP, the 1A-th bias transistor MPb1[A] may operate in response to a first bias signal CP, and the 2A-th bias transistor MPb2[A] may operate in response to a second bias signal BP.

The B-th ramp buffer CRB[B] may include a B-th driving transistor MPd[B], a 1B-th bias transistor MPb1[B], and a 2B-th bias transistor MPb2[B]. Each of the B-th driving transistor MPd[B], the 1B-th bias transistor MPb1[B], and the 2B-th bias transistor MPb2[B] may be a PMOS transistor.

The B-th driving transistor MPd[B], the 1B-th bias transistor MPb1[B], and the 2B-th bias transistor MPb2[B] may be connected in series between the ground voltage VSS and the power supply voltage Vpix. The B-th driving transistor MPd[B] may operate in response to the ramp signal RAMP, the 1B-th bias transistor MPb1[B] may operate in response to the first bias signal CP, and the 2B-th bias transistor MPb2[B] may operate in response to the second bias signal BP.

In an example embodiment, the first and second bias signals CP and BP may be signals generated by the ramp buffer controller 150. As described above, the 1A-th and 2A-th bias transistors MPb1[A] and MPb2[A] of the A-th ramp buffer CRB[A] and the 1B-th and 2B-th bias transistors MPb1[B] and MPb2[B] of the B-th ramp buffer CRB[B] may share the same bias signals CP and BP.

In this case, the first bias current i_{b1} flowing in the A-th ramp buffer CRB[A] and the second bias current i_{b2} flowing in the B-th ramp buffer CRB[B] may have the same or similar magnitude (e.g., i_{ref}) or may be driven at the same or similar timing. In this case, the first ramp buffer output CRB_OUT[A] output through the A-th node n[A] and the second ramp buffer output CRB_OUT[B] output through the B-th node n[B] may be driven with the same or similar magnitude or with the same or similar timing.

In an example embodiment, the A-th ADC circuit ADC[A] may perform a sampling operation by comparing the A-th ramp buffer output CRB_OUT[A] and the A-th pixel voltage VPIX[A], and the B-th ADC circuit ADC[B] may perform a sample operation by comparing the B-th ramp buffer output CRB_OUT[B] and the B-th pixel voltage VPIX[B]. In this case, the A-th pixel voltage VPIX[A] may be a voltage output from a first pixel connected to the A-th column line CL[A] among a plurality of pixels included in the pixel array 110, and the B-th pixel voltage VPIX[B] may be a voltage output from a second pixel connected to the B-th column line CL[B] among a plurality the pixels included in the pixels array 110. The first and second pixels may operate in response to the same selection signal SEL. The first and second pixels may be located in the same row or in different rows.

Hereinafter, for brevity of the drawings and ease of description, example embodiments are described with reference to a reset sampling operation of the ADC circuits. However, example embodiments are not limited thereto, and the ADC circuits may perform a reset sampling operation and a signal sampling operation. Further, depending on the structure of the pixel, the ADC circuits may perform a sampling operation according to a high conversion gain and a low conversion gain.

As shown in FIG. 4D, the A-th ADC circuit ADC[A] and the B-th ADC circuit ADC[B] may perform a reset sampling operation. For example, during a period between the first to second time points (t1-t2), the auto-zero signal AZ may maintain a high level. In this case, in response to the auto-zero signal AZ of the high level, the A-th ADC circuit ADC[A] and the B-th ADC circuit ADC[B] may perform the auto-zero operation. As an example, in the auto-zero period (AZ Period), the auto zero switches AZS1[A], AZS2[A], AZS1[B], and AZS2[B] are turned on, and thus the inverting inputs INn[A] and INn[B] and the non-inverting inputs INP[A] and INP[B] of the amplifiers OTA1[A] and OTA1[B] may be initialized.

Thereafter, in a period between the third to fifth time points (t3-t5), the A-th ADC circuit ADC[A] and the B-th ADC circuit ADC[B] may perform reset sampling. For example, in the period of the third to fifth time points (t3-t5), the ramp generator 140 may generate the ramp signal RAMP. In response to the ramp signal RAMP, the A-th ramp buffer CRB[A] may generate the A-th ramp buffer output CRB_OUT[A], and the B-th ramp buffer CRB[B] may generate the B-th ramp buffer output CRB_OUT[B]. In an example embodiment, the A-th and B-th ramp buffers CRB[A] and CRB[B] operate using the same bias signals BP and CP, therefore the A-th and B-th ramp buffer outputs CRB_OUT[A] and CRB_OUT[B] may be substantially the same or similar.

The A-th ramp buffer output CRB_OUT[A] may be provided to the A-th non-inverting input INp[A] through the A-th non-inverting input capacitor Cp[A] of the A-th ADC circuit ADC[A]. The B-th ramp buffer output CRB_OUT[B] may be provided to the second non-inverting input INp[B] through the B-th non-inverting input capacitor Cp[B] of the B-th ADC circuit ADC[B]. That is, in the period of the third to fifth time points (t3-t5), the A-th and B-th non-inverting inputs INp[A] and INp[B] may decrease in a waveform similar to the A-th and B-th ramp buffer outputs CRB_OUT[A] and CRB_OUT[B], respectively.

The A-th ADC circuit ADC[A] may compare the A-th non-inverting input INp[A] with the A-th inverting input INn[A]. The B-th ADC circuit ADC[B] may compare the B-th non-inverting input INp[B] with the B-th inverting input INn[B]. In this case, the A-th inverting input INn[A] may correspond to a reset level of the A-th pixel voltage VPIX[A], and the B-th inverting input INn[B] may correspond to a reset level of the B-th pixel voltage VPIX[B].

In this case, the A-th and B-th non-inverting inputs INp[A] and INp[B] have similar waveforms, and the A-th and B-th inverting inputs INn[A], INn[B] may have similar levels. Therefore, a time point at which the A-th non-inverting input INp[A] becomes lower than the A-th inverting input INn[A] and a time point at that the B-th non-inverting input INp[B] becomes lower than the B-th inverting input INn[B] may be the same time point (for example, the fourth time point t4). In this case, the A-th and B-th comparison signals COMP[A] and COMP[B] generated from the A-th and the B-th ADC circuits ADC[A] and ADC[B] may be changed to a high level at the same time or within a short time period.

At a time when the A-th and B-th comparison signals COMP[A] and COMP[B] are changed to a high level, fluctuation may occur in the power supply voltage Vpix connected to the ADC circuits. Alternatively or additionally, a variation may occur in the ground voltage VSS connected to the ADC circuits. That is, in the reset sampling period, when the plurality of ADC circuits ADC[A] to ADC[n] are sampled at the same time or within a short time period (that is, when the comparison signal is output at the same time), noise due to a sudden fluctuation in the power supply voltage or the ground voltage may occur. This degrades the overall operational reliability of the image sensor device.

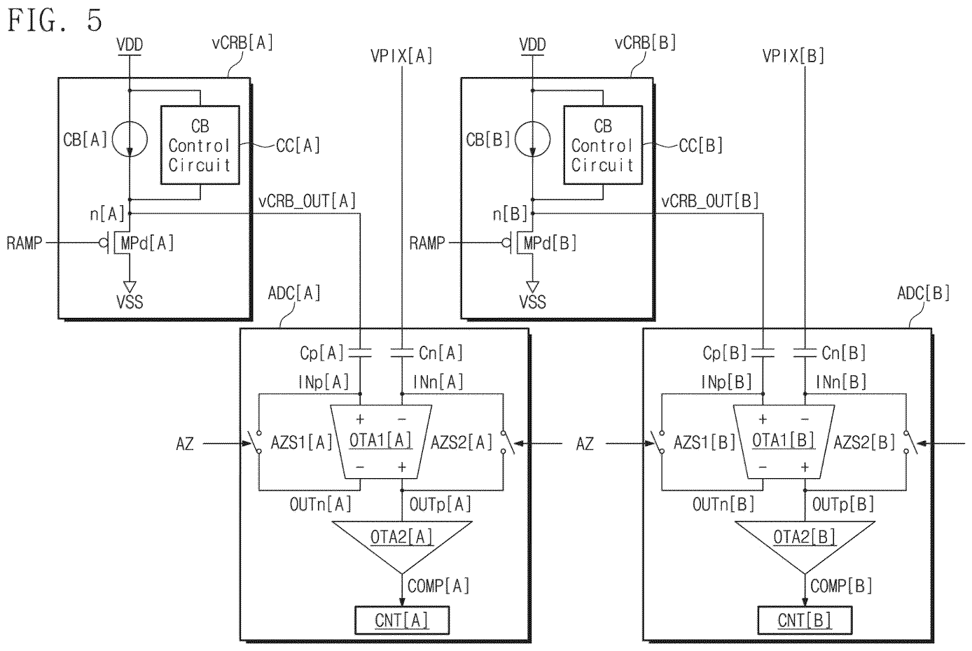

FIG. 5 is a block diagram showing a variable ramp buffer and an ADC circuit of the image sensor device of FIG. 1. For ease of description, detailed descriptions of the above-described components are omitted. Referring to FIGS. 1 and 5, the image sensor device 100 may include an A-th variable ramp buffer vCRB[A], a B-th variable ramp buffer vCRB[B], an A-th ADC circuit ADC[A], and a B-th ADC circuit ADC[B]. Because the A-th ADC circuit ADC[A] and the B-th ADC circuit ADC[B] have been described with reference to FIG. 4A, a detailed description thereof is omitted.

In response to the ramp signal RAMP, the A-th variable ramp buffer vCRB[A] may generate or output an A-th ramp output voltage vCRB_OUT[A] (hereinafter, for convenience of description, the output of the variable ramp buffer is referred to as a “ramp output voltage”). For example, the A-th variable ramp buffer vCRB[A] may include an A-th driving transistor MPd[A], an A-th current bias circuit CB[A], and an A-th current control circuit CC[A]. In an example embodiment, the A-th driving transistor MPd[A] and the A-th current bias circuit CB[A] are similar to those described with reference to FIG. 4A, and thus a detailed description thereof is omitted.

The A-th current control circuit CC[A] may be configured to control a bias current generated by or flowing through the A-th current bias circuit CB[A]. In an example embodiment, when the bias current of the A-th variable ramp buffer vCRB[A] is varied, the level of the A-th ramp output voltage vCRB_OUT[A] may be varied. For example, when the bias current decreases, the level of the A-th ramp output voltage vCRB_OUT[A] may decrease. When the bias current increases, the level of the A-th ramp output voltage vCRB_OUT[A] may increase.

The B-th variable ramp buffer vCRB[B] may generate the B-th ramp output voltage vCRB_OUT[B] in response to the ramp signal RAMP. For example, the B-th variable ramp buffer vCRB[B] may include a driving transistor MPd[B], a B-th current bias circuit CB[B], and a B-th current control circuit CC[B]. In an example embodiment, the B-th driving transistor MPd[B] and the B-th current bias circuit CB[B] are similar to those described with reference to FIG. 4A, and thus a detailed description thereof is omitted.

The B-th current control circuit CC[B] may be configured to control a bias current generated by or flowing through the B-th current bias circuit CB[B]. Because the operation of the B-th current control circuit CC[B] is similar to the operation of the A-th current control circuit CC[A], a detailed description thereof is omitted.

In an example embodiment, the A-th and B-th driving transistors MPd[A] and MPd[B] may operate in response to the same ramp signal RAMP. The A-th and B-th current bias circuits CB[A] and CB[B] may operate in response to the same bias signals. On the other hand, the A-th current control circuit CC[A] and the B-th current control Circuit CC[B] may operate in response to different control signals.

That is, as the A-th current control circuit CC[A] and the B-th current control circuit CC[B] are individually controlled, the bias currents of the A-th and B-th variable ramp buffers vCRB[A] and vCRB[B] may be individually controlled. Accordingly, the A-th and B-th ramp output voltages vCRB_OUT[A] and vCRB_OUT[B] may also be individually controlled.

By individually controlling the A-th and B-th ramp output voltages vCRB_OUT[A] and vCRB_OUT[B], the A-th non-inverting input INp[A] of the A-th ADC circuit ADC[A] and the B-th non-inverting input INp[B] of the B-th ADC Circuit ADC[B] may have a predetermined offset. In this case, even if the A-th and B-th pixel voltages VPIX[A] and VPIX[B] have the same or similar level, the sampling time point of the A-th and the B-th ADC circuits ADC[A] and ADC[B] (i.e., the time points at which the A-th and a B-th comparison signals COMP[A] and COMP[B] become high level) may be distributed. Accordingly, a sudden fluctuation in the power supply voltage Vpix or the ground voltage VSS may be prevented. The structure and operation of a variable ramp buffer according to an example embodiment are described in more detail with reference to the following drawings.

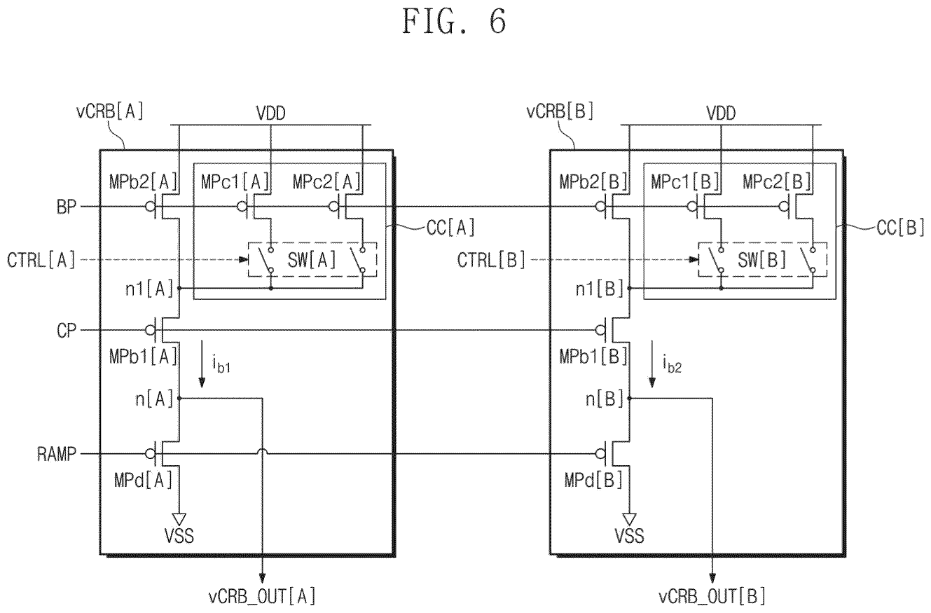

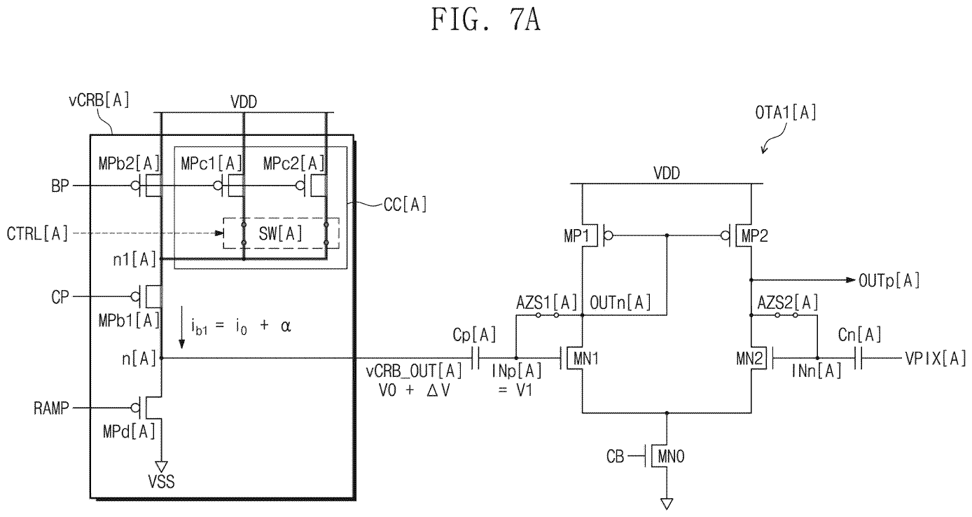

FIG. 6 is a circuit diagram showing the variable ramp buffers of FIG. 5. Referring to FIGS. 1, 5, and 6, the A-th variable ramp buffer CRB[A] may include an A-th driving transistor MPd[A], a 1A-th bias transistor MPb1[A], a 2A-th bias transistor MPb2[A], and an A-th current control circuit CC[A]. The A-th current control circuit CC[A] may include a 1A-th control transistor MPc1[A], a 2A-th control transistor MPc2[A], and an A-th control switch circuit SW[A]. In an example embodiment, each of the A-th driving transistor MPd[A], the 1A-th bias transistor MPb1[A], the 2A-th bias transistor MPb2[A], the 1A-th control transistor MPc1[A], and the 2A-th control transistor MPc2[A] may be a PMOS transistor.

The A-th driving transistor MPd[A], the 1A-th bias transistor MPb1[A], and the 2A-th bias transistor MPb2[A] may be connected in series between the ground voltage VSS and the power supply voltage Vpix. The 1A-th control transistor MPc1[A] may be connected between the power supply voltage Vpix and the A-th control switch circuit SW[A]. The 2A-th control transistor MPc2[A] may be connected between the power supply voltage Vpix and the A-th control switch circuit SW[A].

The A-th control switch circuit SW[A] may include a plurality of control switches. For example, one of a plurality of control switches of the A-th control switch circuit SW[A] may be configured to switch between the 1A-th node n1[A] and the 1A-th control transistor MPc1[A]. Other one of the plurality of control switches of the A-th control switch circuit SW[A] may be configured to switch between the 1A-th node n1[A] and the 2A-th control transistor MPc2[A]. The 1A-th node n1[A] may be a node between the 1A-th and 2A-th bias transistors MPb1[A] and MPb2[A].

The B-th variable ramp buffer vCRB[B] may include a B-th driving transistor MPd[B], a 1B-th bias transistor MPb1[B], a 2B-th bias transistor MPb2[B], and a B-th current control circuit CC[B]. The B-th current control circuit CC[B] may include a 1B-th control transistor MPc1[B], a 2B-th control transistor MPc2, and a B-th control switch circuit SW[B]. In an example embodiment, each of the B-th driving transistor MPd[B], the 1B-th bias transistor MPb1[B], the 2B-th bias transistor MPb2[B], and the 1B-th control transistor MPc1[B] and the 2B-th control transistor MPc2[B] may be a PMOS transistor.

The B-th driving transistor MPd[B], the 1B-th bias transistor MPb1[B], and the 2B-th bias transistor MPb2[B] may be connected in series between the ground voltage VSS and the power supply voltage Vpix. The 1B-th control transistor MPc1[B] may be connected between the power supply voltage Vpix and the B-th control switch circuit SW[B]. The 2B-th control transistor MPc2[B] may be connected between the power supply voltage Vpix and the B-th control switch circuit SW[B].

The B-th control switch circuit SW[B] may include a plurality of control switches. For example, one of a plurality of control switches of the B-th control switch circuit SW[B] may be configured to switch between the 1B-th node n1[B] and the 1B-th control transistor MPc1[B]. Other one of the plurality of control switches of the B-th control switch circuit SW[B] may be configured to switch between the 1B-th node n1[B] and the 2B-th control transistor MPc2[B]. The 1B-th node n1[B] may be a node between the 1B-th and 2B-th bias transistors MPb1[B] and MPb2[B].

The A-th and B-th driving transistors MPd[A] and MPd[A] may operate in response to the ramp signal RAMP. The 1A-th and 1B-th bias transistors MPb1[A] and MPb1[B] may operate in response to the first bias signal CP. Each of the 2A-th and 2B-th bias transistors MPb2[A] and MPb2[B], the 1A-th, 1B-th, 2A-th, and the 2B-th control transistors MPc1[A], MPc1[B], MPc2[A], and MPc2[A] may operate in response to the second bias signal BP.

In an example embodiment, the magnitudes of the first and second bias currents i_{b1} and i_{b2} may be adjusted according to switching operations of the A-th control switch circuit SW[A] and the B-th control switch circuit SW[B]. In an example embodiment, the first bias current i_{b1} may refer to a current provided to the A-th node n[A]. The second bias current i_{b2} may refer to a current provided to the B-th node n[B]. The first and second bias currents i_{b1} and i_{b2} may be determined based on a connection structure, an effective size (e.g., W/L, etc.), or a gate voltage (e.g., a size of bias signals) of the bias transistors and the control transistors.

For example, the A-th control switch circuit SW[A] may operate in response to the A-th control signal CTRL[A], and the B-th control switch circuit SW[B] may operate in responses to the B-th control signal CTRL[B]. That is, the A-th and B-th control switch circuits SW[A] and SW[B] may be individually controlled. In one example embodiment, the A-th and B-th control signals CTRL[A] and CTRL[B] may be generated by the ramp buffer controller 150 of FIG. 1.

When the 1A-th and 2A-th control transistors MPc1[A] and MPc2[A] are connected to the 1A-th node n1[A] by the A-th control switch circuit SW[A], the 2A-th bias transistor MPb2[A] and the 1A-th and 2A-th control transistors MPb1[A], MPc2[A], that operate in response to the second bias signal BP, are connected in parallel. In this case, because the effective width of the channel of the transistor operating in response to the second bias signal BP increases, the first bias current i_{b1} may relatively increase. When the first bias current i_{b1} increases relatively, the A-th ramp output voltage vCRB_OUT[A] output through the A-th node n[A] may increase.

As another example, when the 1B-th and 2B-th control transistors MPc1[B] and MPc2[B] are not connected to the 1B-th node n1[B] by the B-th control switch circuit SW[B], only the 2B bias transistor MPb2[B] operates in response to the second bias signal BP, thereby relatively reducing the second bias current i_{b2}. When the second bias current i_{b2} decreases relatively, the B-th ramp output voltage vCRB_OUT[B] output through the B-th node n[B] may decrease.

As described above, by the operation of the A-th and B-th control switch circuits SW[A] and SW[B], the first and second bias currents i_{b1} and i_{b2} may be individually controlled, and thus the first and second ramp output voltages vCRB_OUT[A], vCRB_OUT[B] may be individually controlled.

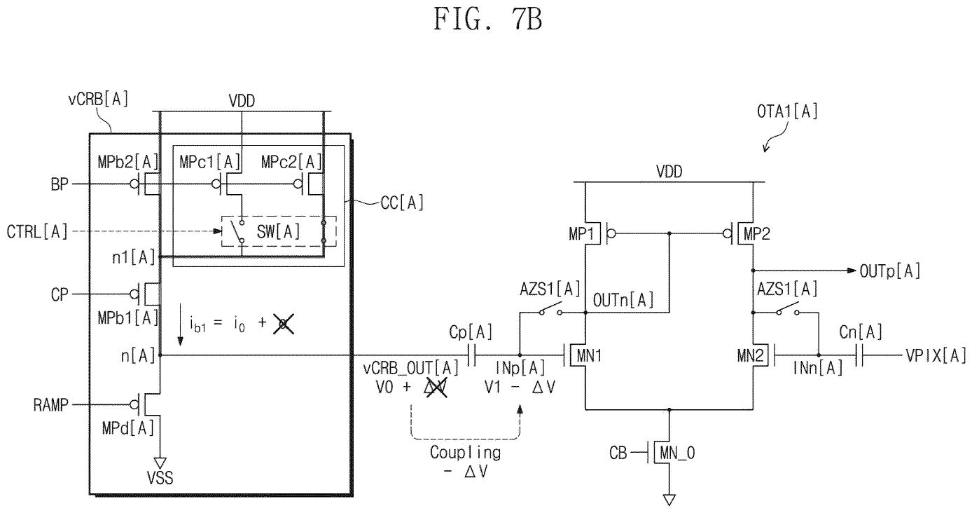

FIGS. 7A and 7B are diagrams for describing an operation of applying an offset to an inverting input terminal of the first amplifier by an operation of the A-th variable ramp buffer of FIG. 6. Referring to FIGS. 7A and 7B, the A-th variable ramp buffer vCRB[A] may include an A-th driving transistor MPd[A], first and 2A-th bias transistors MPb1[A] and MPb2[A], 1A-th and 2A-th control transistors MPc1[A] and MPc2[A], and an A-th control switch circuit SW[A]. The 1A-th amplifier OTA1[A] may include a plurality of transistors MP1, MP2, MN0, MN1, and MN2, auto-zero switches AZS1[A] and AZS2[A], and input capacitors Cp[A] and Cn[A]. Because the structures of the A-th variable ramp buffer vCRB[A] and the 1A-th amplifier OTA1[A] have been described above, a detailed description thereof is omitted.

First, referring to FIG. 7A, the A-th variable ramp buffer vCRB[A] may generate the A-th ramp output voltage vCRB_OUT[A] in response to the ramp signal RAMP. The 1A-th amplifier OTA1[A] may receive the A-th ramp output voltage vCRB_OUT[A] as the A-th non-inverting input INp[A] through the A-th non-inverting input capacitor Cp[A]. The 1A-th amplifier OTA1[A] may receive the A-th pixel voltage VPIX[A] as the A-th inverting input INn[A] through the A-th inverting input capacitor Cn[A].

The 1A-th amplifier OTA1[A] may perform an auto-zero operation before performing a comparison operation. For example, in response to the auto-zero signal AZ, the 1A-th and 2A-th auto-zero switches AZS1[A] and AZS2[A] of the 1A-th amplifier OTA1[A] may be turned on. Accordingly, the A-th non-inverting input INp[A] and the A-th inverting input INn[A] may be initialized. As an example, it is assumed that the A-th non-inverting input INp[A] is set to the first voltage V1 by the auto-zero operation.

While the auto-zero operation is performed, the A-th control switch circuit SW[A] of the A-th variable ramp buffer vCRB[A] may be turned on in response to the A-th control signal CTRL[A]. For example, the 1A-th and 2A-th control transistors MPc1[A] and MPc2[A] may be connected to the 1A-th node n1[A] by the A-th control switch circuit SW[A].

Accordingly, the first bias current i_{b1} may be generated through the 1A-th and 2A-th control transistors MPc1[A] and MPc2[A] and the 2A-th bias transistor MPb2[A]. In this case, the first bias current i_{b1} may have a magnitude of i₀+α. When the first bias current i_{b1} has a magnitude of i₀+α, the A-th ramp output voltage vCRB_OUT[A] may have a magnitude of V0+ΔV. That is, in the auto-zero operation of the first amplifier OTA1[A], the first ramp output voltage vCRB_OUT[A] may have a magnitude of V0+ΔV and the first non-inverting input INp[A] of the first amplifier OTA1[A] may has a magnitude of V1.

Next, referring to FIG. 7B, the A-th amplifier OTA1[A] may complete the auto-zero operation. In this case, the 1A-th and 2A-th auto-zero switches AZS1[A] and AZS2[A] may be turned off, and some control switches in the A-th control switch circuit SW[A] of the A-th variable ramp buffer vCRB[A] may be turned off. For example, a control switch between the 1A-th control transistor MPc1[A] and the 1A-th node n1[A] may be turned off. In this case, because the first bias current i_{b1} is generated by the 2A-th bias transistor MPb2[A] and the 2A-th control transistor MPc2[A], the first bias current i_{b1} may be relatively reduced.

As an example, the first bias current i_{b1} may decrease from i₀+α to i₀ (i.e., decreases by α). As the first bias current i_{b1} decreases to i₀, the A-th ramp output voltage vCRB_OUT[A] may decrease from V0+ΔV to V0 (i.e., decreases by ΔV). As the A-th ramp output voltage vCRB_OUT[A] decreases, the A-th non-inverting input INp[A] may decrease by ΔV by the A-th non-inverting input capacitor Cp[A]. As a result, after the auto-zero operation, the A-th non-inverting input INp[A] of the 1A-th amplifier OTA1[A] may be adjusted to V1−ΔV by the operation of the A-th variable ramp buffer vCRB[A]. In this regard, an offset of −ΔV may be applied to the A-th non-inverting input INp[A] of the 1A-th amplifier OTA1[A].

As described above, as the bias current of the variable ramp buffer may be individually controlled, the offset may be individually adjusted to the non-inverting input that is input to the plurality of ADC circuits. In this case, the sampling timing of the plurality of ADC circuits may be distributed.

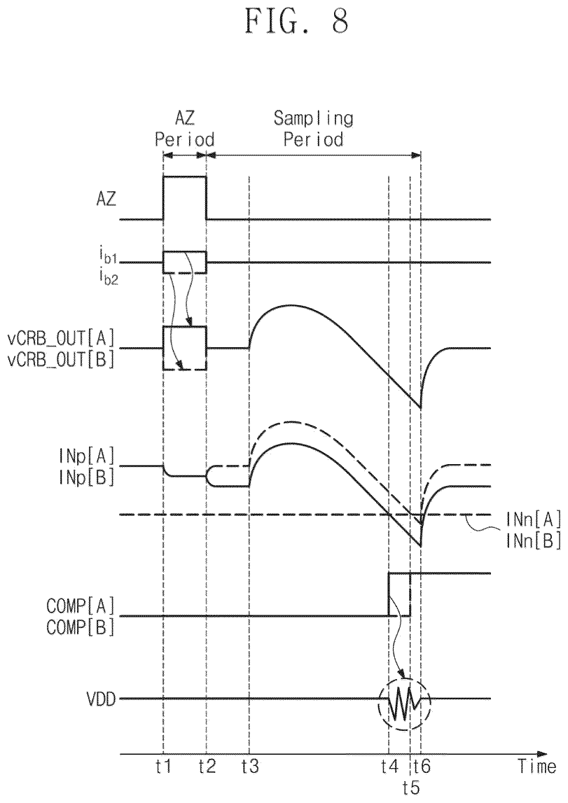

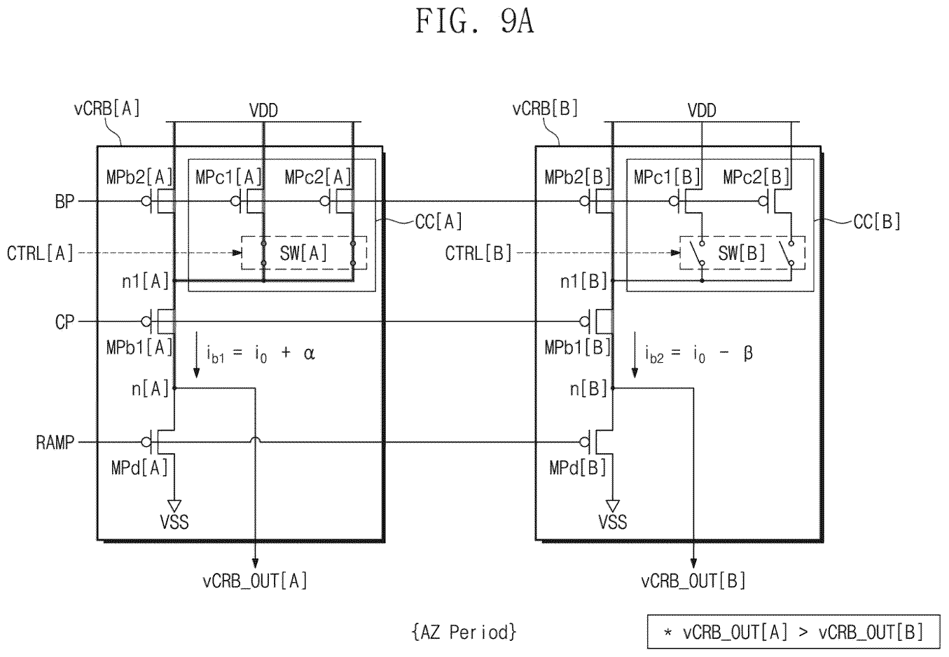

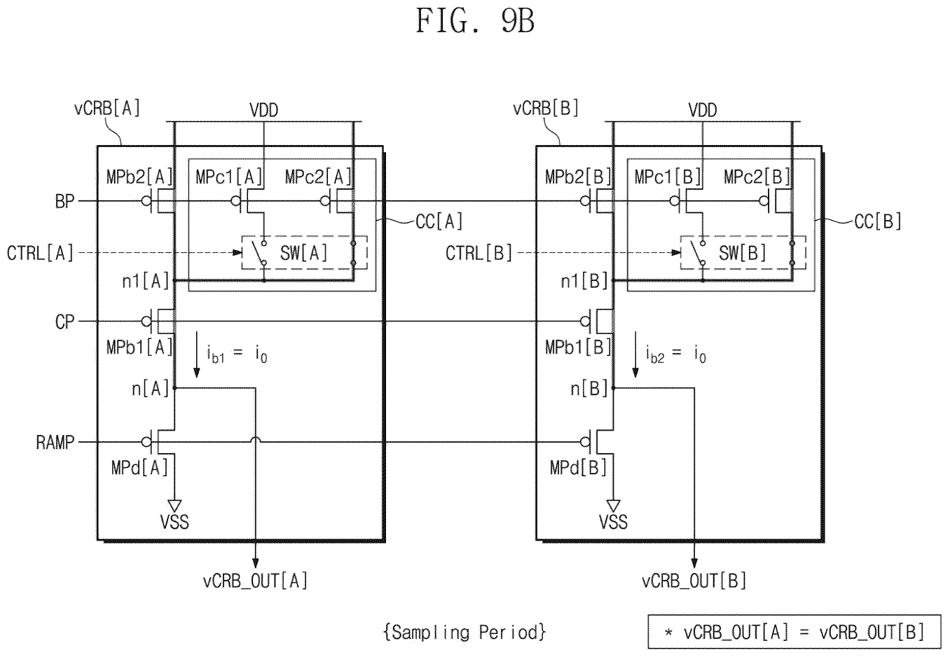

FIG. 8 is a timing diagram showing operation of the variable ramp buffers and ADC circuits of FIG. 5. FIGS. 9A and 9B are diagrams for describing operation of variable ramp buffers according to the timing diagram of FIG. 8. Referring to FIGS. 5, 6, 8, 9A, and 9B, in a period between the first to second time points (t1-t2), the A-th and B-th ADC circuits ADC[A] and ADC[B] may perform an auto-zero operation. For example, in the period between the first to second time points (t1-t2), the auto-zero signal AZ may maintain a high level. In response to the auto-zero signal AZ of the high level, the auto-zero switches AZS1[A], AZS2[A], AZS1[B], and AZS2[B] of the A-th and B-th ADC circuits ADC[A] and ADC[B] may be turned on. Accordingly, the A-th and B-th non-inverting inputs INp[A] and INp[B] may be set to a predetermined level.

The period between the first to second time points (t1-t2) (i.e., during the auto-zero operation), the A-th and B-th variable ramp buffers vCRB[A] and vCRB[B] may adjust the first and second bias currents i_{b1} and i_{b2} to adjust the A-th and B-th ramp output voltages vCRB_OUT[A] and vCRB_OUT[B], respectively.

For example, as shown in FIG. 9A, the A-th control switch circuit SW[A] of the A-th variable ramp buffer vCRB[A] may connect the 1A-th and 2A-th control transistors MPc1[A] and MPc2[A] with the 1A-th node n1[A] in response to the A-th controller signal CTRL[A]. In this case, the first bias current i_{b1} may be generated through the first path including the 2A-th bias transistor MPb2[A] and the 1A-th and 2A-th control transistors MPc1[A] and MPc2[A]. In this case, the first bias current i_{b1} may have a magnitude of i₀+α. The B-th control switch circuit SW[B] of the B-th variable ramp buffer vCRB[B] may not connect the 1B-th and 2B-th control transistors MPc1[B] and MPc2[B] to the 1B-th node n1[B] in response to the B-th control signal CTRL[B]. In this case, the second bias current i_{b2} may be generated through the second path including the 2B-th bias transistor MPb2[B]. At this time, the second bias current i_{b2} may have a magnitude of i₀−β. As described above, because the first bias current i_{b1} is greater than the second bias current i_{b2}, the A-th ramp output voltage vCRB_OUT[A] may be greater than the B-th ramp output voltage VCRB_OUT[B].

In an example embodiment, during the auto-zero operation, the non-inverting input terminals INp[A] and INp[B] of the A-th and B-th ADC circuits ADC[A] and ADC[B] may be set to a specific level, and each of the A-th ramp output voltages vCRB_OUT[A] and vCRB_out[B] may be set to a different level.

Referring again to FIG. 8, at a second time point t2, the auto-zero operation ends. For example, at the second time point t2, the auto-zero signal AZ is changed to a low level. In response to the low level of auto-zero signal AZ, the auto-zero switches AZS1[A], AZS2[A], AZS1[B], and AZS2[B] of the A-th and B-th ADC circuits ADC[A] and ADC[B] may be turned off.

At the second time point t2, the A-th and B-th variable ramp buffers vCRB[A] and vCRB[B] may adjust the first and second bias currents i_{b1}, i_{b2} to adjust the A-th and the B-th ramp output voltages vCRB_OUT[A] and vCRB_out[B], respectively. For example, as illustrated in FIG. 9B, the A-th control switch circuit SW[A] of the A-th variable ramp buffer vCRB[A] may connect the 2A-th control transistor MPc2[A] to a first A-th node n1[A] and disconnect the 1A-th control transistor MPc1[A] to the first A-th nodes n1[A]. In this case, the first bias current i_{b1} may be generated through the 2A-th bias transistor MPb2[A] and the 2A-th control transistor MPc2[A]. At this time, the first bias current i_{b1} may decrease to a magnitude of i₀. As the first bias current i_{b1} decreases, the magnitude of the A-th ramp output voltage vCRB_OUT[A] may decrease.

The B-th control switch circuit SW[B] of the B-th variable ramp buffer vCRB[B] may connect the 1B-th control transistor MPc2[B] to the 1B-th node n1[B] and disconnect the 1B-th control transistor MPc1[B] to the 1B-th nodes n1[B]. In this case, the second bias current i_{b2} may be generated through the 2B-th bias transistor MPb2[B] and the 2B-th control transistor MPc2[B]. At this time, the second bias current i_{b2} may increase to a magnitude of i₀. As the second bias current i_{b2} increases, the magnitude of the B-th ramp output voltage vCRB_OUT[B] may increase.

In one example embodiment, because the first and second bias currents i_{b1} and i_{b2} are substantially the same, the A-th and B-th ramp output voltages vCRB_OUT[A] and vCRB_out[B] will be set to the same level.

In an example embodiment, after the auto-zero operation is performed, by the operation of the A-th and B-th variable ramp buffers vCRB[A] and vCRB[B], the A-th ramp output voltage vCRB_OUT[A] may decrease and the B-th ramp output power vCRB_out[B] may increase. In this case, as described with reference to FIG. 7B, the A-th non-inverting input INp[A] may decrease as the A-th ramp output voltage vCRB_OUT[A] decreases, and the B-th non-inverting input INp[B] may increase as the B-th ramp output voltage vCRB_out[B] increases. In this case, the A-th non-inverting input INp[A] and the B-th non-inverting input INp[B] may have a predetermined difference (e.g., offset) from each other. In one example embodiment, an offset between the A-th non-inverting input INp[A] and the B-th non-inverting input INp[B] may be maintained in a subsequent sampling operation.

In an example embodiment, for brevity of the drawings and convenience of description, it is described that the A-th and B-th ramp output voltages vCRB_OUT[A] and vCRB_out[B] are controlled immediately after completing the auto-zero operation (for example, at the second time point t2), but example embodiments are not limited thereto. For example, after a predetermined time elapses from the second time point t2, the A-th and B-th ramp output voltages vCRB_OUT[A] and vCRB_out[B] may be controlled. This is to generate coupling by variation of the A-th and B-th ramp output voltages vCRB_OUT[A] and vCRB_out[B] after the A-th and B-th non-inverting inputs INp[A], INp[B] are floated (i.e., after the auto-zero switches are turned off).

Thereafter, in a period between the third to sixth time points (t3-t6), the A-th and B-th ADC circuits ADC[A] and ADC[B] may perform a sampling operation. For example, the ramp generator 140 may generate a ramp signal RAMP. The A-th and B-th variable ramp buffers vCRB[A] and vCRB[B] may adjust the A-th and the B-th ramp output voltages vCRB_OUT[A] and vCRB_out[B] in response to the ramp signal RAMP. In an example embodiment, during the sampling period, the A-th and B-th ramp output voltages vCRB_OUT[A] and vCRB_out[B] may have the same level or the same waveform. On the other hand, because the A-th non-inverting input INp[A] and the B-th non-inverting input INp[B] have a certain difference (e.g., offset) from each other, even if the levels of the A-th and B-th inverting inputs INn[A] and INn[B] are equal to each other (in this regard, the A-th or B-th pixel voltages VPIX[A] and VPIX[B] are equal to each other), the point in time sampled by the A-th ADC circuits ADC[A] and ADC[B] may be distributed.

For example, the A-th ADC circuit ADC[A] may generate the A-th comparison signal COMP[A] by comparing the A-th non-inverting input INp[A] with the A-th inverting input INn[A], and the B-th ADC circuit ADC[B] may generate the B-th comparison signal COMP[B] by comparing the B-th non-inverting input INp[B] with the B-th inverting input INn[B]. At this time, the A-th non-inverting input INp[A] may be lower than the A-th inverting input INn[A] at the fourth time point t4. In response, an A-th comparison signal COMP[A] may be generated. On the other hand, the B-th non-inverting input INp[B] may be lower than the B-th inverting input INn[B] at a fifth time point t5 after the fourth time point t4. In response, a B-th comparison signal COMP[B] may be generated.

That is, in the reset sampling, the plurality of ADC circuits ADC[A] to ADC[n] are configured to respectively sample reset levels of the plurality of pixel voltages VPIX[A] to VPIX[n]. At this time, because the reset levels of the plurality of pixel voltages VPIX[A] to VPIX[n] have the same or similar level, when sampling is performed using the same ramp signal, a plurality of comparison signals are simultaneously generated at the same time or within a short time. In this case, due to the simultaneous generation of the comparison signal, a sudden fluctuation in the power supply voltage Vpix or the ground voltage VSS may occur.

On the other hand, according to an example embodiment, the variable ramp buffers vCRB may be used to apply different offsets to the non-inverting inputs INp (or an input corresponding to a ramp signal) provided to the amplifiers of the plurality of ADC circuits ADC[A] to ADC[n]. For example, during auto-zero operation on the plurality of ADC circuits ADC[A] to ADC[n], the variable ramp buffers vCRB may individually control each bias current. In this case, the ramp output voltages vCRB_OUT may have different levels. After an auto-zero operation on the plurality of ADC circuits ADC[A] to ADC[n], the variable ramp buffers vCRB may adjust each bias current to a reference current (e.g., i₀). In this case, the ramp output voltages vCRB_OUT may increase or decrease. By increasing or decreasing the ramp output voltages vCRB_OUT, the non-inverting inputs INp provided to the amplifiers of the plurality of ADC circuits ADC[A]-ADC[n] may increase or decrease, respectively, and this increase or decrease may provide an offset between the non-inverting inputs INp. Therefore, because sampling is performed using non-inverting inputs having different offsets in the plurality of ADC circuits ADC[A] to ADC[n], the generation time point of the comparison signal may be distributed. Accordingly, a sudden fluctuation in the power supply voltage Vpix or the ground voltage VSS can be prevented.

In an example embodiment, the plurality of pixel voltages VPIX[A] to VPIX[n] input to the plurality of ADC circuits ADC[A] to ADC[n] may be output from the plurality of pixels of the pixel array 110 through the plurality of column lines CL[A] to CL[n]. In this case, the plurality of pixels may operate in response to the same selection signal SEL. That is, the plurality of pixels may be located in the same row. Alternatively, the plurality of pixels may operate together during one readout operation.

Hereinafter, in order to easily describe example embodiments, the structure or operation of the variable ramp buffer vCRB configured to individually control the outputs of the variable ramp buffer vCRB is mainly described. It will be appreciated, however, that example embodiments are not limited to the specifically described features, and that the following variable ramp buffers may be applied to embodiments described above. That is, when the outputs of the variable ramp buffer vCRB are individually controlled, different offsets may be applied to the inputs of each of the plurality of ADC circuits. Thus, the sampling time point of the ADC circuits is distributed, and a sudden fluctuation in the power supply voltage or the ground voltage may be prevented.

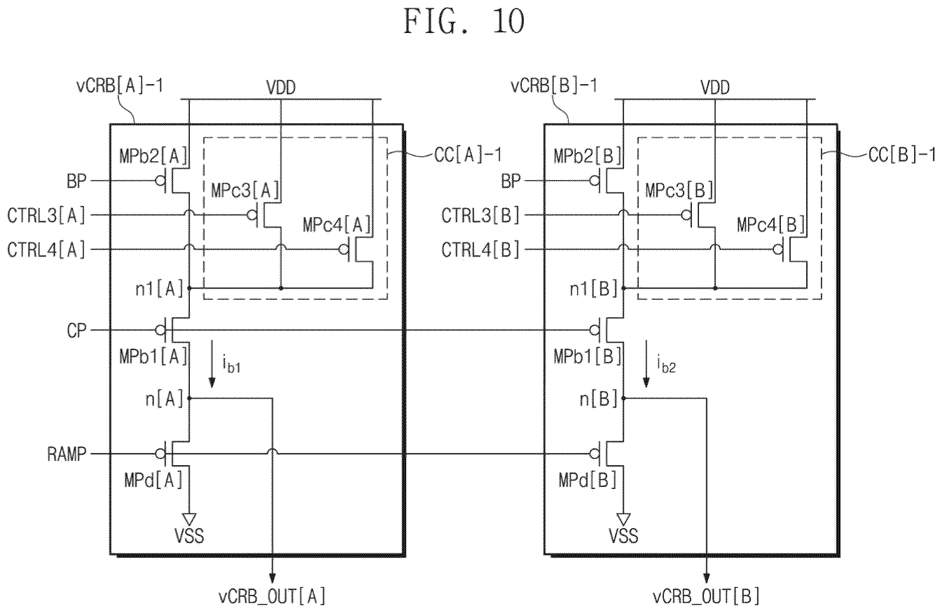

FIG. 10 is a circuit diagram showing the variable ramp buffer of FIG. 1. Referring to FIGS. 1 and 10, the image sensor device 100 may include A-th and B-th variable ramp buffers vCRB[A]-1 and vCRB[B]-1. The A-th and B-th variable ramp buffers vCRB[A]-1 and vCRB[B]-1 may correspond to the A-th and the B-th variable ramp buffers vCRB[A] and vCRB[B] described above, respectively.

The A-th variable ramp buffer vCRB[A]-1 may include an A-th driving transistor MPd[A], a 1A-th bias transistor MPb1[A], a 2A-th bias transistor MPb2[A], and an A-th current control circuit CC[A]-1. The B-th variable ramp buffer vCRB[B]-1 may include a B-th driving transistor MPd[B], a 1B-th bias transistor MPb1[B], the 2B-th bias transistor MPb2[B], and a B-th current control circuit CC[B]-1. Because the A-th driving transistor MPd[A], the 1A-th bias transistor MPb1[A], the 2A-th bias transistor MPb2[A], the B-th driving transistors MPd[B], the 1B-th bias transistor MPb1[B], and the 2B-th bias transistor MPb2[B] have been described above, detailed descriptions thereof are omitted.

The A-th current control circuit CC[A]-1 may include a 3A-th control transistor MPc3[A] and a 4A-th control transistor MPc4[A]. The 3A-th control transistor MPc3[A] may be connected between the power supply voltage Vpix and the 1A-th node n1[A], and may operate in response to the 3A-th control signal CTRL3[A]. The 4A-th control transistor MPc4[A] may be connected between the power supply voltage Vpix and the 1A-th node n1[A], and may operate in response to the 4A-th control signal CTRL4[A].

The B-th current control circuit CC[B]-1 may include a 3B-th control transistor MPc3[B] and a 4B-th control transistor MPc4[B]. The 3B-th control transistor MPc3[B] may connected between the power supply voltage Vpix and the 1B-th node n1[B], and may operate in response to the 3B-th control signal CTRL3[B]. The 4B-th control transistor MPc4[B] may be connected between the power supply voltage Vpix and the 1B-th node n1[B], and may operate in response to the 4B-th control signal CTRL4[B].

As described above, the A-th and B-th variable ramp buffers vCRB[A]-1 and vCRB[B]-1 may control the first and second bias currents i_{b1} and i_{b2}, respectively. For example, during the auto-zero operation, the A-th current control circuit CC[A]-1 may turn on the 3A-th control transistor MPc3[A] and the 4A-th control transistor MPc4[A], and the B-th current control circuit CC[B]-1 may turn off the 3B-th control transistors MPc3[B] and the 4B-th control transistor MPc4[B]. In this case, the first bias current i_{b1} may be greater than the second bias current i_{b2}.

After the auto-zero operation, the A-th current control circuit CC[A]-1 may turn off the 3A-th control transistor MPc3[A] and turn on the 4A-th control transistor MPc4[A]. The B-th current control circuit CC[B]-1 may turn off the 3B-th control transistor MPc3[B] and turn on the 4B-th control transistor MPc4[B]. In this case, the first bias current i_{b1} may decrease and the second bias current i_{b2} may increase. As the first bias current i_{b1} decreases, the A-th ramp output voltage vCRB_OUT[A] may decrease, and as the second bias current i_{b2} increases, the B-th ramp output potential vCRB_OUT[B] may decrease. Accordingly, different offsets may be applied to the non-inverting inputs INp[A] and INp[B] of the ADC circuits ADC[A] and ADC[B], respectively, and because the operation principle thereof has been described above, a detailed description thereof is omitted.

As described above, each of the A-th and B-th variable ramp buffers vCRB[A]-1 and vCRB[B]-1 may control the bias current by directly turning on or off the control transistors. According to the control of the bias current, the ramp output voltage vCRB_OUT may be controlled, and accordingly, an offset may be applied to the non-inverting inputs INp[A] and INp[B] of the ADC circuits ADC[A] and ADC[B].

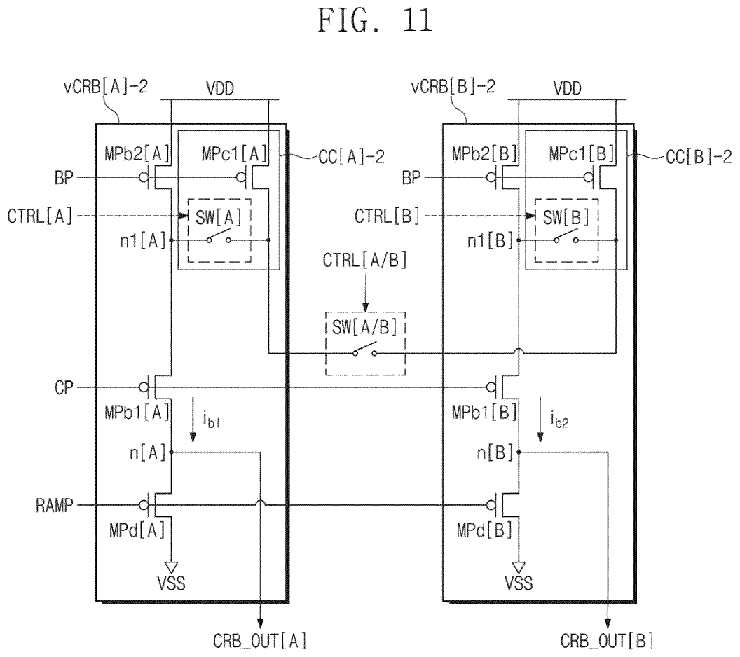

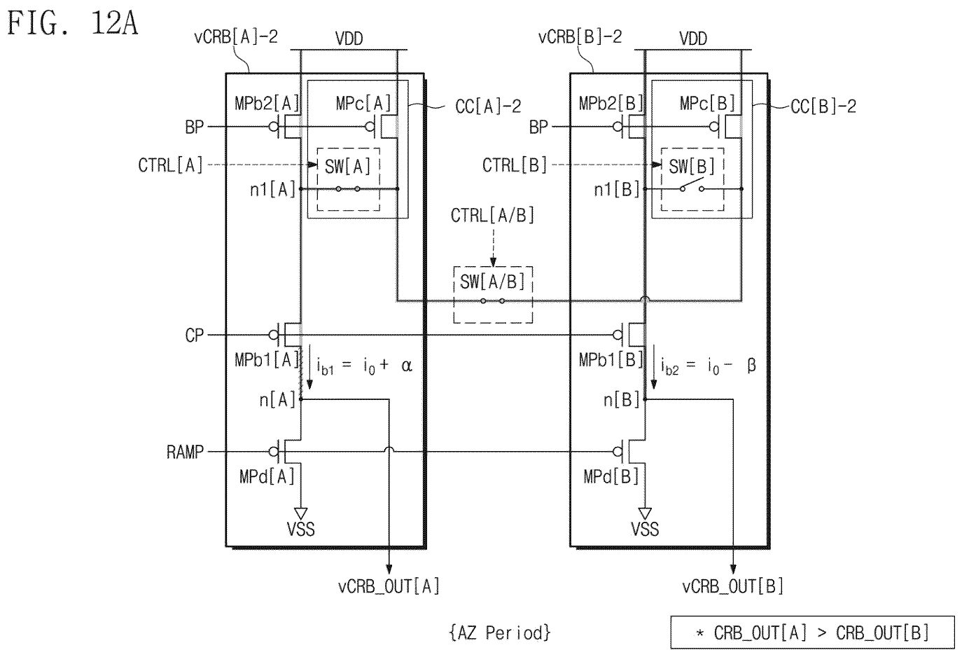

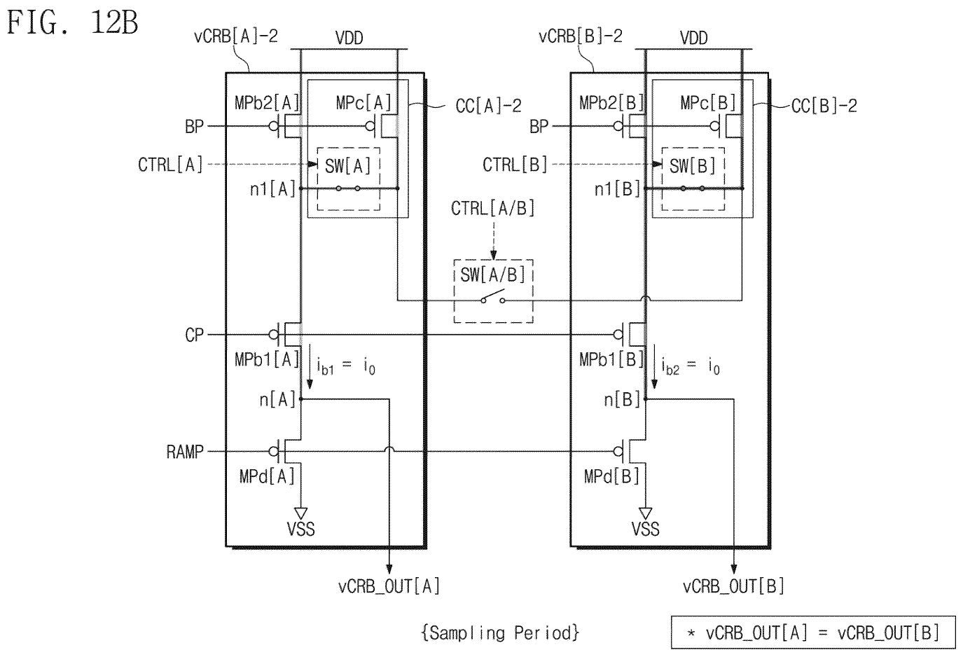

FIG. 11 is a circuit diagram showing the variable ramp buffer of FIG. 1. FIGS. 12A and 12B are diagrams for describing the operation of the variable ramp buffer of FIG. 11. Referring to FIGS. 1, 11, 12A, and 12B, the image sensor device 100 may include an A-th variable ramp buffer vCRB[A]-2, a B-th variable ramp Buffer vCRB[B]-2, and an AB-th control switch circuit SW[A/B]. The A-th variable ramp buffer vCRB[A]-2 and the B-th variable ramp Buffer vCRB[B]-2 may correspond to the A-th and B-th variable ramp buffers vCRB[A] and vCRB[B] described above.

The A-th variable ramp buffer vCRB[A]-2 may include an A-th driving transistor MPd[A], a 1A-th bias transistor MPb1[A], an 2A-th bias transistor MPb2[A], and an A-th current control circuit MPc[A]. The B-th variable ramp buffer vCRB[B]-2 may include a B-th driving transistor MPd[B], a 1B-th bias transistor MPb1[B], the 2B-th bias transistor MPb2[B], and a B-th current control circuit MPc[B]. The A-th driving transistor MPd[A], the 1A-th bias transistor MPb1[A], the 2A-th via transistor MPb2[A], the B-th driving transistors MPd[B], the 1B-th bias transistors MPb1[B], and the 2B-th bias transistors MPb2[B] are similar to those described above, and thus a detailed description thereof is omitted.

The A-th current control circuit CC[A]-2 may include a first A control transistor MPc1[A] and an A-th control switch circuit SW[A]. The 1A-th control transistor MPc1[A] and the A-th control switch SW[A] may be connected in series between the 1A-th nodes n1[A] and the power supply voltage Vpix. The 1A-th control transistor MPc1[A] may operate in response to the second bias signal BP. The A-th control switch circuit SW[A] may operate in response to the A-th control signal CTRL[A].

The B-th current control circuit CC[B]-2 may include a 1B-th control transistor MPc1[B] and a B-th control switch circuit SW[B]. The 1B-th control transistor MPc1[B] and the B-th control switch SW[B] may be connected in series between the 1B-th nodes n1[B] and the power supply voltage Vpix. The 1B-th control transistor MPc1[B] may operate in response to the second bias signal BP. The B-th control switch circuit SW[B] may operate in response to the B-th control signal CTRL[B].

The AB-th control switch circuit SW[A/B] may be connected between the A-th current control circuit CC[A]-2 and the B-th current control circuit CC[B]-2. For example, the AB-th control switch circuit SW[A/B] may be connected between a first node of the A-th current control circuit CC[A]-2 and a second node of the B-th current control circuit CC[B]-2. The first node of the A-th current control circuit CC[A]-2 may refer to a node between the 1A-th control transistor MPc1[A] and the A-th control switch circuit SW[A]. The second node of the B-th current control circuit CC[B]-2 may refer to a node between the 1B control transistor MPc1[B] and the B-th control switch circuit SW[B]. The AB-th control switch circuit SW[A/B] may operate in response to the AB-th control signals CTRL[A/B].

In an example embodiment, the A-th, B-th, and AB-th control signals CTRL[A], CTRL[B], and CTRL[A/B] may be individually controlled. That is, the A-th, B-th, and AB-th control switch circuits SW[A], SW[B], and SW[A/B] may operate individually or independently. According to the operation of the A-th, B-th, and AB-th control switch circuits SW[A], SW[B], and SW[A/B], the bias currents i_{b1} and i_{b2} of the A-th and B-th variable ramp buffers vCRB[A] and vCRB[B] may be controlled.

For example, as shown in FIG. 12A, during auto-zero operation of the ADC circuits, the A-th and AB-th control switch circuits SW[A] and SW[A/B] may be turned on, and the B-th control switch circuit SW[B] may be turned off. In this case, the 2A-th bias transistor MPb2[A] and the A-th control transistor MPc[A] of the A-th variable ramp buffer vCRB[A]-2, and the B-th control transistor MPc[B] of the B-th variable ramp Buffer vCRB[B]-2 are connected in parallel. That is, the first bias current i_{b1} may be generated through the three transistors MPb2[A], MPc[A], and MPc[B]. On the other hand, the second bias current i_{b2} is generated through the 2B-th bias transistor MPb2[B] (i.e., one transistor). In this case, the first bias current i_{b1} may have a relatively large magnitude of i₀+α, and the second bias current i_{b2} may have a relatively small magnitude of i₀−β. Accordingly, the A-th ramp output voltage vCRB_OUT[A] may be greater than the B-th ramp output voltage VCRB_OUT[B].

Next, as shown in FIG. 12B, during the sampling operation of the ADC circuits, the A-th and B-th control switch circuits SW[A] and SW[B] may be turned on, and the AB-th control switch circuit SW[A/B] may be turned off. In this case, the first bias current i_{b1} may be generated through the 2A-th bias transistor MPb2[A] and the A-th control transistor MPc[A] (i.e., the two transistors) of the A-th variable ramp buffer vCRB[A]-2, and the second bias current i_{b2} may be generated through the 2B-th bias transistor MPb2[B] and a B-th control transistor MPc[B] (i.e., the two diodes) of the B-th variable ramp capacitor vCRB[B]-2. In this case, the first and second bias currents i_{b1} and i_{b2} may substantially be the same or similar with each other. Accordingly, the A-th and B-th ramp output voltages vCRB_OUT[A] and vCRB_out[B] may substantially be the same or similar with each other.

As described above, the variable ramp buffers vCRB may control the bias current through a switching operation to individually control the ramp output voltage vCRB_OUT for each column. Accordingly, different offsets may be applied to the non-inverting input of each of the plurality of ADC circuits. In this case, the plurality of ADC circuits may be prevented from performing resetting sampling or simultaneously performing sampling in a low-illuminance environment (that is, a comparison signals COMP are generated at the same time), and thus, rapid fluctuation of the power supply voltage or the ground voltage may be prevented. The configuration of the variable ramp buffer described above is some examples, and example embodiments are not limited thereto.

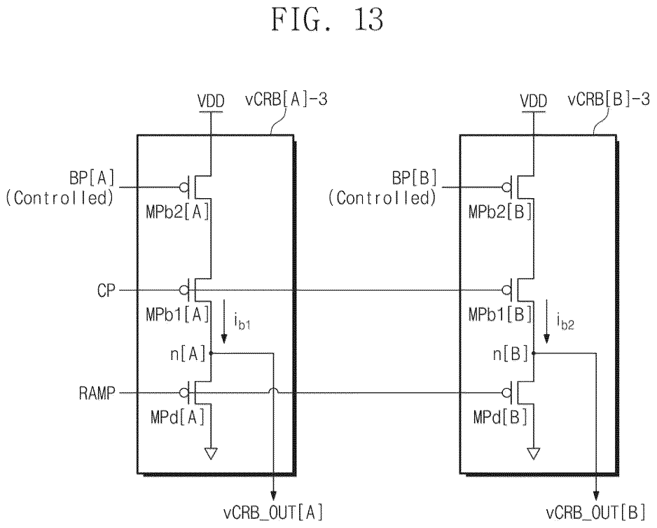

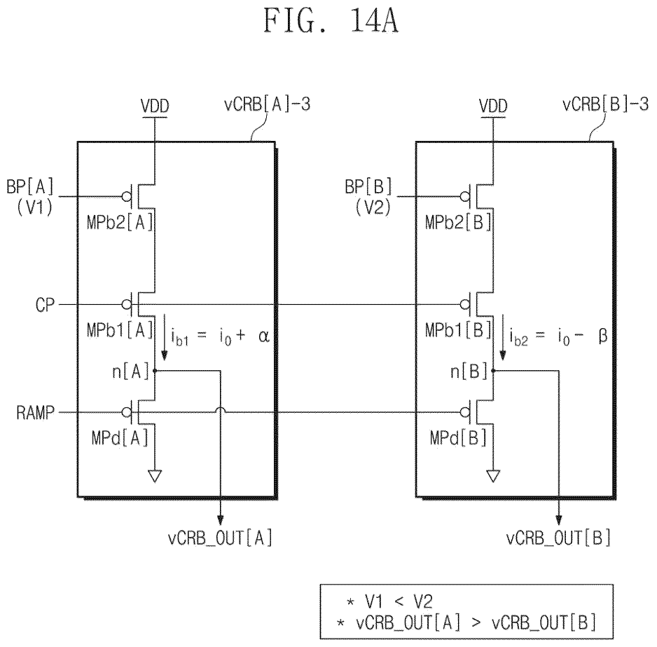

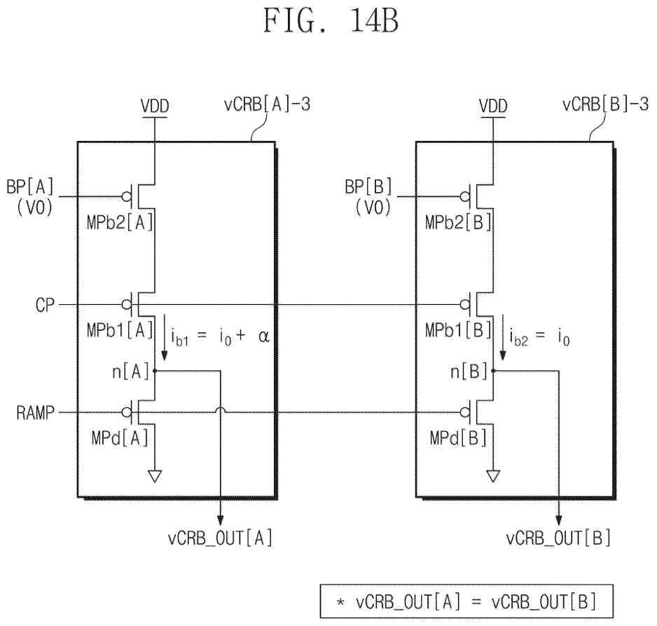

FIG. 13 is a circuit diagram showing the variable ramp buffer of FIG. 1. FIGS. 14A and 14B are diagrams for describing the operation of the variable ramp buffer of FIG. 13. Referring to FIGS. 1, 13, 14A, and 14B, the image sensor device 100 may include A-th and B-th variable ramp buffers vCRB[A]-3 and vCRB[B]-3. The A-th and B-th variable ramp buffers vCRB[A]-3 and vCRB[B]-3 may correspond to the A-th and the B-th variable ramp buffers vCRB[A] and vCRB[B], respectively.

The A-th variable ramp buffer vCRB[A]-3 may include an A-th driving transistor MPd[A], a 1A-th bias transistor MPb1[A], and a 2A-th bias transistor MPb2[A]. The A-th driving transistor MPd[A], the 1A-th bias transistor MPb1[A], and the 2A-th bias transistor MPb2[A] may be connected in series between the ground voltage VSS and the power supply voltage Vpix.

The B-th variable ramp buffer vCRB[B]-3 may include a B-th driving transistor MPd[B], a 1B-th bias transistor MPb1[B], and a 2B-th bias transistor MP b2[B]. The B-th driving transistor MPd[B], the 1B-th bias transistor MPb1[B], and the 2B-th bias transistor MPb2[B] may be connected in series between the ground voltage VSS and the power supply voltage Vpix.

As described above, the A-th and B-th driving transistors MPd[A] and MPd[B] may operate in response to the ramp signal RAMP, and the first A-th and 1B-th bias transistors MPb1[A] and MPb1[B] may operate in response to the first bias signal CP.

On the other hand, the 2A-th bias transistor MPb2[A] may operate in response to the 2A-th bias signal BP[A], and the 2B-th bias transistor MPb2[B] may operate in responses to the 2B-the bias signal BP[B]. At this time, each of the 2A-th and 2B-th bias signals BP[A] and BP[B] may be individually controlled. That is, each of the 2A-th and 2B-th bias transistors MPb2[A] and MPb2[B] may operate in response to individually controlled bias signals BP[A] and BP[B]. In this case, the bias currents i_{b1} and i_{b2} and the outputs vCRB_OUT[A] and vCRB_out[B] of the A-th and B-th variable ramp buffers vCRB[A]-3 and vCRB[B]-3 may be individually controlled by the 2A-th and 2B bias signals BP[A] and BP[B].

For example, as shown in FIG. 14A, during auto-zero operation of the ADC circuits, the 2A-th bias signal BP[A] may be provided at a first voltage V1, and the 2B-th bias signal BP[B] may be provided with a second voltage V2 that is lower than the first voltage V1. In this case, the first bias current i_{b1} of the A-th variable ramp buffer vCRB[A]-3 may have a magnitude of i₀+α, and the second bias current i_{b2} of the B-th variable ramp Buffer vCRB[B]-3 may have the magnitude of i₀−β. Therefore, the A-th ramp output voltage vCRB_OUT[A] may be greater than the B-th ramp output voltage vCRB_OUT[B].

Next, as shown in FIG. 14B, after the auto-zero operation of the ADC circuits is completed, the 2A-th and 2B-th bias signals BP[A] and BP[B] may be provided at the 0-th voltage V0. In this case, the first and second bias currents i_{b1} and i_{b2} may be equal to i₀. Accordingly, the A-th and B-th ramp output voltages vCRB_OUT[A] and vCRB_out[B] may substantially be the same as each other.

As described above, the ramp output voltages may be controlled by individually controlling the bias signals applied to the bias transistors of the variable ramp buffers vCRB, thereby applying different offsets to the inputs of the plurality of ADC circuits.

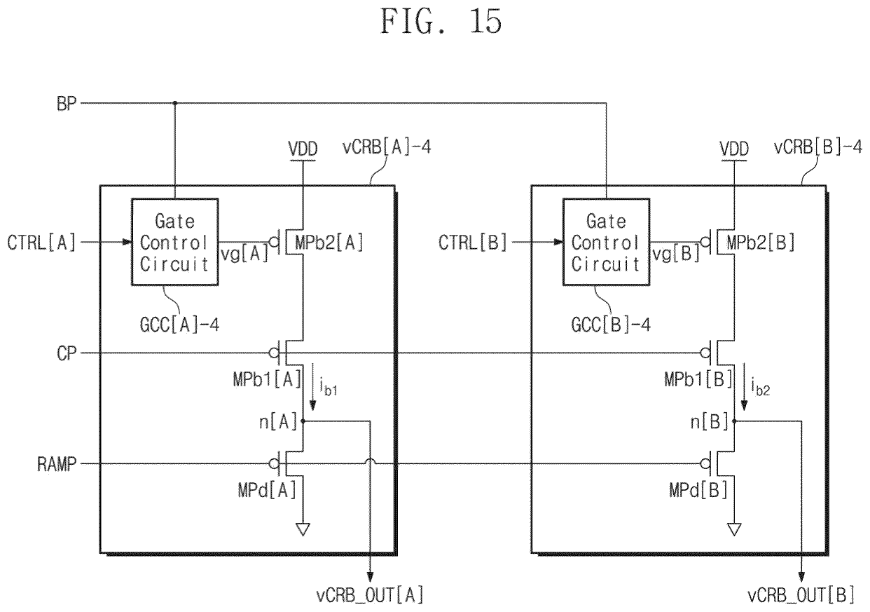

FIG. 15 is a circuit diagram showing the variable ramp buffer of FIG. 1. Referring to FIGS. 1 and 15, the image sensor device 100 may include A-th and B-th variable ramp buffers vCRB[A]-4 and vCRB[B]-4. The A-th and B-th variable ramp buffers vCRB[A]-4 and vCRB[B]-4 may correspond to the A-th and the B-th variable ramp buffers vCRB[A] and vCRB[B] described above, respectively.

The A-th variable ramp buffer vCRB[A]-4 may include an A-th driving transistor MPd[A], a 1A-th bias transistor MPb1[A], a 2A-th bias transistor MPb2[A], and an A-th gate control circuit GCC[A]-4. The A-th driving transistor MPd[A], the 1A-th bias transistor MPb1[A], and the 2A-th bias transistor MPb2[A] may be connected in series between the power supply voltage Vpix and the ground voltage VSS.

The B-th variable ramp buffer vCRB[B]-4 may include a B-th driving transistor MPd[B], a 1B-th bias transistor MPb1[B], a 2B-th bias transistor MP b2[B], and a B-th gate control circuit GCC[B]-4. The B-th driving transistor MPd[B], the 1B-th bias transistor MPb1[B], and the 2A-th bias transistor MPb2[A] may be connected in series between the power supply voltage Vpix and the ground voltage VSS.

The A-th and B-th driving transistors MPd[A] and MPd[B] may operate in response to the ramp signal RAMP. The 1A-th and 1B-th bias transistors MPb1[A] and MPb1[B] may operate in response to the first bias signal CP. The 2A-th bias transistor MPb2[A] may operate in response to the a-th gate voltage vg[A]. The 2B bias transistor MPb2[B] may operate in response to a B-th gate voltage vg[B].

In an example embodiment, the A-th gate voltage vg[A] may be generated by the A-th gate control circuit GCC[A]-4, and the second gate voltage vg[B] may be generated by a B-th gate control Circuit GCC[B]-4. For example, the A-th gate control circuit GCC[A]-4 may generate the A-th gate voltage vg[A] based on the second bias signal BP in response to the A-th control signal CTRL[A]. The B-th gate control circuit GCC[B]-4 may generate the B-th gate voltage vg[B] based on the second bias signal BP in response to the B-th control signal CTRL[B].

In an example embodiment, the magnitude of the first bias current i_{b1} may be controlled by the A-th gate voltage vg[A], and the magnitude of the second bias current i_{b2} may be controlled by the second gate voltage vg[B]. Accordingly, as the A-th and B-th gate voltages vg[A] and vg[B] are individually controlled, the A-th and B-th ramp output voltages vCRB_OUT[A] and vCRB_OUT[B] may be individually controlled.

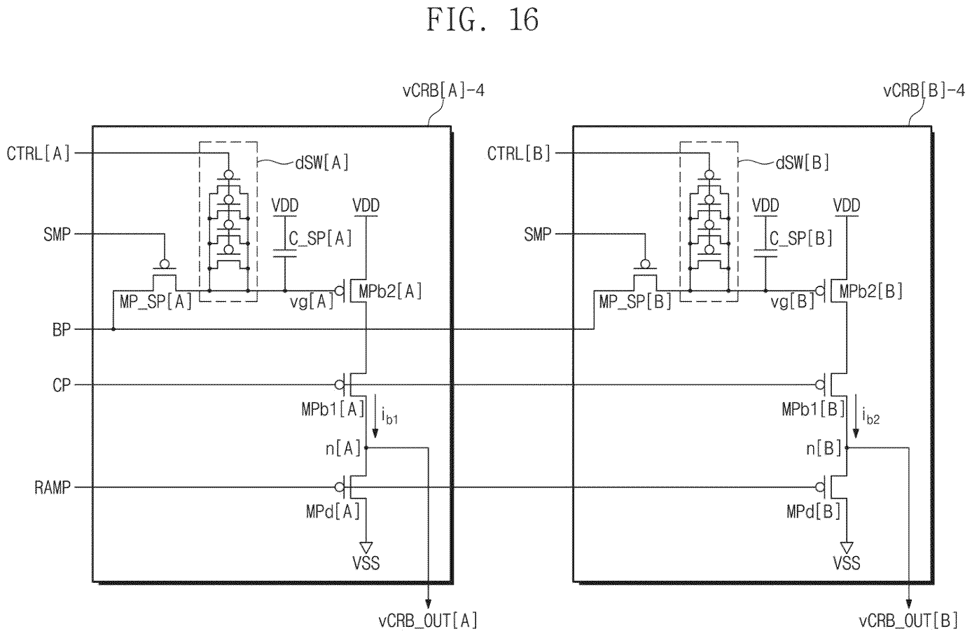

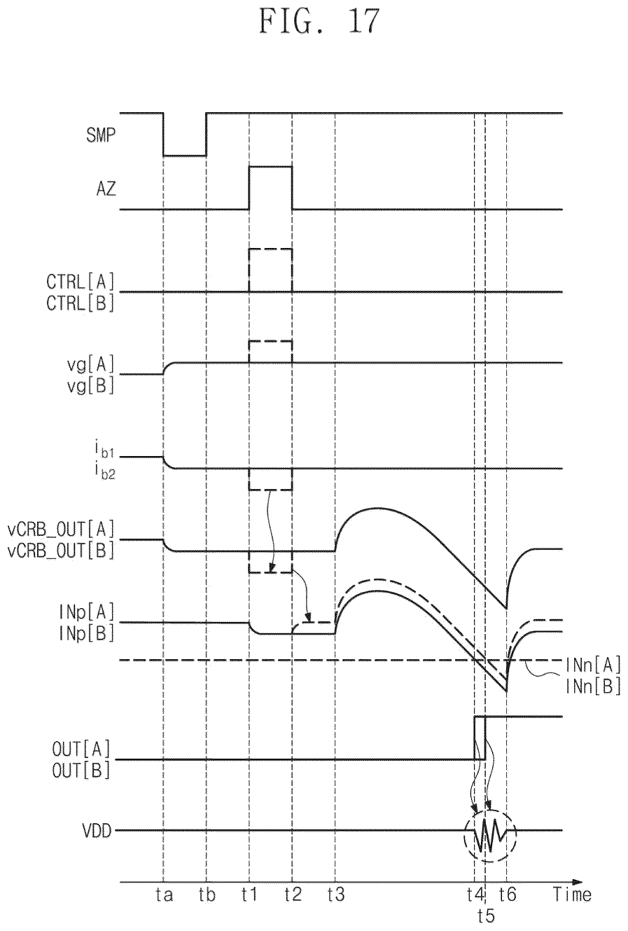

FIG. 16 is a circuit diagram showing the variable ramp buffer of FIG. 15. FIG. 17 is a timing diagram for explaining the operation of the variable ramp buffer of FIG. 16. For ease of description, detailed descriptions of the above-described components are omitted.

Referring to FIGS. 1, 15, and 16, the A-th gate control circuit GCC[A]-4 may include an A-th sampling transistor MP_SP[A], an A-th sampling capacitor C_SP[A], and an A-th dummy control switch dSW[A]. The A-th sampling transistor MP_SP[A] may be connected between the second bias signal BP and a gate electrode of the 2A-th bias transistor MPb2[A]. In an example embodiment, the A-th sampling transistor MP_SP[A] may be a PMOS transistor and may operate in response to the sampling signal SMP. The A-th sampling capacitor C_SP[A] may be connected between the power supply voltage Vpix and the gate electrode of the 2A-th bias transistor MPb2[A]. The A-th dummy control switch dSW[A] may include a plurality of PMOS transistors connected to the gate electrode of the 2A-th bias transistor MPb2[A]. The plurality of PMOS transistors may operate in response to the A-th control signal CTRL[A].

The B-th gate control circuit GCC[B]-4 may include a B-th sampling transistor MP_SP[B], a B-th sampling capacitor C_SP[B], and a B-th dummy control switch dSW[B]. The B-th sampling transistor MP_SP[B] may be connected between the second bias signal BP and a gate electrode of the 2B-th bias transistor MPb2[B]. In an example embodiment, the B-th sampling transistor MP_SP[B] may be a PMOS transistor and may operate in response to the sampling signal SMP. The B-th sampling capacitor C_SP[B] may be connected between the power supply voltage Vpix and the gate electrode of the 2B bias transistor MPb2[B]. The B-th dummy control switch dSW[B] may include a plurality of PMOS transistors connected to the gate electrode of the 2B bias transistor MPb2[B]. The plurality of PMOS transistors may operate in response to the B-th control signal CTRL[B].

In an example embodiment, the A-th and B-th gate voltages vg[A] and vg[B] may be individually controlled according to the operation of the A-th and the B-th dummy control switches dSW[A] and dSW[B]. For example, as shown in FIG. 17, in a period between the a-th to b-th time points (ta-tb), the sampling signal SMP may maintain a logic low. In response to the sampling signal SMP of the logic low, the A-th and B-th sampling transistors MP_SP[A] and MP_SP[B] may be turned on. Accordingly, the A-th and B-th sampling capacitors C_SP[A] and C_SP[B] may be charged to a level corresponding to the second bias signal BP. In this regard, the A-th and B-th gate voltages vg[A] and vg[B] may be charged to a level corresponding to the second bias signal BP.

Thereafter, in a period between the first to second time points (t1-t2), the auto-zero signal AZ may maintain a high level. That is, in the period between the first to second time points (t1-t2), an auto-zero operation on the ADC circuits may be performed. In the period between the first to second time points (t1-t2)((i.e., the auto-zero operation period), at least some PMOS transistors of the A-th dummy control switch dSW[A] may be turned off in response to the A-th control signal CTRL[A]. In this case, the amount of charge stored in the A-th sampling capacitor C_SP[A] varies due to the clock feedthrough effect caused by the switching operation of the A-th dummy control switch dSW[A]. The change in the amount of charge of the A-th sampling capacitor C_SP[A] causes a change in the A-th gate voltage vg[A]. In an example embodiment, the switching operation of the A-th dummy control switch dSW[A] may increase the A-th gate voltage vg[A] by a predetermined level. Thereafter, when the PMOS transistors of the A-th dummy control switch dSW[A] are turned on, the A-th gate voltage vg[A] may be maintained at a certain level again.

In the period between the first to second time points (t1-t2) (i.e., the auto-zero operation period), the B-th dummy control switch dSW[A] does not perform a switching operation. In this case, the B-th gate voltage vg[B] may be maintained at a constant level.

As described above, the A-th and the B-th gate voltages vg[A] and vg[B] may be individually controlled by the switching operation of the A-th and B-th dummy control switches dSW[A] and dSW[B]. In this case, the first and second bias currents i_{b1} and i_{b2} may be individually controlled, and accordingly, the A-th and B-th ramp output voltages vCRB_OUT[A] and vCRB_OUT[B] may be individually controlled.

The subsequent operation (e.g., an offset setting of the non-inverting inputs INp[A] and INp[B] of the A-th and B-th ADC circuits ADC[A] and ADC[B]) and the effect (distribution of the sampling time points) are similar to those described with reference to FIG. 8, and thus a detailed description thereof is omitted.

As described above, in the A-th and B-th variable ramp buffers vCRB[A]-4 and vCRB[B]-4, the A-th and the B-th gate voltages vg[A] and vg[B] may be controlled through a switching operation of the A-th and a B-th dummy control switches dSW[A] and dSW[B]. Accordingly, the A-th and B-th ramp output voltages vCRB_OUT[A] and vCRB_OUT[B] may be individually controlled.

In an example embodiment, in the A-th and B-th dummy control switches dSW[A] and dSW[B], the amount of change of the A-th gate voltages vg[A] and vg[B] may be controlled by adjusting the number of PMOS transistors in which the switching operation is performed. For example, when n PMOS transistors among the PMOS transistors of the A-th dummy control switch dSW[A] perform a switching operation, the A-th gate voltage vg[A] may have a level of Vn. When m PMOS transistors (i.e., m being different from n) among the PMOS transistors of the A-th dummy control switch dSW[A] perform a switching operation, the A-th gate voltage vg[A] may have a level of Vm different from Vn. That is, depending on the number of PMOS transistors in which the switching operation is performed, the effective size of the control switch that causes the clock feedthrough effect varies, and thus, the amount of change in the gate voltage may vary in various ways.

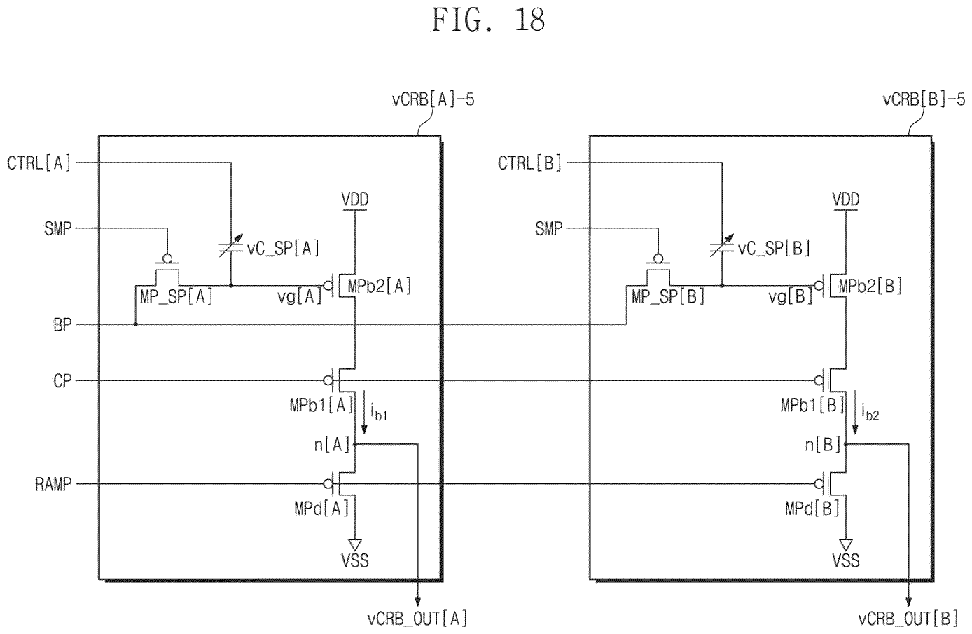

FIG. 18 is a circuit diagram showing the variable ramp buffer of FIG. 1. Referring to FIGS. 1 and 18, the image sensor device 100 may include A-th and B-th variable ramp buffers vCRB[A]-5 and vCRB[B]-5. The A-th and B-th variable ramp buffers vCRB[A]-5 and vCRB[B]-5 may correspond to the A-th and the B-th variable ramp buffers vCRB[A] and vCRB[B], respectively.

The A-th variable ramp buffer vCRB[A]-5 may include an A-th driving transistor MPd[A], a 1A-th bias transistor MPb1[A], a 2A-th bias transistor MPb2[A], an A-th sampling transistor MP_SP[A], and the A-th variable sampling capacitor vC_SP[A]. The B-th variable ramp buffer vCRB[B]-5 may include a B-th driving transistor MPd[B], a 1B-th bias transistor MPb1[B], a 2B-th bias diode MPb2[B], a B-th sampling transistor MP_SP[B], and a B-th variable sampling capacitor vC_SP[B].

The A-th driving transistor MPd[A], the 1A-bias transistor MPb1[A], the 2A-th bias transistor MPb2[A], the A-th sampling transistor MP_SP[A], the B-th driving transistors MPd[B], the 1B-th bias transistor MPb1[B], the 2B-th bias transistor MPb2[B], and the B-th sampling transistor MP_SP[B] have been described above, and thus a detailed description thereof is omitted.

The A-th variable sampling capacitor vC_SP[A] may be connected between the gate electrode of the 2A-th bias transistor MPb2[A] and the A-th control signal CTRL[A]. When the A-th control signal CTRL[A] is controlled, the A-th gate voltage vg[A] may be varied according to the coupling to the A-th variable sampling capacitor vC_SP[A].

Similarly, the B-th variable sampling capacitor vC_SP[B] may be connected between the gate electrode of the 2B bias transistor MPb2[A] and the B-th control signal CTRL[B]. When the B-th control signal CTRL[B] is controlled, the B-th gate voltage vg[B] may be varied according to the coupling to the B-th variable sampling capacitor vC_SP[B].

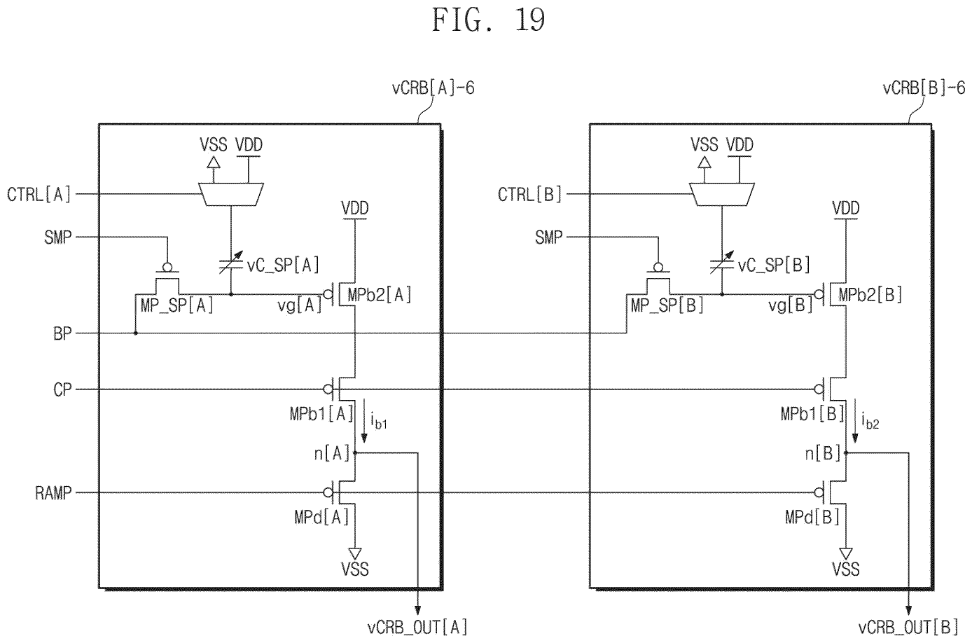

FIG. 19 is a circuit diagram showing the variable ramp buffer of FIG. 1. Referring to FIGS. 1 and 19, the image sensor device 100 may include A-th and B-th variable ramp buffers vCRB[A]-6 and vCRB[B]-6. The A-th and B-th variable ramp buffers vCRB[A]-6 and vCRB[B]-6 may correspond to the A-th and the B-th variable ramp buffers vCRB[A] and vCRB[B], respectively. For ease of description, reference to the above-described components and detailed description are omitted.

The A-th variable sampling capacitor VC_SP[A] may be connected between the gate electrode of the 2A-th bias transistor MPb2[A] and the A-th selection circuit SEL[A]. The A-th selection circuit SEL[A] may output one of the ground voltage VSS and the power supply voltage Vpix in response to the A-th control signal CTRL[A]. The B-th variable sampling capacitor VC_SP[B] may be connected between the gate electrode of the 2B bias transistor MPb2[B] and the B-th selection circuit SEL[B]. The B-th selection circuit SEL[B] may output one of the ground voltage VSS and the power supply voltage Vpix in response to the B-th control signal CTRL[B].

In an example embodiment, the A-th and B-th gate voltages vg[A] and vg[B] may be individually controlled according to the operation of the A-th and the B-th selectors SEL[A] and SEL[B]. For example, before the auto-zero operation, the A-th selector SEL[A] may output the power supply voltage Vpix. During the auto-zero operation, the A-th selector SEL[A] may alternately output the power supply voltage Vpix and the ground voltage VSS in response to the A-th control signal CTRL[A]. In this case, the A-th gate voltage vg[A] may decrease according to a coupling effect on the A-th variable sampling capacitor VC_SP[A]. After the auto-zero operation, the A-th selector SEL[A] may output the power supply voltage Vpix. In this case, the A-th gate voltage vg[A] may be changed to a level corresponding to the second bias signal BP.

Alternatively, before the auto-zero operation, the A-th selector SEL[A] may alternately output the power supply voltage Vpix and the ground voltage VSS based on the first ratio (for example, an output ratio of the power supply voltage Vpix) in response to the A-th control signal CTRL[A]. During the auto-zero operation, the A-th selector SEL[A] may alternately output the power supply voltage Vpix and the ground voltage VSS based on a second ratio that is greater than the first ratio (i.e., the power supply voltages Vpix are output longer than the first ratio), in response to the A-th control signal CTRL[A]. In this case, the A-th gate voltage vg[A] may increase according to a coupling effect on the A-th variable sampling capacitor VC_SP[A]. After the auto-zero operation, the A-th selector SEL[A] may alternately output the power supply voltage Vpix and the ground voltage VSS based on the first ratio in response to the A-th control signal CTRL[A].

In an example embodiment, the method of controlling the B-th gate voltage vg[B] by the B-th selector SEL[B] is similar to that described above, and thus a detailed description thereof is omitted.

FIG. 20 is a circuit diagram showing the variable ramp buffer of FIG. 1. Referring to FIGS. 1 and 20, the image sensor device 100 may include A-th and B-th variable ramp buffers vCRB[A]-7 and vCRB[B]-7. The A-th and B-th variable ramp buffers vCRB[A]-7, vCRB[B]-7 may correspond to the A-th and the B-th variable ramp buffers vCRB[A], vCRB[B] described above, respectively. For ease of description, description and detailed description of the above-described components are omitted.

The A-th sampling transistor MP_SP[A] may operate in response to the A-th sampling signal SMP[A]. The B-th sampling transistor MP_SP[B] may operate in response to the B-th sampling signal SMP[B]. At this time, the A-th and B-th gate voltages vg[A] and vg[B] may be controlled under the control of the A-th and the B-th sampling signals SMP[A] and SMP[B].

For example, a level of the A-th gate voltage vg[A] may be controlled by a voltage magnitude or a sampling time of the A-th sampling signal SMP[A], and a level of the B-th gate voltage vg[B] may be controlled by a voltage magnitude or a sampling time of a B-th sampling signal SMP[B]. As a more detailed example, the A-th sampling signal SMP[A] may remain at a low level for a first time period, and the B-th sampling signal SMP[B] may remain at the low level for a second time period that is longer than the first time period. In this case, the A-th sampling transistor MP_SP[A] may be turned on for the first time period in response to the A-th sampled signal SMP[A], and the B-th sampling transistor MP_SP[B] may be turned off for the second time period in response to a B-th sampling signal SMP[B]. Accordingly, the A-th gate voltage vg[A] may be sampled or charged to a first voltage, and the B-th gate voltage Vg[B] may be sampled or charged to a second voltage higher than the first voltage. Because the A-th and B-th gate voltages vg[A] and vg[B] are different from each other, the corresponding ramp output voltages vCRB_OUT[A] and vCRB_OUT[B] will be different from each other. Thereafter, prior to the sampling operation of the ADC circuit, each of the A-th and B-th sampling signals SMP[A], SMP[B] may maintain a low level for the same third time period. Accordingly, the A-th and B-th gate voltages vg[A] and vg[B] may be sampled or charged to the same level.

As described above, the A-th and B-th gate voltages vg[A] and vg[B] may be controlled according to a voltage level or a sampling time of the A-th and the B-th sampling signals SMP[A] and SMP[B], respectively. Because the operations of the variable ramp buffers vCRB[A] and vCRB[B] and the operations of the ADC circuits ADC[A] and ADC[B] connected thereto have been described above, a detailed description thereof is omitted.

As described with reference to FIGS. 18-20, in various structures, as the A-th and B-th control signals CTRL[A] and CTRL[B] are controlled, the A-th and the B-th gate voltages vg[A] and vg[B] may be individually controlled. In this case, as described above, the bias currents i_{b1} and i_{b2} and the ramp output voltages vCRB_OUT[A] and vCRB_OUT[B] may be individually controlled. Accordingly, different offsets may be applied to the inputs (e.g., non-inverting inputs) of the respective ADC circuits, as described above. For this reason, in a specific situation or a specific environment (e.g., reset sampling, a low-illuminance environment, or the like), sampling time points (e.g., time points at which a ramp signal or a corresponding ramp output voltage becomes lower than a pixel voltage) of the plurality of ADC circuits ADC[A] to ADC[n] are distributed, so that a sudden fluctuation in the power supply voltage Vpix or the ground voltage VSS may be prevented.

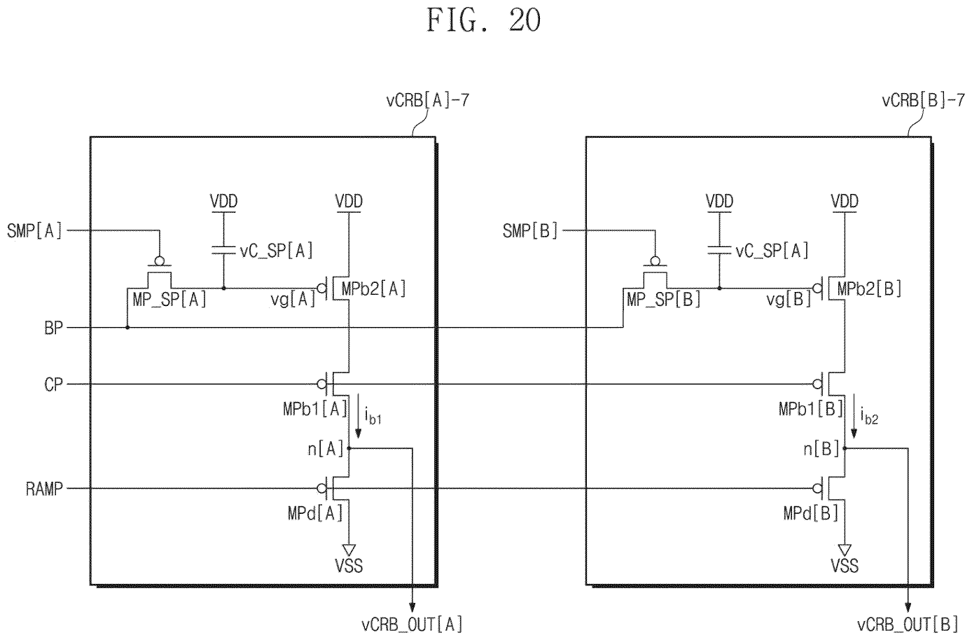

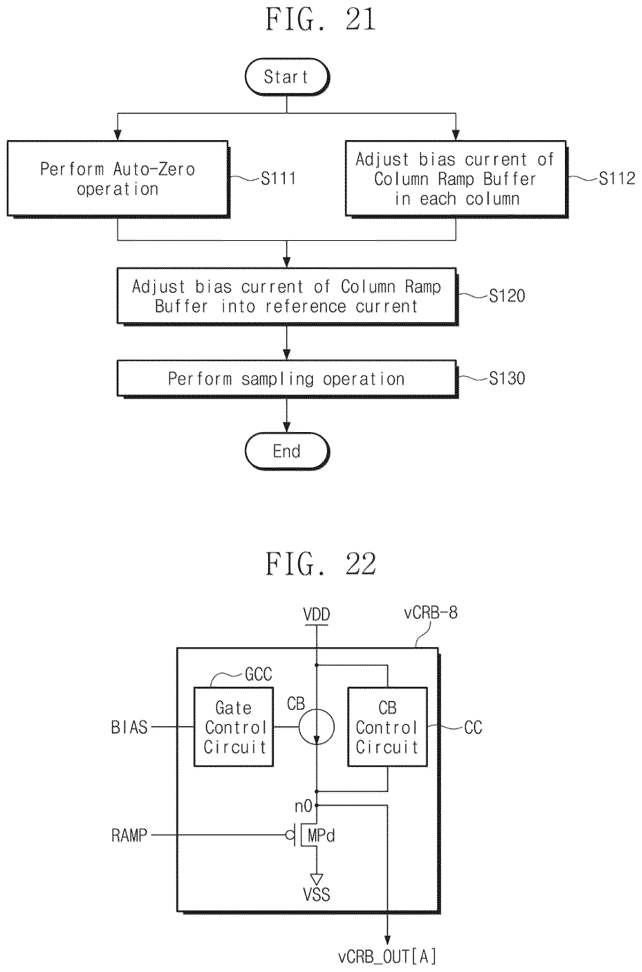

FIG. 21 is a flowchart illustrating the operation of the image sensor device of FIG. 1. For ease of description, in the image sensor device 100, a reset sampling operation on pixels corresponding to one row of a plurality of pixels is described with reference to FIG. 21. That is, the image sensor device 100 may repeatedly perform an operation according to the flowchart of FIG. 21 to generate frame data.

Referring to FIGS. 1 and 21, in operation S111, the image sensor device 100 may perform an auto-zero operation. For example, each of the plurality of ADC circuits ADC[A] to ADC[n] of the image sensor device 100 may perform an auto-zero operation. In an example embodiment, during the auto-zero operation, the auto-zero switches AZS of each of the plurality of ADC circuits ADC[A] to ADC[n] may be turned on in response to the auto-zero signal. Inputs of each of the plurality of ADC circuits ADC[A] to ADC[n] may be initialized by the auto-zero operation.

In operation S112, the image sensor device 100 may adjust the bias current of the variable ramp buffer of each column. For example, as described above, each of the plurality of variable ramp buffers vCRB[A] to vCRB[n] may control or adjust the bias current in response to a corresponding control signal CTRL. Accordingly, the output voltages vCRB_OUT[A] to vCRB_OUT[B] of each of the plurality of variable ramp buffers vCRB[A] to vCRB[n] may vary. Because the bias current control operation and the structure or the output voltage control operation and the structure of each of the plurality of variable ramp buffers vCRB[A] to vCRB[n] have been described above, a detailed description thereof is omitted.

In an example embodiment, the bias current of each of the plurality of variable ramp buffers vCRB[A] to vCRB[n] may be adjusted differently. For example, the A-th variable ramp buffer vCRB[A] may adjust the bias current to a first value, the B-th variable ramp buffer vCRB[B] may adjust the bias current to a second value different from the first value, and the C-th variable ramp buffer vCRB[C] may adjust the bias current to a third value different from each of the first and second values. In this case, the output voltages of the A-th, B-th, and C-th variable ramp buffers vCRB[A], vCRB[B], and vCRB[C] may have different levels.

In an example embodiment, the ramp buffer controller 150 of the image sensor device 100 may generate the control signal CTRL so that the bias current of each of the plurality of variable ramp buffers vCRB[A] to vCRB[n] is individually controlled.

In an example embodiment, the operation S112 (i.e., the operation of adjusting the bias current) may be performed in parallel with the operations S111 (i.e., the auto-zero operation). In this case, inputs of the plurality of ADC circuits ADC[A] to ADC[n] may be fixed to an initial value by an auto-zero operation, and outputs of a plurality of variable ramp buffers vCRB[A] to vCRB[n] may have different levels.

In operation S120, the image sensor device 100 may adjust the bias currents of the plurality of variable ramp buffers vCRB[A] to vCRB[n] to a reference current. For example, when the auto-zero operation of the plurality of ADC circuits ADC[A] to ADC[n] is completed or thereafter, the bias currents of the plurality of variable ramp buffers vCRB[A] to vCRB[n] may be adjusted to a reference current. Because the bias current control operation and structure of each of the plurality of variable ramp buffers vCRB[A] to vCRB[n] have been described above, a detailed description thereof is omitted. As the bias currents of the plurality of variable ramp buffers vCRB[A] to vCRB[n] are adjusted to the reference current, the outputs of the plurality the variable ramp buffers VCRB[A]. to VCRB[n] may be set to the same level or a reference level.

That is, when the auto-zero operation of the plurality of ADC circuits ADC[A] to ADC[n] is completed or thereafter, the outputs of the plurality of variable ramp buffers vCRB[A] to vCRB[n] may be changed. At this time, the amount of change of the respective outputs may be different from each other. The amount of change in the outputs of the plurality of variable ramp buffers vCRB[A] to vCRB[n] may be reflected in the inputs of the plurality the ADC circuits ADC[A] to ADC[n] through the input capacitors of the plurality ADC circuits ADC[A] to ADC[n]. That is, different offsets may be applied to inputs of the plurality of ADC circuits ADC[A]to ADC[n].

In operation S130, the image sensor device 100 may perform a sampling operation. For example, in a sampling operation, the ramp generator 140 may generate a ramp signal RAMP. The plurality of variable ramp buffers vCRB[A] to vCRB[n] may generate outputs based on the ramp signal RAMP. Outputs of the plurality of variable ramp buffers vCRB[A] to vCRB[n] may be respectively provided as non-inverting inputs of the plurality ADC circuits ADC[A] to ADC[n]. The plurality of ADC circuits ADC[A] to ADC[n] may receive the plurality of pixel voltages VPIX[A] to VPIX[n] as inverted inputs, respectively. The plurality of ADC circuits ADC[A] to ADC[n] may perform a sampling operation by comparing the non-inverting inputs and the inverting inputs, respectively.

At this time, as described above, each of the non-inverting inputs of the plurality of ADC circuits ADC[A] to ADC[n] may maintain a different offset. In this case, in a situation in which the plurality of pixel voltages VPIX[A] to VPIX[n] have similar levels (e.g., a reset level or a low-illuminance environment), sampling time points of the plurality of ADC circuits ADC[A] to ADC[n] may be distributed. Accordingly, a sudden fluctuation or a rapid fluctuation (i.e., noise) in the power supply voltage or the ground voltage may be prevented.

In an example embodiment, after the above-described operation, the plurality of ADC circuits ADC[A] to ADC[n] of the image sensor device 100 may perform a signal sampling operation. At this time, similarly as described above, the outputs of the plurality of variable ramp buffers vCRB[A] to vCRB[n] will maintain the same level and the same waveform, but a different offset will be maintained in the non-inverting inputs INP[A] to INP[n] of each of the plurality of ADC circuits ADC[A] to ADC[n]. Therefore, because different offsets are maintained in each of the plurality of ADC circuits ADC[A] to ADC[n], reliability of image data corresponding to digital outputs of the plurality of the ADC circuits ADC[A] to ADC[n] may be improved.

FIG. 22 is a circuit diagram showing the variable ramp buffer of FIG. 1. Referring to FIGS. 1 and 22, the image sensor device 100 may include a variable ramp buffer vCRB-8. The variable ramp buffer vCRB-8 of FIG. 22 may correspond to each of the variable ramp buffers vCRB[A] to vCRB[n] of FIG. 1.

The variable ramp buffer vCRB-8 may include a driving transistor MPd, a current bias circuit CB, a current control circuit CC, and a gate control circuit GCC. The driving transistor MPd and the current bias circuit CB may be connected in series between the ground voltage VSS and the power supply voltage Vpix. The driving transistor MPd may operate in response to the ramp signal RAMP. The current bias circuit CB may generate a bias current used to generate the ramp output voltage vCRB_OUT[A].

In an example embodiment, the current control circuit CC may be configured to control the current generated in the current bias circuit CB. For example, the current control circuit CC may be connected in parallel with the current bias circuit CB between the power supply voltage Vpix and the 0-th node n0. The current control circuit CC may include at least some of the features described with reference to FIGS. 5, 6, 7A, 7B, 8, 9A, 9B, 10, 11, 12A, and 12B (i.e., a current control circuit configured to control an effective channel width or length of bias transistors that generate a bias current). The gate control circuit GCC may be configured to control a gate voltage provided to the current bias circuit CB. In an example embodiment, the gate control circuit GCC may include at least some of the features described with reference to FIGS. 13-20 (i.e., a gate control circuit configured to control a gate voltage of a bias transistor).

In an example embodiment, the current control circuit CC and the gate control circuit GCC may operate in response to the control signal CTRL and the bias signal BIAS. Because specific operations and configurations of the current control circuit CC and the gate control circuit GCC have been described above, detailed descriptions thereof are omitted.

The variable ramp buffer vCRB-8 may control the bias current by controlling the width or length of the effective channel of the bias transistor configured to generate the bias current using the current control circuit CC, or by controlling the gate voltage of the bias transistor constructed to generate a bias current using the gate control circuit GCC. In this case, the ramp output voltage vCRB_OUT may be individually controlled. Because subsequent operations and methods according to the individual control of the ramp output voltage vCRB_OUT (for example, applying different offsets to each of the plurality of ADC circuits ADC[A] to ADC[n]) have been described above, a detailed description thereof is omitted.

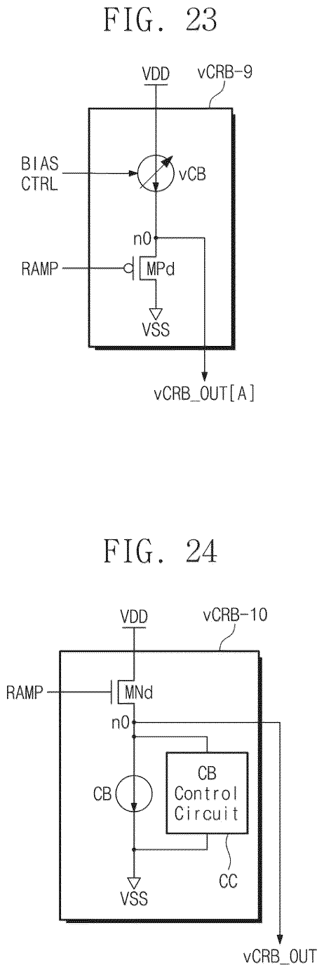

FIG. 23 is a block diagram illustrating the variable ramp buffer of FIG. 1. Referring to FIGS. 1 and 23, the image sensor device 100 may include a variable ramp buffer vCRB-9. The variable ramp buffer vCRB-9 of FIG. 23 may correspond to each of the variable ramp buffers vCRB[A] to vCRB[n] of FIG. 1.

The variable ramp buffer vCRB-9 may include a driving transistor MPd and a variable current bias circuit vCB. The driving transistor MPd and the variable current bias circuit vCB may be connected in series between the ground voltage VSS and the power supply voltage Vpix. The driving transistor MPd may operate in response to the ramp signal RAMP. The variable current bias circuit vCB may be configured to generate a bias current.

In an example embodiment, the variable current bias circuit vCB may be configured to control the bias current in response to the bias signal BIAS and the control signal CTRL. Because the subsequent operation according to the control of the bias current (e.g., controlling the ramp output voltage vCRB_OUT and applying the offset to the ADC circuits) has been described above, a detailed description thereof is omitted.

As described above, according to example embodiments, the plurality of variable ramp buffers vCRB[A] to vCRB[n] may individually control the bias current. In this case, different offsets may be applied to the non-inverting inputs INp input to each of the plurality of ADC circuits ADC[A] to ADC[n], thereby distributing sampling time points of the plurality of the ADC circuits ADC[A] to ADC[n] in a specific situation (e.g., reset sampling, low-light environment, etc.).

FIG. 24 is a block diagram illustrating the variable ramp buffer of FIG. 1. Referring to FIGS. 1 and 24, the image sensor device 100 may include a variable ramp buffer vCRB-10. The variable ramp buffer vCRB-10 of FIG. 24 may correspond to each of the variable ramp buffers vCRB[A] to vCRB[n] of FIG. 1.

The variable ramp buffer vCRB-10 may include a driving transistor MNd, a current bias circuit CB, and a current control circuit CC. The driving transistor MNd and the current bias circuit CB may be connected in series between the power supply voltage Vpix and the ground voltage VSS. In an example embodiment, the driving transistor MNd may be an NMOS transistor. The driving transistor MNd may operate in response to the ramp signal RAMP.

The current bias circuit CB may be configured to generate a bias current used in the variable ramp buffer VCB-10. In an example embodiment, the current bias circuit CB may include NMOS transistors connected in series or in parallel, and the NMOS transistor may operate in response to a bias signal.

The current control circuit CC is connected in parallel with the current bias circuit CB at the 0-th node n0 and the ground voltage VSS, and may be configured to control a bias current. In an example embodiment, the current control circuit CC of FIG. 24 is similar to the operation of the current control circuit described with reference to FIGS. 5, 6, 7A, 7B, 8, 9A, 9B, 10, 11, 12A, and 12B, except that it is implemented using an NMOS transistor, and thus a detailed description thereof is omitted. In an example embodiment, the current control circuit CC is implemented using an NMOS transistor, so that each signal level or voltage level may vary, but this will be readily understood by those skilled in the art to which the present disclosure pertains.

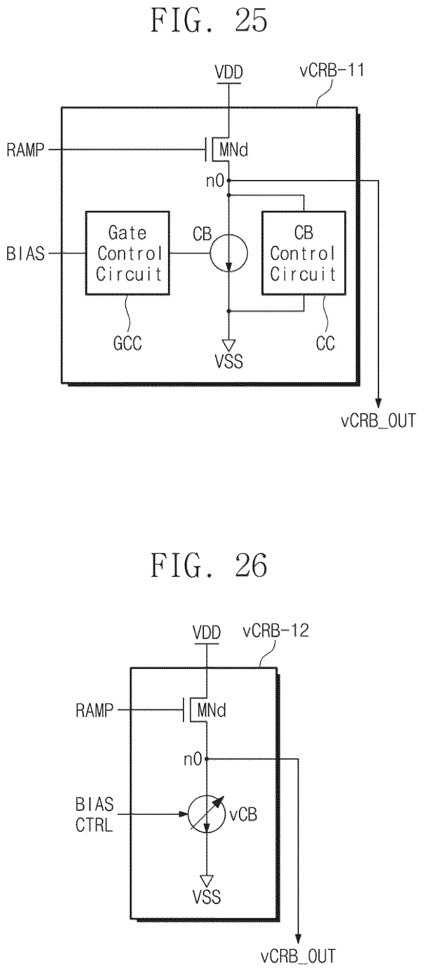

FIG. 25 is a block diagram illustrating the variable ramp buffer of FIG. 1. Referring to FIGS. 1 and 25, the image sensor device 100 may include a variable ramp buffer vCRB-11. The variable ramp buffer vCRB-11 of FIG. 25 may correspond to each of the variable ramp buffers vCRB[A] to vCRB[n] of FIG. 1.

The variable ramp buffer vCRB-11 may include a driving transistor MNd, a current bias circuit CB, a current control circuit CC, and a gate control circuit GCC. Because the driving transistor MNd, the current bias circuit CB, and the current control circuit CC have been described with reference to FIG. 24, a detailed description thereof is omitted.

The variable ramp buffer vCRB-11 of FIG. 25 may further include a gate control circuit GCC, compared with the variable ramp buffer vCRB-10 of FIG. 24. The gate control circuit GCC may be configured to control a gate voltage provided to the current bias circuit CB. In an example embodiment, the configuration of the gate control circuit GCC is similar to the operation of the gate control Circuit described with reference to FIGS. 13-20, except that it is implemented using an NMOS transistor, and thus a detailed description thereof is omitted. In an example embodiment, because the gate control circuit GCC is implemented using an NMOS transistor, each signal level or voltage level may vary, but this will be readily understood by those skilled in the art to which the present disclosure pertains.

FIG. 26 is a block diagram illustrating the variable ramp buffer of FIG. 1. Referring to FIGS. 1 and 26, the image sensor device 100 may include a variable ramp buffer vCRB-12. The variable ramp buffer vCRB-12 of FIG. 26 may correspond to each of the variable ramp buffers vCRB[A] to vCRB[n] of FIG. 1.

The variable ramp buffer vCRB-12 may include a driving transistor MNd and a variable current bias circuit vCB. The driving transistor MNd and the variable current bias VCB may be connected in series between the power supply voltage Vpix and the ground voltage VSS. The driving transistor MNd may operate in response to the ramp signal RAMP. The variable current bias circuit vCB may be configured to control the bias current.

As described above, the variable ramp buffer vCRB may be implemented in various ways. It will be appreciated that the invention may include various modifications of example embodiments described above.

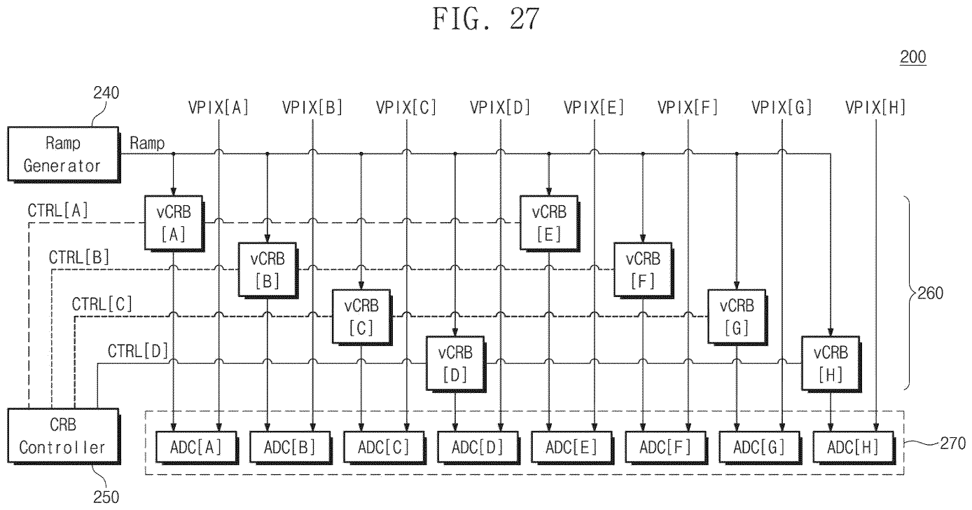

FIG. 27 is a block diagram showing some configurations of an image sensor device according to an example embodiment. Hereinafter, for convenience of description, components unnecessary to describe the configuration and operation of the variable ramp buffer are omitted. In addition, for ease of description, example embodiments are described with reference to eight columns, but example embodiments are not limited thereto.

Referring to FIG. 27, the image sensor device 200 may include a ramp generator 240, a ramp buffer controller 250, a variable ramp buffer block 260, and an ADC block 270. Because the ramp generator 240 and the variable ramp buffer controller 250 have been described above, a detailed description thereof is omitted.

The variable ramp buffer block 260 may include a plurality of variable ramp buffers vCRB[A] to vCRB[H]. The ADC block 270 may include a plurality of ADC circuits ADC[A] to ADC[H]. The plurality of variable ramp buffers vCRB[A]to vCRB[H] may buffer the ramp signal RAMP in response to the plurality of control signals CTRL[A] to CTRL[D]. The buffered ramp signals may be respectively provided to a plurality of ADC circuits ADC[A] to ADC[H].

In an example embodiment, some of the variable ramp buffers vCRB[A] to vCRB[H] may operate in response to the same control signal. At this time, the same offset may be applied to the corresponding ADC circuits. For example, the A-th and E-th variable ramp buffers vCRB[A] and vCRB[E] may operate in response to the A-th control signal CTRL[A], the B-th and F-th variable ramp buffers vCRB[B] and vCRB[F] may operate in response to the B-th control signal CTRL[B], the C-th and G-th variable ramp Buffers vCRB [C] and vCRB[G] may operate in response to the C-th control signal CTRL[C], and the D-th and H-th variable ramp Buffers vCRB[D], vCRB[H] may operate in response to the D-th control signal CTRL[D].

In this case, the outputs of the A-th and E-th variable ramp buffers vCRB[A] and vCRB[E] will be the same or similar with each other, the outputs of the B-th and F-th variable ramp buffers vCRB[B] and vCRB[F] will be the same or similar with each other, the outputs of C-th and G-th variable ramp Buffers vCRB[C] and vCRB[G] will be the same or similar with each other, and the outputs of the D-th and H th variable ramp Buffers vCRB[D] and vCRB[H] will be the same or similar with each else. Accordingly, a first offset may be applied to the A-th and E-th ADC circuits ADC[A] and ADC[E], a second offset may be applied the B-th and F-th ADC circuits ADC[B] and ADC [F], a third offset may be applied the C-th and G-th ADC circuits ADC[C] and ADC[G], and a fourth offset may be applied the D-th and H-th ADC circuits ADC[D] and ADC[H]. At this time, the first to fourth offsets may be different from each other.

As described above, some of the plurality of variable ramp buffers ADC[A] to ADC[H] may operate in response to the same control signal. In this case, the same offset may be applied to the corresponding ADC circuits. However, other offsets will be applied to the ADC circuits corresponding to the variable ramp buffers operating in response to other control signals.

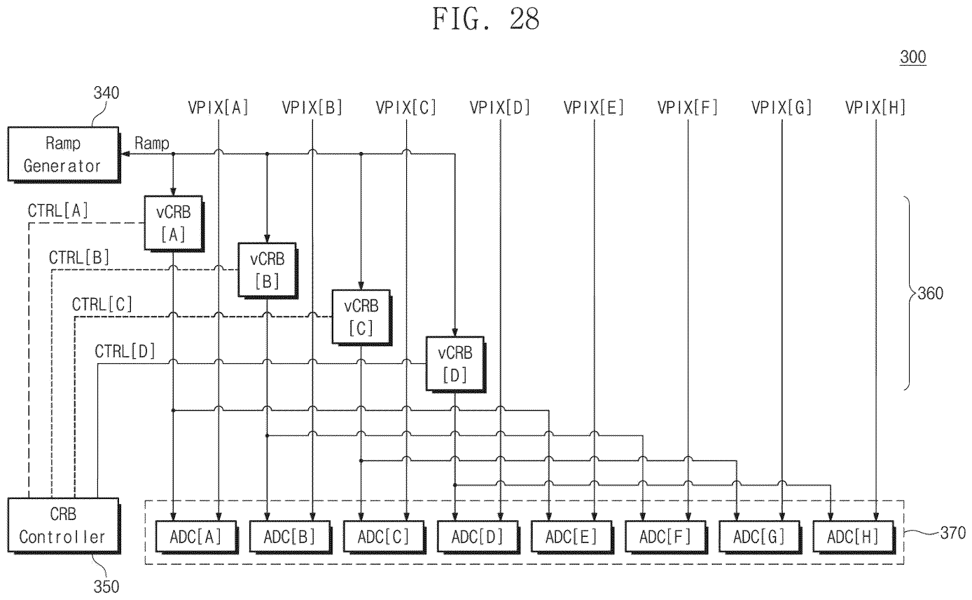

FIG. 28 is a block diagram showing an image sensor device according to an example embodiment. Hereinafter, for ease of description, components unnecessary to describe the configuration and the operation of the variable ramp buffer are omitted. Referring to FIG. 28, the image sensor device 300 may include a ramp generator 340, a variable ramp buffer controller 350, a variable ramp buffer block 360, and an ADC block 370. Because the ramp generator 340 and the variable ramp buffer controller 350 have been described above, a detailed description thereof is omitted.

The variable ramp buffer block 360 may include a plurality of variable ramp buffers vCRB[A] to vCRB[D]. The ADC block 370 may include a plurality of ADC circuits ADC[A] to ADC[H]. The plurality of variable ramp buffers vCRB[A]to vCRB[D] may operate in response to the A-th to D-th control signals CTRL[A] to CTRL[D], respectively. Because the operation of the plurality of variable ramp buffers vCRB[A] to vCRB[D] is similar to that described above, a detailed description thereof is omitted.

In an example embodiment, each of the plurality of variable ramp buffers vCRB[A] to vCRB[D] may provide an output to at least two ADC circuits. In this regard, the at least two ADC circuits may share one variable ramp buffer. For example, the A-th variable ramp buffer vCRB[A] may buffer the ramp signal RAMP in response to the A-th control signal CTRL[A]. The output of the A-th variable ramp buffer vCRB[A] may be provided to the A-th and E-th ADC circuits ADC[A] and ADC[E]. The B-th variable ramp buffer vCRB[B] may buffer the ramp signal RAMP in response to the B-th control signal CTRL[B]. The output of the B-th variable ramp buffer vCRB[B] may be provided to the B-th and F-th ADC circuits ADC[B] and ADC[F]. The C-th variable ramp buffer vCRB[C] may buffer the ramp signal RAMP in response to the C-th control signal CTRL[C]. The output of the C-th variable ramp buffer vCRB[C] may be provided to the C-th and G-th ADC circuits ADC[C] and ADC[G]. The D-th variable ramp buffer vCRB[D] may buffer the ramp signal RAMP in response to the D-th control signal CTRL[D]. The output of the D-th variable ramp buffer vCRB[D] may be provided to the D-th and H-th ADC circuits ADC[D] and ADC[H]. Accordingly, different offsets may be applied to the plurality of ADC circuits ADC[A] to ADC[H].

FIG. 29 is a block diagram showing an image sensor device according to an example embodiment. For ease of description, some components are omitted. Referring to FIG. 29, the image sensor device 400 may include a variable pixel load block 430, a ramp generator 440, a ramp buffer block 460, an ADC block 470, and a pixel load controller 490. Because the ramp generator 440 and the ADC block 470 have been described above, a detailed description thereof is omitted.

The ramp buffer block 460 may include a plurality of ramp buffers CRB[A] to CRB[H]. Each of the plurality of ramp buffers CRB[A] to CRB[H] may be similar to that described with reference to FIGS. 4A and 4C. That is, each of the plurality of ramp buffers CRB[A] to CRB[H] may be configured to buffer the ramp signal RAMP.

The pixel load controller 490 may be configured to control variable pixel load block 430. For example, the pixel load controller 490 may generate the control signals CTRL[A] to CTRL[D]. The control signals CTRL[A] to CTRL[D] may be provided to the variable pixel load block 430.

The variable pixel load block 430 may include a plurality of variable pixel load circuits vPLD[A] to vPLD[H]. Each of the plurality of variable pixel load circuits vPLD[A] to vPLD[H] may be respectively connected to a plurality of column lines, and may provide a pixel bias current to each of the plurality of column lines. The initialization speed of the plurality of column lines may be increased by the plurality of variable pixel load circuits vPLD[A] to vPLD[H].

In an example embodiment, the plurality of variable pixel load circuits vPLD[A] to vPLD[H] may operate in a manner similar to the operation of the variable ramp buffer described with reference to FIGS. 1-29. For example, during the auto-zero operation of the plurality of ADC circuits ADC[A] to ADC[H], the plurality of variable pixel load circuits vPLD[A] to vPLD[H] may each control the pixel bias current differently. After the auto-zero operation of the plurality of ADC circuits ADC[A] to ADC[H] is completed, the plurality of variable pixel load circuits vPLD[A] to vPLD[H] may control the pixel bias current to be equal to each other. In this case, similar to the operation principle described above, different offsets may be applied to the inverting inputs INn of the plurality of ADC circuits ADC[A] to ADC[H], and thus, even if the pixel voltages VPIX[A] to VPIX[B] are the same as each other, sampling time points of the plurality of the ADC circuits ADC[A] to ADC[H] may be distributed. The configuration and operation of the plurality of variable pixel load circuits vPLD[A] to vPLD[H] are described in more detail with reference to the following drawings.

In an example embodiment, the plurality of variable pixel load circuits vPLD[A] to vPLD[H] may operate individually in response to the plurality of control signals CTRL[A] to CTRL[D]. For example, the A-th and E-th variable pixel load circuits vPLD[A] and vPLD[E] may operate in response to the A-th control signal CTRL[A]. The B-th and F-th variable pixel load circuits vPLD[B] and vPLD[F] may operate in response to the B-th control signal CTRL[B]. The C-th and G-th variable pixel load circuits vPLD[C] and vPLD[G] may operate in response to the C-th control signal CTRL[C]. The D-th and H-th variable pixel load circuits vPLD[D] and vPLD[H] may operate in response to the D-th control signal CTRL[D]. In this case, a first offset may be applied to the A-th and E-th ADC circuits ADC[A] and ADC[E], a second offset may be applied the B-th and F-th ADC circuits ADC[B] and ADC [F], a third offset may be applied the C-th and G-th ADC circuits ADC[C] and ADC[G], and a fourth offset may be applied the D-th and H-th ADC circuitry ADC[D] and ADC[H]. At this time, the first to fourth offsets may be different from each other.

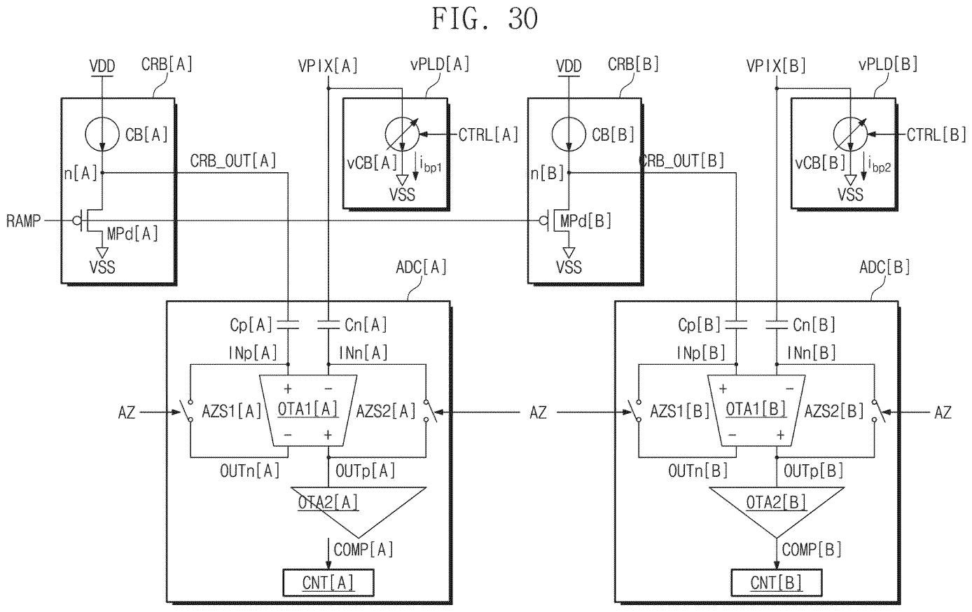

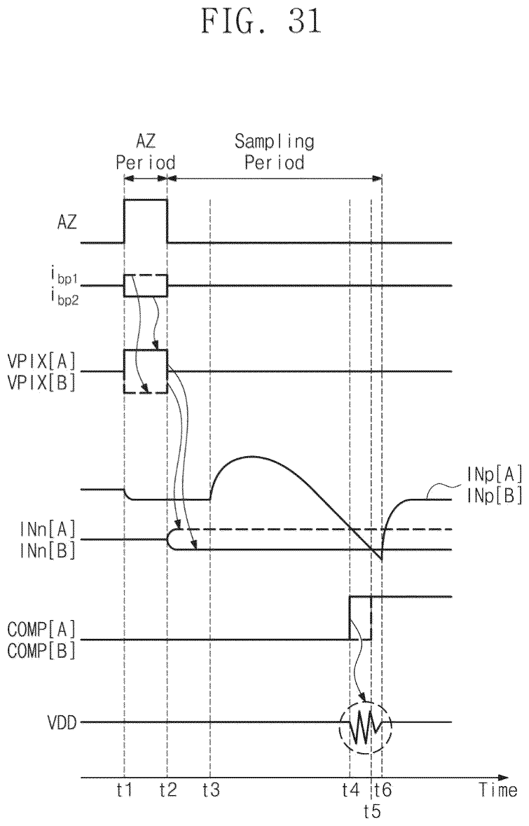

FIG. 30 is a block diagram illustrating the variable pixel load circuit and the ADC circuit of FIG. 29. FIG. 31 is a timing diagram for describing an operation of the variable pixel load circuit of FIG. 30. For brevity of the drawings and ease of description, some components are omitted. Referring to FIGS. 29-31, the image sensor device 400 may include A-th and B-th ramp buffers CRB[A] and CRB[B], A-th and B-th ADC circuits ADC[A] and ADC[B], and A-th and B th variable pixel load circuits vPLD[A] and vPLD[B]. The A-th and B-th ramp buffers CRB[A] and CRB[B], and the A-th and the B-th ADC circuits ADC[A] and ADC[B] have been described with reference to FIG. 4A, and thus a detailed description thereof is omitted.

The A-th variable pixel load circuit vPLD[A] may be connected to the A-th column line CL[A], through which the A-th pixel voltage VPIX[A] is provided. The A-th variable pixel load circuit PLD[A] may include an A-th variable current bias circuit vCB[A] configured to generate a first pixel bias current i_{bp1}. The A-th variable current bias circuit vCB[A] may control the first pixel bias current i_{bp1} in response to the A-th control signal CTRL[A].

The B-th variable pixel load circuit PLD[B] may be connected to the B-th column line CL[B], through which the B-th pixel voltage VPIX[B] is provided. The B-th variable pixel load circuit PLD[B] may include a B-th variable current bias circuit vCB[B] configured to generate a second pixel bias current i_{bp2}. The B-th variable current bias circuit vCB[B] may control the second pixel bias current i_{bp2} in response to the B-th control signal CTRL[B].

In an example embodiment, the A-th and B-th variable current bias circuits vCB[A] and vCB[B] may be implemented in a manner similar to the variable current bias circuit vCB described with reference to FIG. 26. For example, each of the A-th and B-th variable current bias circuits vCB[A] and vCB[B] may include a switch circuit and control transistors, and may control an effective size of a transistor, that generates a bar pixel bias current, by operation of the switch circuit. Alternatively, each of the A-th and B-th variable current bias circuits vCB[A], vCB[B] may include a circuit for controlling a gate voltage of a transistor that generates a bar pixel bias current. However, example embodiments are not limited thereto.

In an example embodiment, the A-th and B-th pixel voltages VPIX[A] and VPIX[B] may vary according to the first and second pixel bias currents i_{bp1} and i_{bp2}. In this case, a different offset may be applied to the A-th and B-th ADC circuits ADC[A] and ADC[B], similar to the operation principle described above.

For example, as shown in FIG. 31, in a period between the first to second time points (t1-t2), the auto-zero signal AZ may maintain a high level. In response to the auto-zero signal AZ of the high level, the A-th and B-th ADC circuits ADC[A] and ADC[B] may perform an auto-zero operation. During the auto-zero operations of the A-th and B-th ADC circuits ADC[A] and ADC[B], the A-th variable pixel load circuit vPLD[A] may control the first pixel bias current i_{bp1} to a first level in response to the A-th control signal CTRL[A] and the B-th variable pixel load circuit vPLD [B] may control the second pixel bias current i_{bp2} to a second level different from the first level (e.g., the second level is higher than the first level) in response to the B-th control signal CTRL[B]. In this case, the A-th pixel voltage VPIX[A] may increase by a level corresponding to a change amount of the first pixel bias current i_{bp1}, and the B-th pixel voltage VPIX[B] may decrease by a level corresponding the change amount of the second pixel bias current i_{bp2}.

After the second time point t2, the auto-zero signal AZ changes to a low level. In a period between the second to sixth time points (t2-t6), the A-th and B-th ADC circuits ADC[A] and ADC[B] may perform a reset sampling operation.

After the A-th and B-th ADC circuits ADC[A] and ADC[B] complete the auto-zero operation (i.e., after the second time point t2), the A-th variable pixel load circuit vPLD[A] may control the first pixel bias current i_{bp1} to the reference level in response to the A-th control signal CTRL[A], and the B-th variable pixel load circuit vPLD[B] may control the second pixel bias current i_{bp2} to the reference level, in response to the B-th control signal CTRL[B]. In this case, the A-th pixel voltage VPIX[A] may decrease by a level corresponding to a change amount of the first pixel bias current i_{bp1}, and the B-th pixel voltage VPIX[B] may increase by a level corresponding the change amount of the second pixel bias current i_{bp2}. In this case, the A-th and B-th pixel voltages VPIX[A] and VPIX[B] may correspond to a reset level.

A different offset may be applied to the A-th and B-th inverting inputs INn[A] and INn[B] according to a change in the A-th and the B-th pixel voltages VPIX[A] and VPIX[B] at the second time point t2. For example, at the second time point t2, as the A-th pixel voltage VPIX[A] decreases, the A-th inverting input INn[A] may decrease by a predetermined level by coupling of the A-th inverting input capacitor Cn[A] of the A-th ADC circuit ADC[A]. In addition, as the B-th pixel voltage VPIX[B] increases, the B-th inverting input INn[B] may increase by a predetermined level by coupling of the B-th inverting input capacitor Cn[B] of the B-th ADC circuit ADC[B].

That is, the A-th and the B-th inverting inputs INn[A] and INn[B] of the A-th and B-th ADC circuits ADC[A] and ADC[B] may have different offsets by operation of the A-th and B-th variable pixel load circuits vPLD[A] and vPLD[B]. In this case, at the fourth time point t4, the A-th non-inverting input INp[A] becomes lower than the A-th inverting input INn[A], thereby generating the A-th comparison signal COMP[A]. At the fifth time point t5, the B-th non-inverting input INP[B] becomes lower than a B-th inverting input INn[B], thereby generating the B-th comparison signal COMP[B].

In this regard, different offsets may be applied to the A-th and the B-th ADC circuits ADC[A] and ADC[B] by operation of the A-th and B-th variable pixel load circuits vPLD[A] and vPLD[B], thereby, even if the A-th or the B-th pixel voltages VPIX[A], VPIX[B] are the same as each other, distributing sampling points of the A-th or B-th ADC circuits ADC[A] and ADC [B].

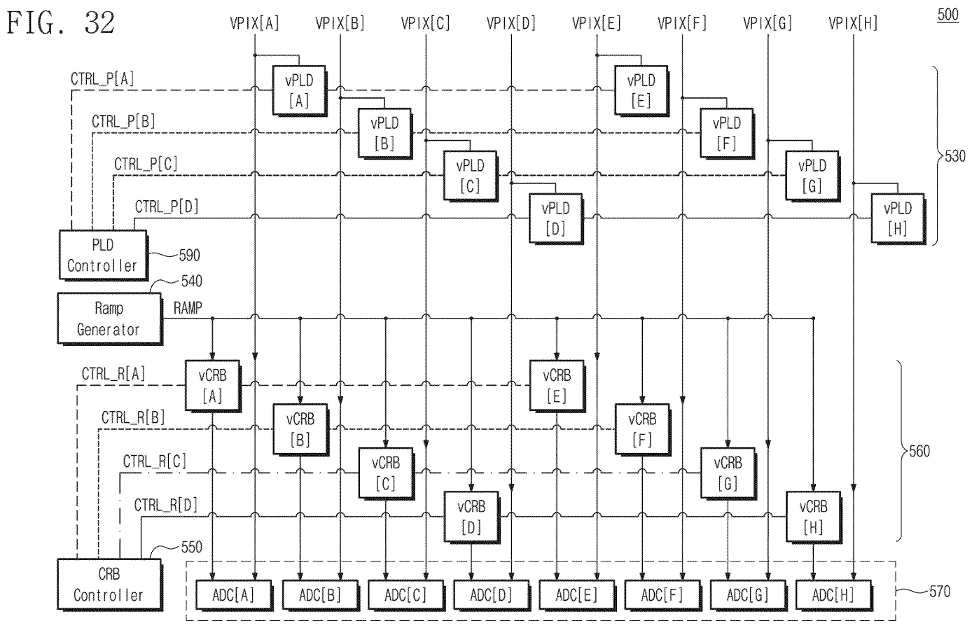

FIG. 32 is a block diagram illustrating an image sensor device according to an example embodiment. For ease of description, some components are omitted. Referring to FIG. 32, the image sensor device 500 may include a variable pixel load block 530, a ramp generator 540, a ramp buffer block 560, an ADC block 570, and a pixel load controller 590. Because the ramp generator 540 and the ADC block 570 have been described above, a detailed description thereof is omitted.

The variable pixel load block 530 may include a plurality of variable pixel load circuits vPLD[A] to vPLD[H]. The plurality of variable pixel load circuits vPLD[A] to vPLD[H] may operate in response to the plurality of pixel control signals CTRL_P[A] to CTRL_P[D] from the pixel load controller 590. Because the operations of the plurality of variable pixel load circuits vPLD[A] to vPLD[H] have been described with reference to FIGS. 29-31, a detailed description thereof is omitted.

The variable ramp buffer block 560 may include a plurality of variable ramp buffers vCRB[A] to vCRB[H]. The plurality of variable ramp buffers vCRB[A] to vCRB[H] may operate in response to the plurality of ramp control signals CTRL_R[A] to CTRL_R[D] from the ramp buffer controller 550. Because the operations of the plurality of variable ramp buffers vCRB[A] to vCRB[H] have been described with reference to FIGS. 5-28, a detailed description thereof is omitted. Through the above-described structure, different offsets may be applied to the plurality of ADC circuits ADC[A] to ADC[H].

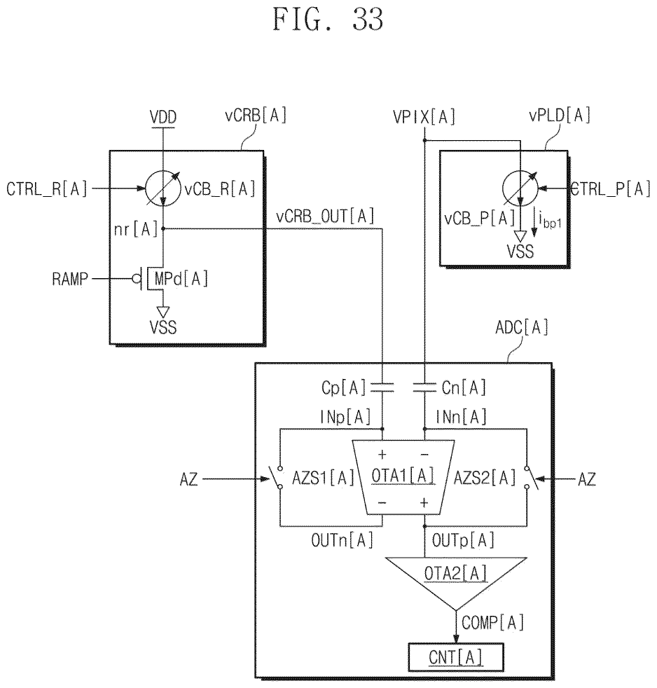

FIG. 33 is a block diagram illustrating the variable ramp buffer, variable pixel load circuit, and the ADC circuit of FIG. 32. Referring to FIGS. 31-33, the image sensor device 500 may include an A-th variable ramp buffer vCRB[A], an A-th pixel load circuit vPLD[A], and an A-th ADC circuit ADC[A]. The detailed configuration of each of the A-th variable ramp buffer vCRB[A], the A-th pixel load circuit vPLD[A], and the A-th ADC circuit ADC[A] has been described above, and thus a detailed description thereof is omitted.

In an example embodiment, before and after the auto-zero operation of the A-th ADC circuit ADC[A], the A-th variable ramp buffer vCRB[A] may adjust or control the first ramp bias current i_{rb1} to adjust or control the A-th variable ramp buffer output vCRB_OUT[A], and the A-th variable pixel load circuit vPLD[A] may adjust or control the first pixel bias current i_{bp1} to adjust or control the A-th pixel voltage VPIX[A]. In this case, as described above, an offset may be applied to each of the A-th non-inverting input INp[A] and the A-th inverting input INn[A] in the A-th ADC circuit ADC[A]. As described above, using the variable ramp buffer vCRB and the variable pixel load circuit vPLD, different offsets may be applied to each of the ADC circuits.

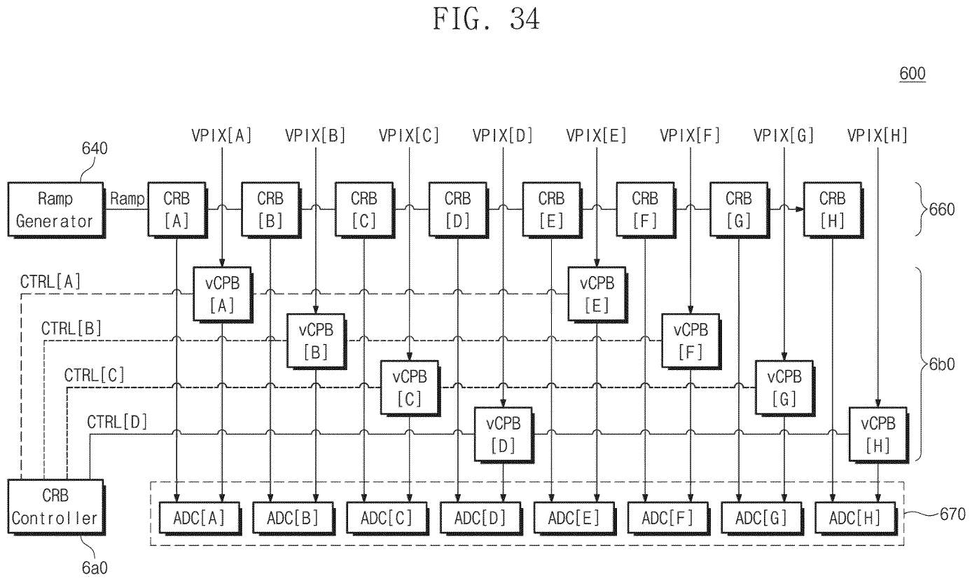

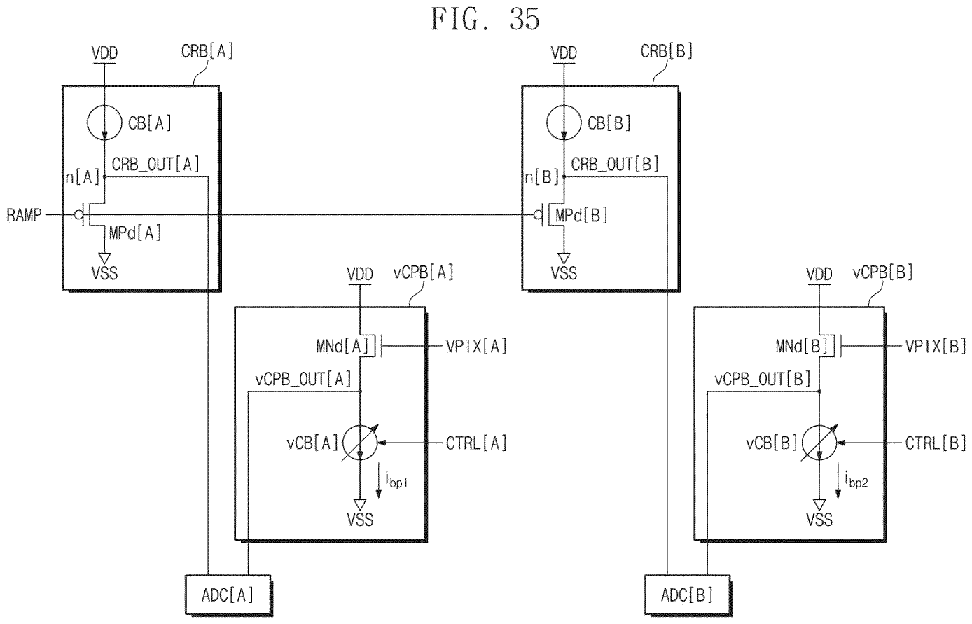

FIG. 34 is a block diagram illustrating an image sensor device according to an example embodiment. FIG. 35 is a block diagram illustrating the ramp buffer, variable pixel buffer, and ADC circuitry of FIG. 34. Referring to FIGS. 34-35, the image sensor device 600 may include a ramp generator 640, a ramp buffer block 660, an ADC block 670, a pixel buffer controller 6a0, and a pixel buffer block 6b0. Because the ramp generator 640, the ramp buffer block 660, and the ADC block 670 have been described above, a detailed description thereof is omitted.

The ramp buffer block 660 may include a plurality of ramp buffers CRB[A] to CRB[H]. Each of the plurality of ramp buffers CRB[A] to CRB[H] may be similar to that described with reference to FIGS. 4A and 4C. That is, each of the plurality of ramp buffers CRB[A] to CRB[H] may be configured to buffer the ramp signal RAMP.

The variable pixel buffer controller 6a0 may be configured to control the variable pixel buffer block 6b0. For example, the variable pixel buffer controller 6a0 may generate control signals CTRL[A] to CTRL[D]. The control signals CTRL[A] to CTRL[D] may be provided to the variable pixel buffer block 6b0.

The variable pixel buffer block 6b0 may include a plurality of variable pixel buffers vCPB[A] to vCPB[H]. The plurality of variable pixel buffers vCPB[A] to vCPB[H] may be configured to buffer the plurality of pixel voltages VPIX[A] to VPIX[H]. At this time, the plurality of variable pixel buffers vCPB[A] to vCPB[H] may operate in response to the plurality of control signals CTRL[A] to CTRL[D], respectively, and accordingly, different offsets may be applied to the plurality of ADC circuits ADC[A] to ADC[H].

For example, as described with reference to FIGS. 1-28, different offsets may be applied to non-inverting inputs (e.g., inputs corresponding to a ramp signal) input to the plurality of ADC circuits ADC[A] to ADC[H] as the variable ramp buffers are individually controlled. On the other hand, in FIG. 34, the variable pixel buffers vCPB[A] to vCPB[H] may operate similarly to the variable ramp buffers vCRB described above, but may be configured to buffer the pixel voltage VPIX. In this case, similar to the operation principle described above, different offsets may be applied to inverting inputs (e.g., inputs corresponding to pixel voltages) input to the plurality of ADC circuits ADC[A] to ADC[H]. Accordingly, sampling time points of the plurality of ADC circuits ADC[A] to ADC[H] may be distributed.

For example, as shown in FIG. 35, the image sensor device 600 may include the A-th and B-th ramp buffers CRB[A] and CRB[B], the A-th and the B-th variable pixel buffers vCPB[A] and vCPB[B], and the A-th and a B-th ADC circuits ADC[A] and ADC[B]. The A-th and B-th ramp buffers CRB[A] and CRB[B] and the A-th and the B-th ADC circuits ADC[A] and ADC[B] have been described above, and thus a detailed description thereof is omitted.

The A-th variable pixel buffer vCPB[A] may include an A-th driving transistor MNd[A] and an A-th variable current bias circuit vCB[A]. The A-th driving transistor MNd[A] and the A-th variable current bias circuit vCB[A] may be connected in series between the power supply voltage Vpix and the ground voltage VSS.

The A-th driving transistor MNd[A] may be an NMOS transistor. The A-th driving transistor MNd[A] may operate in response to the A-th pixel voltage VPIX[A]. The A-th variable current bias circuit vCB[A] may control the first bias current i_{bp1} in response to the A-th control signal CTRL[A]. In this case, a first offset may be applied to the inverting input INn[A] of the A-th ADC circuit ADC[A] similarly as described above.

The B-th variable pixel buffer vCPB[B] may include a B-th driving transistor MNd[B] and a B-th variable current bias circuit vCB[B]. The B-th driving transistor MNd[B] and the B-th variable current bias circuit vCB[B] may be connected in series between the power supply voltage Vpix and the ground voltage VSS.

The B-th driving transistor MNd[B] may be an NMOS transistor. The B-th driving transistor MNd[B] may operate in response to the B-th pixel voltage VPIX[B]. The B-th variable current bias circuit vCB[B] may control the second bias current i_{bp2} in response to the B-th control signal CTRL[B]. In this case, a second offset may be applied to the inverting input INn[A] of the B-th ADC circuit ADC[B] similarly as described above. In an example embodiment, the first and second offsets may vary depending on the control of the first and second bias currents i_{bp1} and i_{bp2}. The principle of the offset control operation is similar to that described above, and thus a detailed description thereof is omitted.

As described above, the image sensor device may include variable pixel buffers (vCPB) configured to buffer the pixel voltage. The variable pixel buffers vCPB may control the bias current before and after the auto-zero operation of the ADC circuits, and accordingly, different offsets may be applied to each of the ADC Circuits.

In FIG. 34, it has been described that the ramp signal RAMP is buffered by a plurality of ramp buffers CRB[A] to CRB[H], but example embodiments are not limited thereto. For example, some of the plurality of ADC circuits ADC[A] to ADC[H] may share the same ramp buffer CRB. As an example, the A-th and E-th ADC circuits ADC[A] and ADC[E] may share the A-th ramp buffer CRB[A], as described with reference to FIG. 28. Alternatively, the plurality of ramp buffers CRB[A] to CRB[H] may be omitted, and in this case, the ramp signal RAMP may be directly provided to the plurality of ADC circuits ADC[A] to ADC[H].

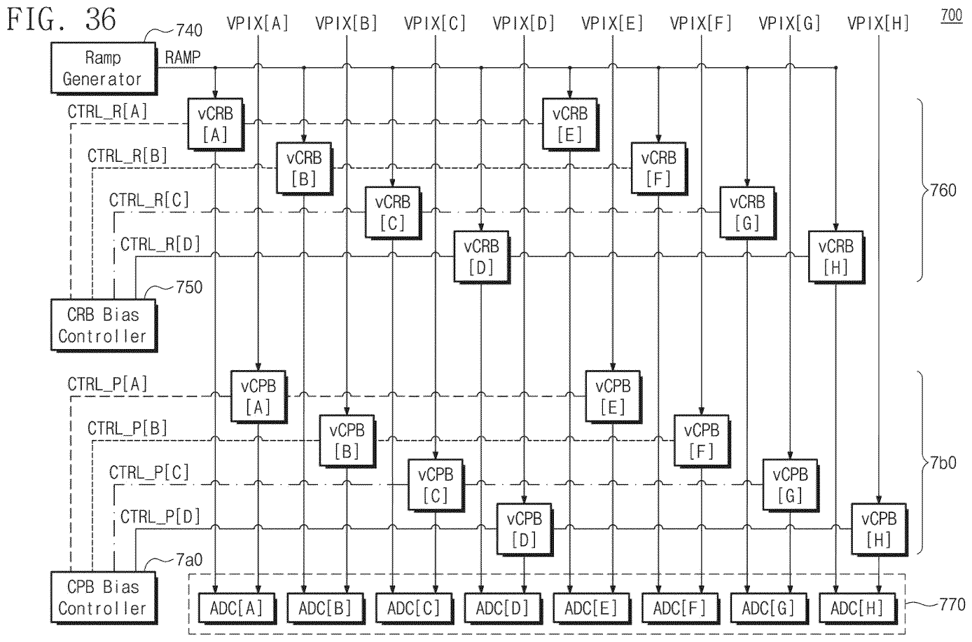

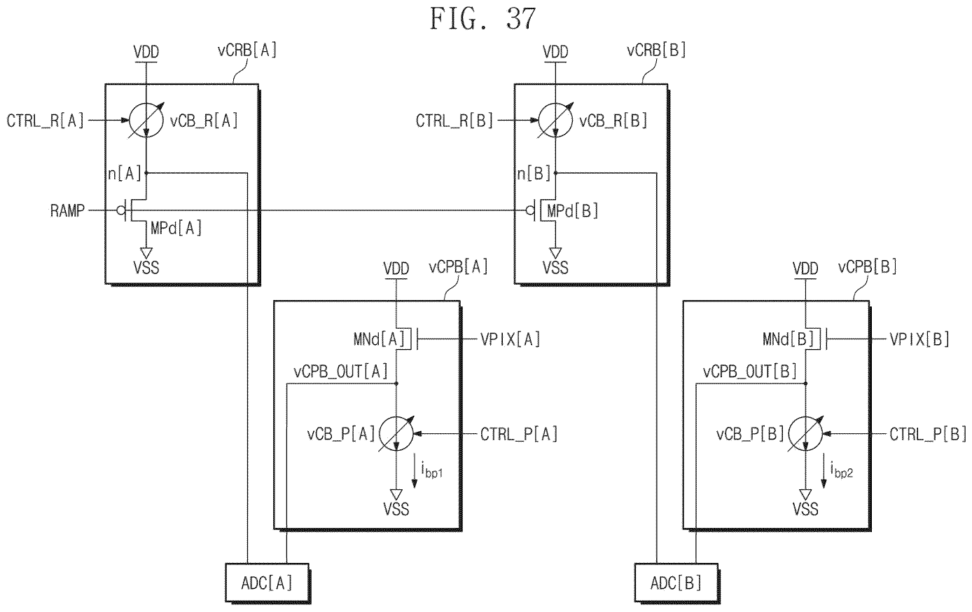

FIG. 36 is a block diagram showing an image sensor device according to an example embodiment. FIG. 37 is a block diagram illustrating the variable ramp buffer, variable pixel buffer, and ADC circuitry of FIG. 36. Referring to FIGS. 36-37, the image sensor device 700 may include a ramp generator 730, a ramp buffer controller 750, a variable ramp buffer block 660, an ADC block 770, a pixel buffer controller 7a0, and a variable pixel buffer block 7b0. Each component of the image sensor device 700 has been described above, and thus a detailed description thereof is omitted.

As shown in FIG. 36, the variable ramp buffer block 760 may include a plurality of variable ramp buffers vCRB[A] to vCRB[H]. The variable pixel buffer block 7b0 may include a plurality of variable pixel buffers vCPB[A] to vCPB[H]. The ADC block 770 may include a plurality of ADC circuits ADC[A] to ADC[H].

The plurality of variable ramp buffers vCRB[A] to vCRB[H] may buffer the ramp signal RAMP and provide the same to the plurality of ADC circuits ADC[A] to ADC[H], respectively. The plurality of variable pixel buffers vCPB[A] to vCPB[H] may buffer the plurality of pixel voltages VPIX[A] to VPIX[H], respectively, and provide the same to the plurality of ADC circuits ADC[A] to ADC[H], respectively.

In an example embodiment, the plurality of variable ramp buffers vCRB[A] to vCRB[H] may operate in response to the A-th to D-th ramp control signals CTRL_R[A] to CTRL_R[D], and the plurality of variable pixel buffers vCPB[A] and vCPB[H] shall operate in response to A th to D th pixel control signals CTRL_P[A] to CTRL_P[D].

For example, as shown in FIG. 37, the A-th and B-th variable ramp buffers vCRB[A] and vCRB[B] may include the A-th and the B-th driving transistors MPd[A] and MPd[B] and the A-th and a B-th ramp variable current bias vCB_R[A] and vCB_R[B], respectively. The A-th and B-th driving transistors MPd[A] and MPd[B] may operate in response to the ramp signal RAMP, and the A-th and the B-th ramp variable current biases vCB_R[A] and vCB_R[B] may each operate in response to A-th and a B-th ramp control signals CTRL_R[A]. In an example embodiment, each of the A-th and B-th variable ramp buffers vCRB[A] and vCRB[B] may be the variable ramp buffer vCRB-9 described with reference to FIG. 23. In this regard, each of the A-th and B-th variable ramp buffers vCRB[A] and vCRB[B] may be configured to control the bias current, in accordance with various example embodiments described above.

The A-th and B-th variable pixel buffers vCPB[A] and vCPB[B] may include the A-th and the B-th driving transistors MNd[A] and MNd[B] and A-th and a B-th pixel variable current biases vCB_P[A] and vCB_P[B], respectively. The A-th and B-th driving transistors MNd[A] and MNd[B] may operate in response to the A-th and the B-th pixel voltages VPIX[A] and VPIX[B], respectively, and the A-th and B-th pixel variable current biases VCB_P[A] and VCB_ P[B] may operate in response to A-th and a B-th pixel control signals CTRL_P[A] and CTRL_P[B], respectively. In an example embodiment, each of the A-th and B-th variable pixel buffers vCPB[A] and vCPB[B] may be the variable pixel buffer vCPB described above. In this regard, each of the A-th and B-th variable pixel buffers vCPB[A] and vCPB[B] may be configured to control the bias current, in accordance with various example embodiments described above.

In this case, different offsets may be applied to the plurality of ADC circuits ADC[A] to ADC[H]. A detailed description thereof is omitted because the detailed operation can be easily implemented or understood through a combination of the above-described example embodiments.

As described above, according to example embodiments, the image sensor device may include a plurality of variable ramp buffers. Each of the plurality of variable ramp buffers may control a ramp output voltage corresponding to a ramp signal by controlling a bias current. In this case, different offsets may be applied to the non-inverting inputs of the plurality of ADC circuits corresponding to the ramp signal. Alternatively, the image sensor device may include a plurality of variable pixel buffers. The plurality of variable pixel buffers may control the pixel output voltages, each corresponding to the plurality of pixel voltages, by controlling the bias current. In this case, different offsets may be applied to the inverting inputs of the plurality of ADC circuits corresponding to the plurality of pixel voltages. Accordingly, in certain situations, multiple ADC circuits may be prevented from performing sampling at the same time and thus from abrupt voltage fluctuations.

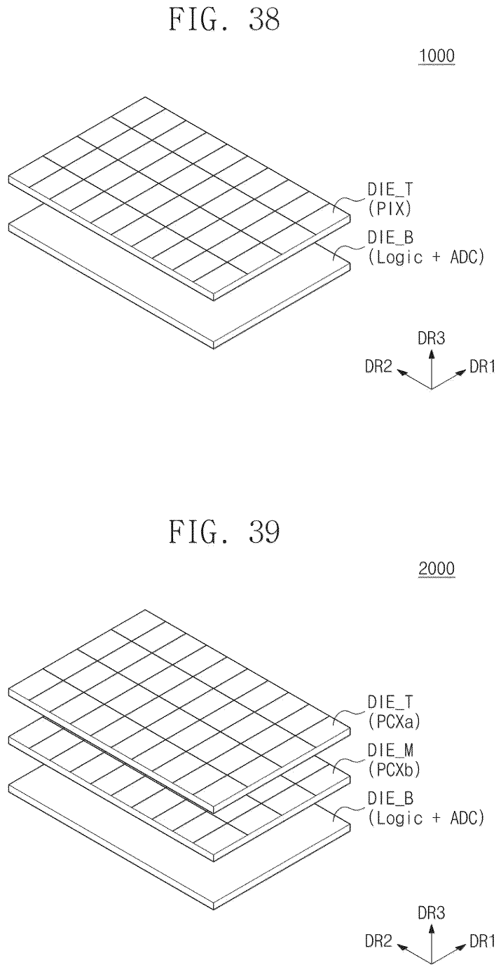

FIGS. 38 and 39 are diagrams showing a stacked structure of an image sensor device according to an example embodiment. First, referring to FIG. 2 and FIG. 38, the image sensor device 1000 may include an upper semiconductor die DIE_T (hereinafter, referred to as a “top die” for convenience of description) and a lower semiconductor die DIE_1T (hereinafter, called a “bottom die” for conveniences of description). The upper plate DIE_T may include a pixel array 110 including a plurality of pixels PIX. The lower plate DIE_B may include components other than the pixel array 110. In an example embodiment, the lower plate DIE_B may include a plurality of variable ramp buffers vCRB, a plurality of ADC circuits ADC, a plurality of variable pixel load circuits vPLD, or a plurality of variable pixels buffers VCPR, which may be implemented through one or a combination of at least two or more of the various example embodiments described with reference to FIGS. 1-37.

Next, referring to FIG. 2 and FIG. 38, the image sensor device 2000 may include an upper semiconductor die DIE_T (hereinafter, referred to as a “top die” for convenience of description), a middle semiconductor die DIE_M (hereinafter, referred as a “middle die” for convenient of description), and a lower semiconductor die DIE_B (hereinafter, referred for convenience of description, referred to as “bottom die”).

The upper plate DIE_T may include a partial pixel circuit PCXa of each of the plurality of pixels PIX of the pixel array 110, and the middle plate DIE_M may include a remaining partial pixel circuit PCXb of each of the plural pixels PIX. For example, in the pixel PIX of FIG. 3A, components (e.g., TX, RX, SF, SEL, etc.) other than the photodiode PD may be pixel circuits for the pixel PIX. A portion PCXa of the pixel circuit of the pixel PIX and the photodiode PD may be formed in the upper plate DIE_T, and the remaining portion PCXb of the pixel circuit in the pixel PIX may be formed in a middle plate DIE_M. The lower plate DIE_B may include components other than the pixel array 110. For example, the lower plate DIE_B may include a plurality of variable ramp buffers vCRB, a plurality of ADC circuits ADC, a plurality of variable pixel load circuits vPLD, or a plurality of variable pixels buffers VCPR. The plurality of variable ramp buffers vCRB, the plurality of ADC circuits ADC, or the plurality of variable pixel buffers VCPR may be implemented through one or a combination of at least two or more of the various example embodiments described with reference to FIGS. 1-37.

In an example embodiment, the plurality of variable ramp buffers vCRB, the plurality of ADC circuits ADC, or the plurality of variable pixel buffers VCPR may be formed across the middle plate DIE_M and the lower plate DIE_B. For example, a plurality of variable pixel buffers VCPR may be formed in the lower plate DIE_B, and a plurality of variable ramp buffers vCRB and a plurality of ADC circuits ADC may be formed in a middle plate DIE_M. Alternatively, the plurality of variable ramp buffers vCRB and the plurality of variable pixel buffers VCPR may be formed in the middle plate DIE_M, and the plurality of ADC circuits ADC may be formed in a lower plate DIE_B. The above description is merely illustrative, and example embodiments are not limited thereto. The implementation manner of each component may be variously modified.

In some embodiments, each of the components represented by a block as illustrated in FIGS. 1, 2, 4A, 5, 15, 22, 24, 25, 27-30 and 32-37 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Furthermore, the components, elements, modules or units represented by a block or processing steps may employ any number of related art techniques for electronics configuration, signal processing and/or control, data processing and the like.

According to an aspect of an example embodiment, an image sensor device includes: a first pixel configured to output a first pixel voltage via a first column line; a ramp generator circuit configured to generate a ramp signal; a first variable pixel load circuit connected to the first column line, the first variable pixel load circuit is configured to generate a first pixel bias current according to a first control signal; and a first analog to digital conversion (ADC) circuit configured to sample a first digital signal based on the ramp signal and a first pixel output voltage, the first variable pixel load circuit is further configured to control the first pixel bias current to a first level during an auto-zero operation of the first ADC circuit, and control the first pixel bias current to a reference level after the auto-zero operation.

In an embodiment, the first variable pixel load circuit includes a first variable current bias circuit connected between the first column line and a ground voltage, and the first variable pixel load circuit is configured to operate according to the first control signal.

According to an aspect of an example embodiment, an image sensor device includes: a ramp generator circuit configured to generate a ramp signal; a first variable ramp buffer circuit configured to output a first output voltage according to the ramp signal and a first control signal; a second variable ramp buffer circuit configured to output a second output voltage according to the ramp signal and a second control signal; a first control switch coupled between the first variable ramp buffer circuit and the second variable ramp buffer circuit; a first analog to digital conversion (ADC) circuit configured to sample a first digital signal based on a first pixel voltage received via a first column line and the first output voltage; and a second ADC circuit configured to sample a second digital signal based on a second pixel voltage received via a second column line and the second output voltage, the first control switch is turned on during an auto-zero operation of the first and second ADC circuits, and the first control switch is turned off after the auto-zero operation.

In an embodiment, the first output voltage is higher than the second output voltage during the auto-zero operation of the first and second ADC circuits, and the first output voltage is equal to the second output voltage after the auto-zero operation.

In an embodiment, after the auto-zero operation, a first input of the first ADC circuit corresponding to the first output voltage is lower than a second input of the second ADC circuit corresponding the second output voltage.

According to an aspect of an example embodiment, a method of operating an image sensor device includes: performing an auto-zero operation of first and second analog to digital converting (ADC) circuits of the image sensor device; controlling, while the auto-zero operation is performed, a first output voltage of a first variable ramp buffer to a first level and a second output voltage of a second variable ramp buffer to a second level; controlling, after the auto-zero operation, the first output voltage of the first variable ramp buffer to a reference level and the second output voltage of the second variable ramp buffer to the reference level; controlling, by the first variable ramp buffer, the first output voltage based on a ramp signal; controlling, by the second variable ramp buffer, the second output voltage based on the ramp signal; sampling, by the first ADC circuit, a first digital signal based on the first output voltage and a first pixel voltage; and sampling, by the second ADC circuit, a second digital signal based on the second output voltage and a second pixel voltage.

In an embodiment, the first and second pixel voltages are equal to each other, and a first time point at which the first digital signal is sampled by the first ADC circuit is different from a second time point at which the second digital signal is sampled by the second ADC circuit.

According to an aspect of an example embodiment, an image sensor device includes: a first pixel configured to output a first pixel voltage via a first column line; a ramp generator circuit configured to generate a ramp signal; a first variable pixel buffer circuit configured to receive the first pixel voltage via the first column line, and output a first pixel output voltage according to the first pixel voltage and a first control signal; and a first analog to digital conversion (ADC) circuit configured to sample a first digital signal based on the ramp signal and the first pixel output voltage, the first variable pixel buffer circuit is further configured to control the first pixel output voltage to a first level during an auto-zero operation of the first ADC circuit, and control the first pixel output voltage to a reference level corresponding to the first pixel voltage after the auto-zero operation.

While aspects of example embodiments have been particularly shown and described, it will be understood that various changes in form and details may be made therein without departing from the spirit and scope of the following claims.

1. An image sensor device comprising:
a ramp generator circuit configured to generate a ramp signal;
a first variable ramp buffer circuit configured to output a first output voltage according to the ramp signal and a first control signal;
a second variable ramp buffer circuit configured to output a second output voltage according to the ramp signal and a second control signal;
a first analog to digital conversion (ADC) circuit configured to sample a first digital signal based on a first pixel voltage received via a first column line and the first output voltage; and
a second ADC circuit configured to sample a second digital signal based on a second pixel voltage received via a second column line and the second output voltage,
wherein the first variable ramp buffer circuit is further configured to control the first output voltage to a first level during an auto-zero operation of the first and second ADC circuits, and control the first output voltage to a reference level after the auto-zero operation, and
wherein the second variable ramp buffer circuit is further configured to control the second output voltage to a second level different from the first level during the auto-zero operation, and control the second output voltage to the reference level after the auto-zero operation.

2. The image sensor device of claim 1, further comprising:
a first pixel configured to output the first pixel voltage via the first column line; and
a second pixel configured to output the second pixel voltage via the second column line,
wherein the first and second pixels operate according to a common selection signal.

3. The image sensor device of claim 2, wherein the first pixel voltage corresponds to a reset level of the first pixel,
wherein the second pixel voltage corresponds to a reset level of the second pixel,
wherein the first ADC circuit is further configured to sample the first digital signal at a first time point, and
wherein the second ADC circuit is further configured to sample the second digital signal at a second time point different from the first time point.

4. The image sensor device of claim 1, wherein the first ADC circuit comprises:
a first amplifier comprising a first inverting input, a first non-inverting input, a first inverting output, and a first non-inverting output;
a first auto-zero switch coupled between the first non-inverting input and the first inverting output, wherein the first auto-zero switch is configured to operate according to an auto-zero signal; and
a first non-inverting input capacitor coupled between the first non-inverting input and the first output voltage,
wherein the second ADC circuit comprises:
a second amplifier comprising a second inverting input, a second non-inverting input, a second inverting output, and a second non-inverting output;
a second auto-zero switch coupled between the second non-inverting input and the second inverting output, wherein the second auto-zero switch is configured to operate according to the auto-zero signal; and
a second non-inverting input capacitor coupled between the second non-inverting input and the second output voltage.

5. The image sensor device of claim 4, wherein after the auto-zero operation, the first non-inverting input has a first offset corresponding to a difference between the first level and the reference level, and the second non-inverting input has a second offset corresponding to a difference between the second level and the reference level, and
wherein the first offset and the second offset are different from each other.

6. The image sensor device of claim 5, wherein the first non-inverting input maintains the first offset and the second non-inverting input maintains the second offset while the ramp signal is output.

7. The image sensor device of claim 1, further comprising:
a third variable ramp buffer configured to output a third output voltage according to the ramp signal and a third control signal; and
a third ADC circuit configured to output a third digital signal based on a third pixel voltage received via a third column line and the third output voltage,
wherein the third variable ramp buffer is further configured to control the third output voltage to a third level during the auto-zero operation of the third ADC circuit, and control the third output voltage to the reference level after the auto-zero operation.

8. The image sensor device of claim 1, further comprising:
a third variable ramp buffer circuit configured to output a third output voltage according to the ramp signal and the first control signal;
a fourth variable ramp buffer circuit configured to output a fourth output voltage according to the ramp signal and the second control signal;
a third ADC circuit configured to sample a third digital signal based on a third pixel voltage received via a third column line and the third output voltage; and
a fourth ADC circuit configured to sample a fourth digital signal based on a fourth pixel voltage received via a fourth column line and the fourth output voltage.

9. The image sensor device of claim 1, further comprising:
a first pixel load circuit coupled with the first column line, wherein the first pixel load circuit is configured to generate a first pixel bias current; and
a second pixel load circuit coupled with the second column line, wherein the second pixel load circuit is configured to generate a second pixel bias current.

10. The image sensor device of claim 9, wherein the first pixel load circuit is further configured to control, during the auto-zero operation, the first pixel bias current to the first level,
wherein the second pixel load circuit is further configured to control, during the auto-zero operation, the second pixel bias current to a third level different than the first level,
wherein the first pixel load circuit is further configured to control, after the auto-zero operation, the first pixel bias current to the reference level, and
wherein the second pixel load circuit is further configured to control, after the auto-zero operation, the second pixel bias current to the reference level.

11. An image sensor device comprising:
a ramp generator circuit configured to generate a ramp signal;
a first variable ramp buffer circuit configured to output a first output voltage according to the ramp signal and a first control signal; and
a first analog to digital conversion (ADC) circuit configured to output a first digital signal based on a first pixel voltage received via a first column line and the first output voltage,
wherein the first variable ramp buffer circuit comprises:
a first driving transistor connected between a first node to which the first output voltage is output and a ground voltage, wherein the first driving transistor is configured to operate according to the ramp signal; and
a first variable current bias circuit coupled between the first node and a power supply voltage, wherein the first variable current bias circuit is configured to control a first bias current provided to the first node according to the first control signal, drive the first bias current to a first magnitude during an auto-zero operation of the first ADC circuit, and drive the first bias current to a reference magnitude after the auto-zero operation.

12. The image sensor device of claim 11, wherein the first variable current bias circuit comprises:
a first bias transistor connected between the first node and a second node, wherein the first bias transistor is configured to operate according to a first bias signal;
a second bias transistor connected between the second node and the power supply voltage, wherein the second bias transistor is configured to operate according to a second bias signal; and
a first current control circuit connected between the second node and the power supply voltage, wherein the first current control circuit is configured to operate according to the first control signal.

13. The image sensor device of claim 12, wherein the first current control circuit comprises:
a first control transistor configured to operate according to the second bias signal; and
a first control switch configured to operate according to the first control signal,
wherein the first control transistor and the first control switch are connected in series between the power supply voltage and the second node, and
wherein:
the first control switch is turned on during the auto-zero operation, and the first control switch is turned off after the auto-zero operation, or
the first control switch is turned off during the auto-zero operation, and the first control switch is turned on after the auto-zero operation.

14. The image sensor device of claim 11, further comprising:
a second variable ramp buffer configured to output a second output voltage according to the ramp signal and a second control signal; and
a second ADC circuit configured to output a second digital signal based on a second pixel voltage received via a second column line and the second output voltage,
wherein the second variable ramp buffer comprises:
a second driving transistor connected between a third node to which the second output voltage is output and the ground voltage, wherein the second driving transistor is configured to operate according to the ramp signal; and
a second variable current bias circuit coupled between the third node and the power supply voltage, wherein the second variable current bias circuit is configured to control a second bias current provided to the third node according to the second control signal, drive the second bias current to a second magnitude during an auto-zero operation of the second ADC circuit, and drive the second bias current to the reference magnitude after the auto-zero operation.

15. The image sensor device of claim 14, further comprising a third control switch coupled between the first variable current bias circuit and the second variable current bias circuit,
wherein during the auto-zero operation of the first and second ADC circuits, the third control switch is turned on, and
wherein after the auto-zero operation of the first and second ADC circuits, the third control switch is turned off.

16. The image sensor device of claim 11, wherein the first variable current bias circuit comprises:
a first bias transistor connected between the first node and a second node, wherein the first bias transistor is configured to operate according to a first bias signal;
a second bias transistor connected between the second node and the power supply voltage, wherein the second bias transistor is configured to operate according to a first gate voltage; and
a first gate control circuit configured to control the first gate voltage based on a second bias signal, according to the first control signal,
wherein the first gate control circuit is further configured to control the first gate voltage to a first level during the auto-zero operation, and control the first gate voltage to a level corresponding to the second bias signal after the auto-zero operation the first gate voltage.

17. The image sensor device of claim 16, wherein the first gate control circuit comprises:
a first sampling capacitor connected between a gate electrode of the second bias transistor and the power supply voltage;
a first sampling transistor connected between the second bias signal and a gate electrode of the second bias transistor, wherein the first sampling transistor is configured to operate according to a sampling signal; and
a first dummy switch circuit connected to a gate electrode of the second bias transistor, wherein the first dummy switch circuit is configured to operate according to the first control signal, and
wherein the first dummy switch circuit comprises a plurality of transistors configured to individually operate according to the first control signal.

18. The image sensor device of claim 17, wherein during the auto-zero operation, M (where M is an integer greater than or equal to 0) transistors of the plurality of transistors of the first dummy switch circuit are turned on, and after the auto-zero operation, N (where N is an integer equal to or greater than 0 different from M) transistors of the plurality of transistors in the first dummy switch circuit are turned on.

19. An image sensor device comprising:
a ramp generator circuit configured to generate a ramp signal;
a variable ramp buffer block circuit configured to buffer the ramp signal to output a plurality of output voltages; and
an analog to digital converting (ADC) block circuit configured to sample a plurality of digital signals corresponding to a plurality of pixel voltages by comparing the plurality of pixel voltages received via a plurality of column lines and the plurality of output voltages, respectively,
wherein the variable ramp buffer block circuit is further configured to control at least two output voltages of the plurality of output voltages to have different levels while the ADC block circuit performs an auto-zero operation, and control the plurality of output voltages to have a common voltage level after the auto-zero operation.

20. The image sensor device of claim 19, further comprising a plurality of pixels connected with the plurality of column lines and configured to operate according to a common selection signal,
wherein the ADC block circuit comprises a plurality of ADC circuits, and
wherein in a reset sampling operation on the plurality of pixels, at least two of the plurality of ADC circuits perform sampling at different time points.

21-28. (canceled)
